(19) United States
(12) Patent Application Publication
(10) Pub. No.: US 2026/0343855 A1
(43) Pub. Date: Oct. 29, 2026

(54) SEMICONDUCTOR STRUCTURES AND MANUFACTURING METHOD OF THE SAME

(71) Applicant: Taiwan Semiconductor Manufacturing Company, Ltd., Hsinchu (TW)

(72) Inventors: Hsin-Yu LAI, Hsinchu (TW); Cheng-Yi Wu, Taichung City (TW); Katherine H. CHIANG, New Taipei City (TW)

(73) Assignee: Taiwan Semiconductor Manufacturing Company, Ltd., Hsinchu (TW)

(21) Appl. No.: 19/192,347

(22) Filed: Apr. 29, 2025

(51) Int. Cl. H10B 12/00; H10D 1/00; H10D 1/68

(52) U.S. Cl. CPC H10B 12/315; H10B 12/033; H10B 12/318; H10B 12/50; H10D 1/043; H10D 1/716

(57) ABSTRACT

A method including following steps is provided. An interconnect structure including interlayer dielectric layers is formed over a semiconductor substrate. A first region of the interconnect structure is patterned to form first trench segments, and a second region of the interconnect structure is patterned to form second trench segments laterally adjacent to the first trench segments. First bottom electrodes in the first trench segments and second bottom electrodes in the second trench segments are concurrently formed. An insulator layer covering the first bottom electrodes and the second bottom electrodes is formed. A first top electrode and a second top electrode are concurrently formed over the insulator layer. The first bottom electrodes, a first portion of the insulator layer and the first top electrode, form a memory cell storage capacitor, and the second bottom electrodes, a second portion of the insulator layer and the second top electrode, form a decoupling capacitor.

### BACKGROUND

In modern Integrated Circuit (IC) manufacturing, on-chip capacitors are available for a large number of applications, such as Dynamic Random Access Memory (DRAM), voltage controlled oscillators, and operational amplifiers. The capacitor may be used to provide decoupling between the circuit and undesired interference or noise generated by the rest of the chip. Technological advances in materials and design have resulted in many generations of semiconductor devices, each with smaller and more complex architecture than the previous generation. In the course of advancement and innovation, there is a need for an improved structure and method of manufacturing IC including capacitors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1R are schematic cross-sectional views illustrating structures produced at various stages of a manufacturing process of forming a memory cell with a decoupling capacitor, in portion or entity, in accordance with some embodiments of the present disclosure.

FIG. 2A through FIG. 2T are schematic cross-sectional views illustrating structures produced at various stages of a manufacturing process of forming a memory cell with a decoupling capacitor, in portion or entity, in accordance with some alternative embodiments of the present disclosure.

FIG. 3A through 3P are schematic cross-sectional views illustrating structures produced at various stages of a manufacturing process of forming a memory cell with a decoupling capacitor, in portion or entity, in accordance with some alternative embodiments of the present disclosure.

FIG. 4 through FIG. 8 are schematic cross-sectional views illustrating different configuration of an IC including a memory cell with a decoupling capacitor, in accordance with some embodiments of the present disclosure.

FIG. 9A through FIG. 9F illustrate top-down plane views of a decoupling capacitor, in accordance with some embodiments of the decoupling capacitor illustrated in FIG. 3P to FIG. 8.

FIG. 10A through FIG. 10M are schematic cross-sectional views illustrating structures produced at various stages of a manufacturing process of forming a memory cell with a decoupling capacitor, in portion or entity, in accordance with some alternative embodiments of the present disclosure.

FIG. 11A through FIG. 11B are schematic illustration demonstrating an interconnecting network including a memory cell, a decoupling capacitor and front-end-of-line (FEOL) devices, in accordance with some embodiments.

FIG. 12A through FIG. 12C are schematic cross-sectional views illustrating a semiconductor device including a memory cell and a decoupling capacitor, in accordance with some embodiments of the present disclosure.

### DETAILED DESCRIPTION

The present disclosure relates generally to a method of integrating a decoupling capacitor with a memory cell (i.e., back-end of line embedded DRAM (BEOL eDRAM)), and an associated structure.

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, the manufacturing method is part of a package manufacturing process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

Throughout the various views and illustrative embodiments, like reference numbers are used to designate like elements.

A method of forming a memory cell (e.g., BEOL eDRAM) with a decoupling capacitor is described herein. Each memory cell includes a metal-insulator-metal (MIM) storage capacitor and a thin film transistor (TFT). The MIM storage capacitor is formed concurrent with the decoupling capacitor in the BEOL region, without the need of occupying the FEOL region, and further reduces the processing steps and manufacturing cost of increasingly complex IC.

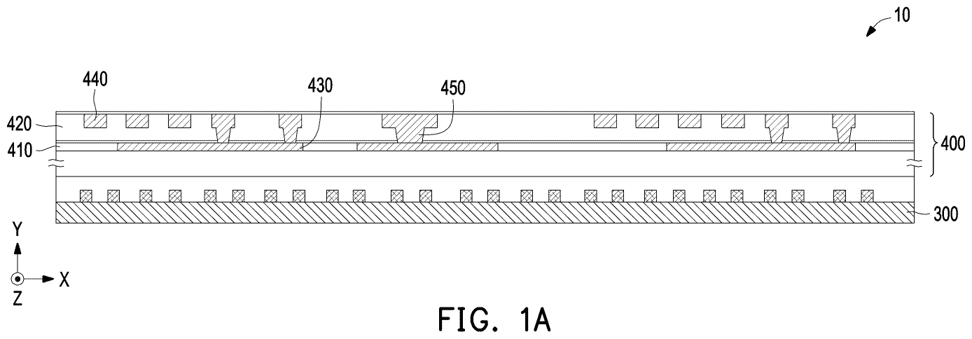

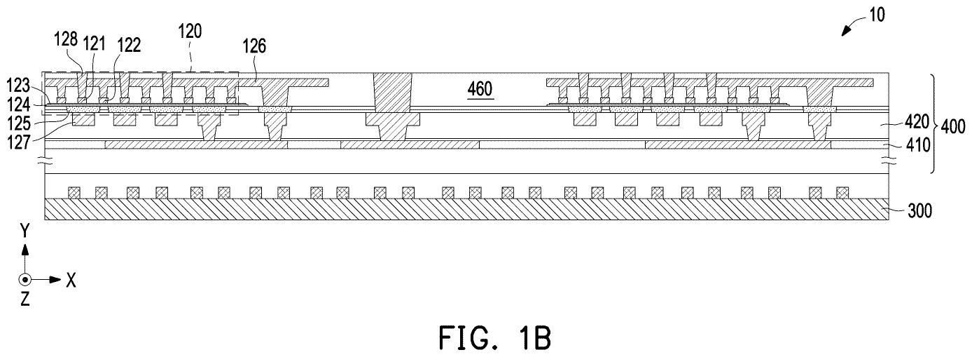

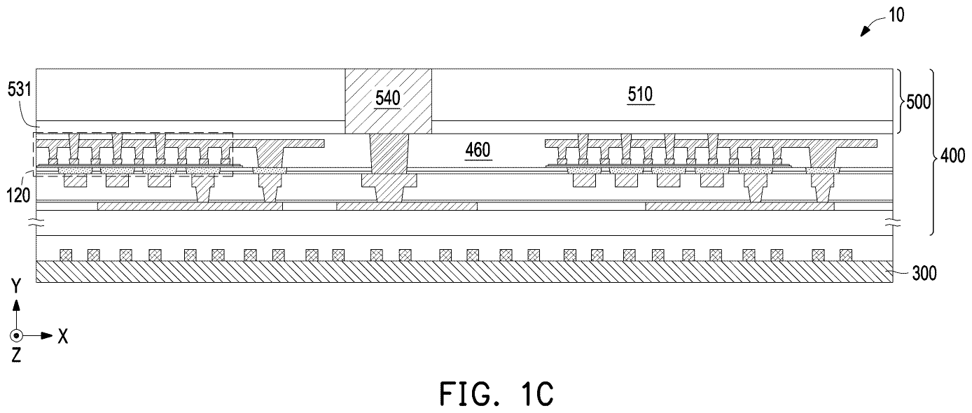

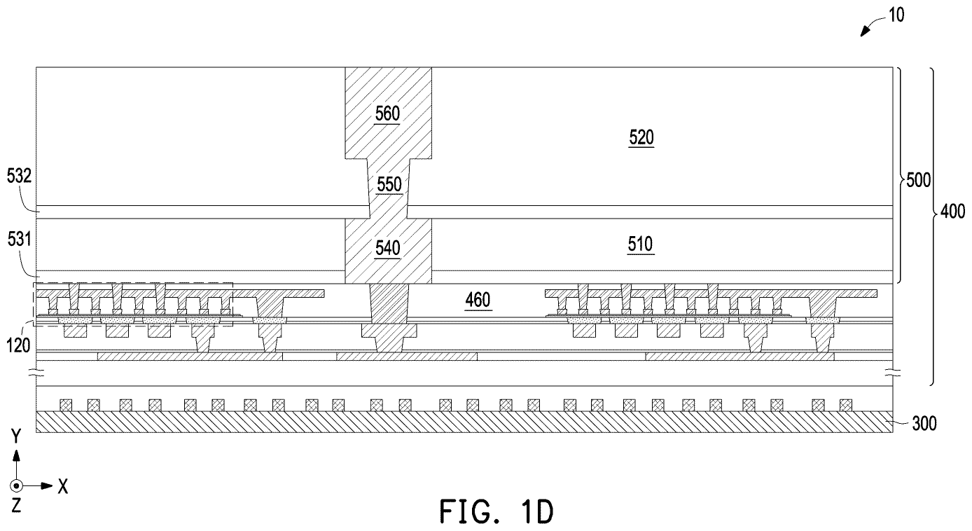

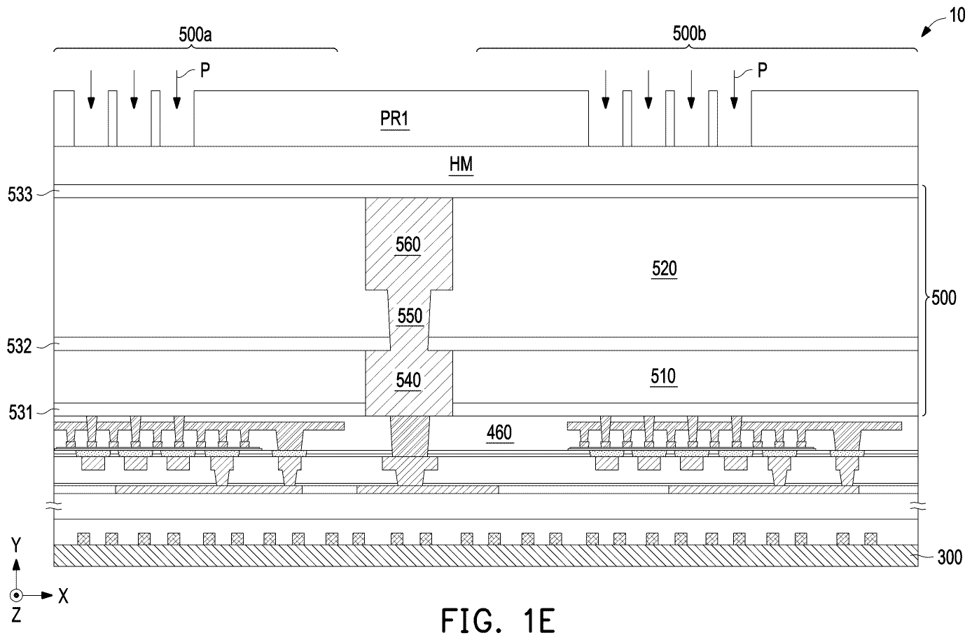

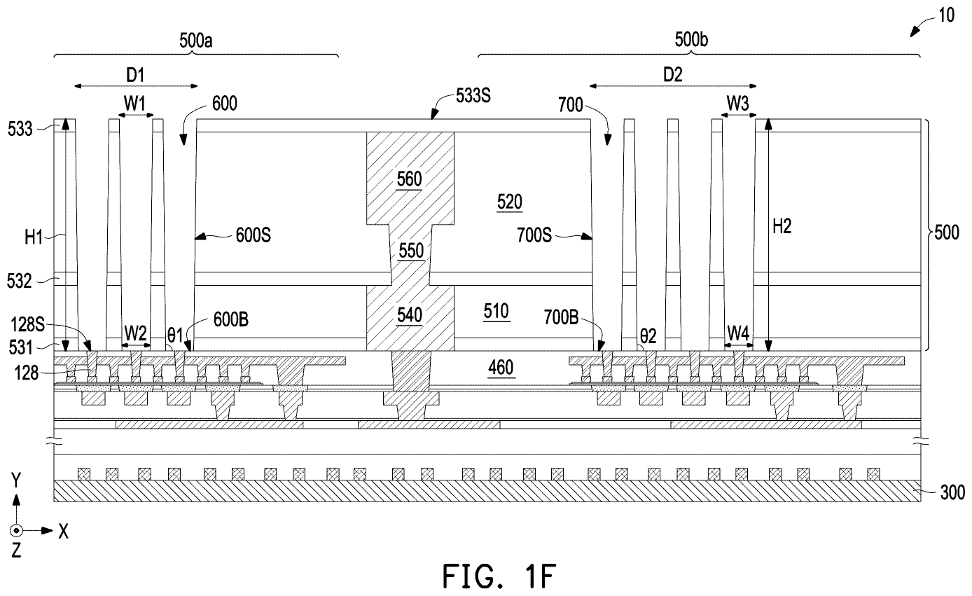

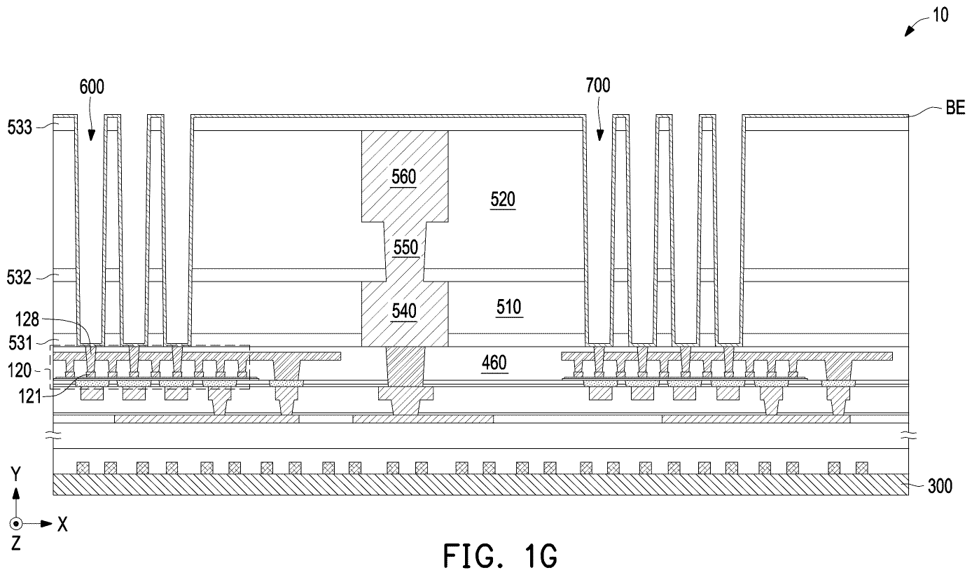

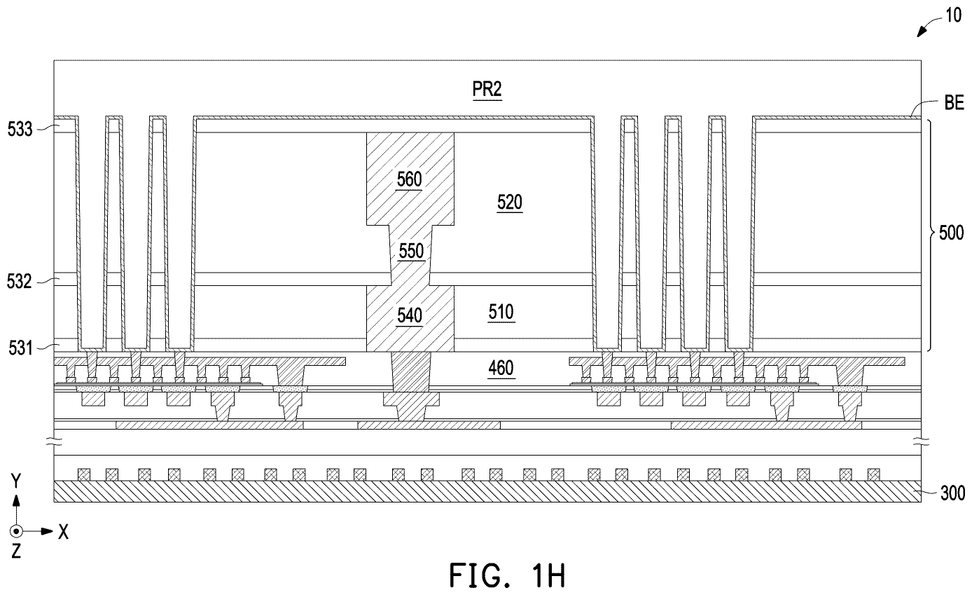

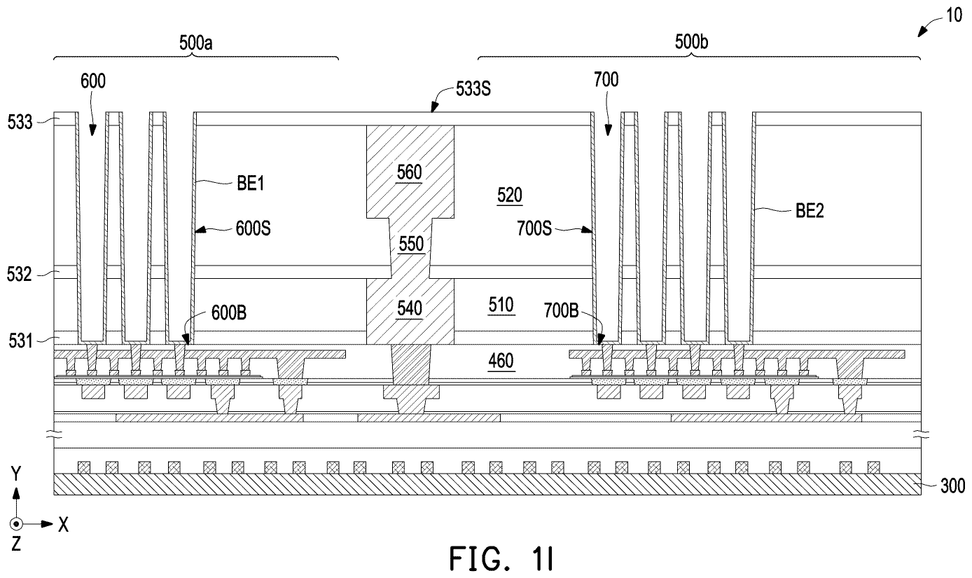

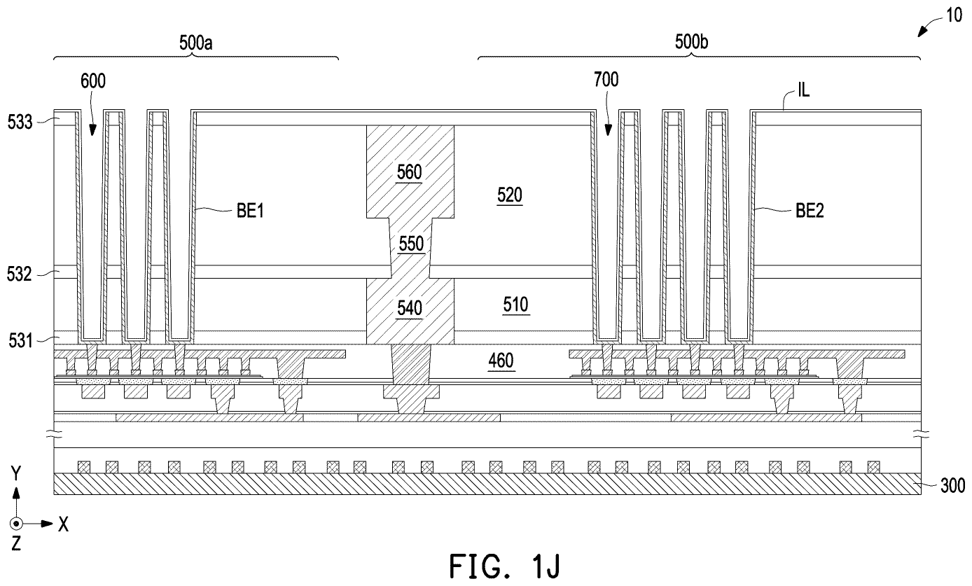

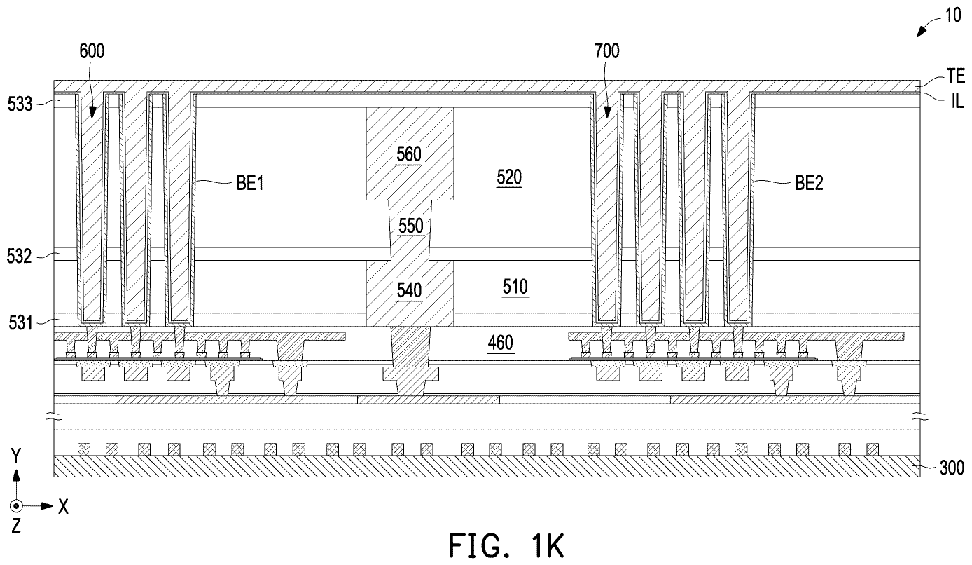

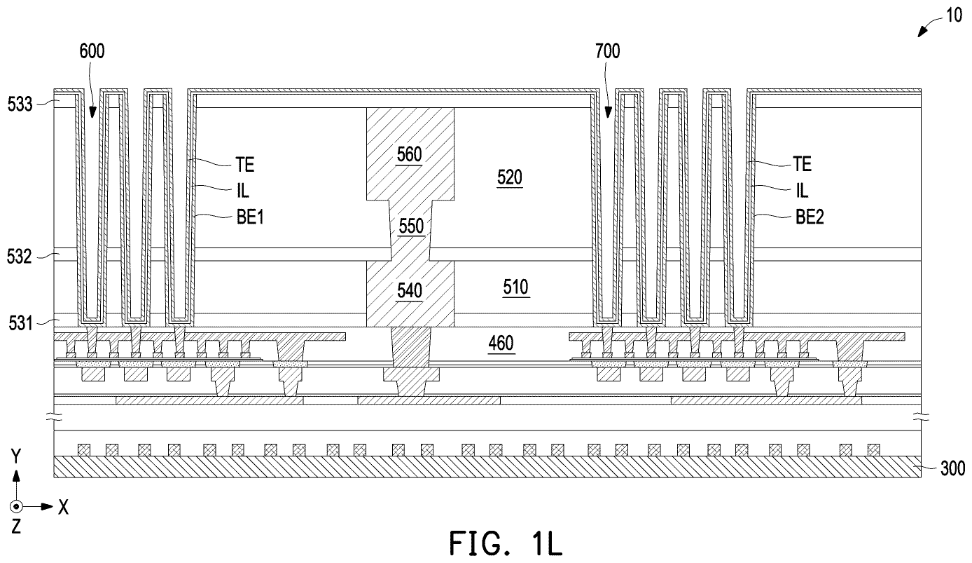

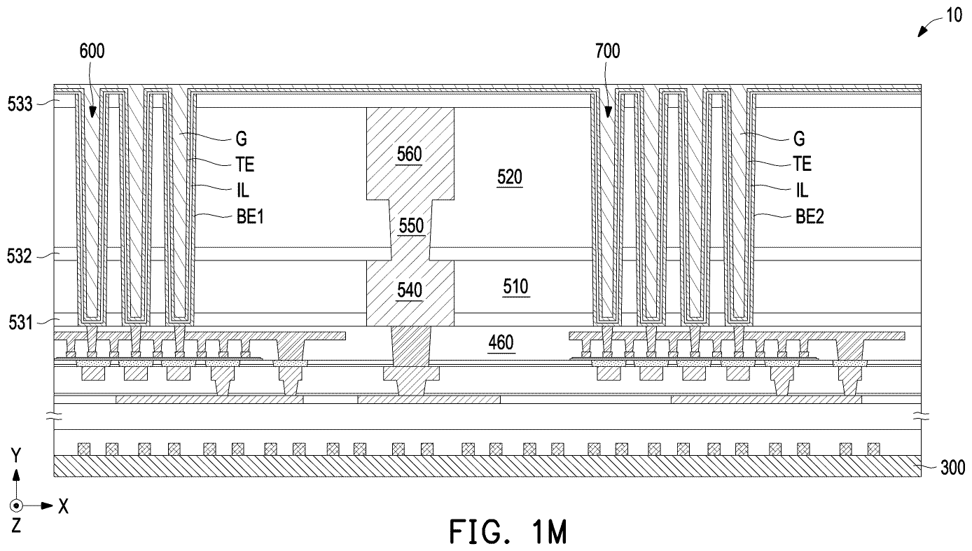

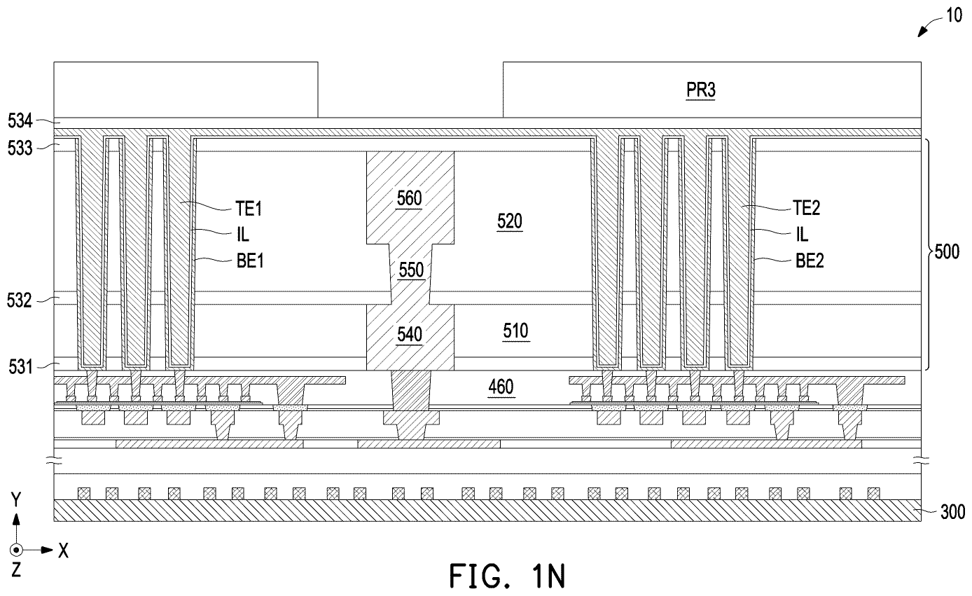

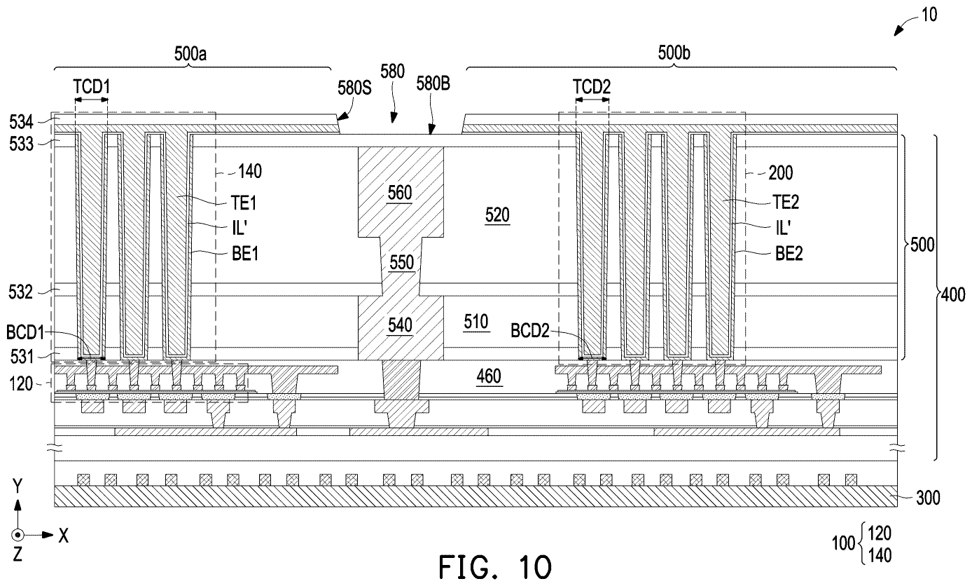

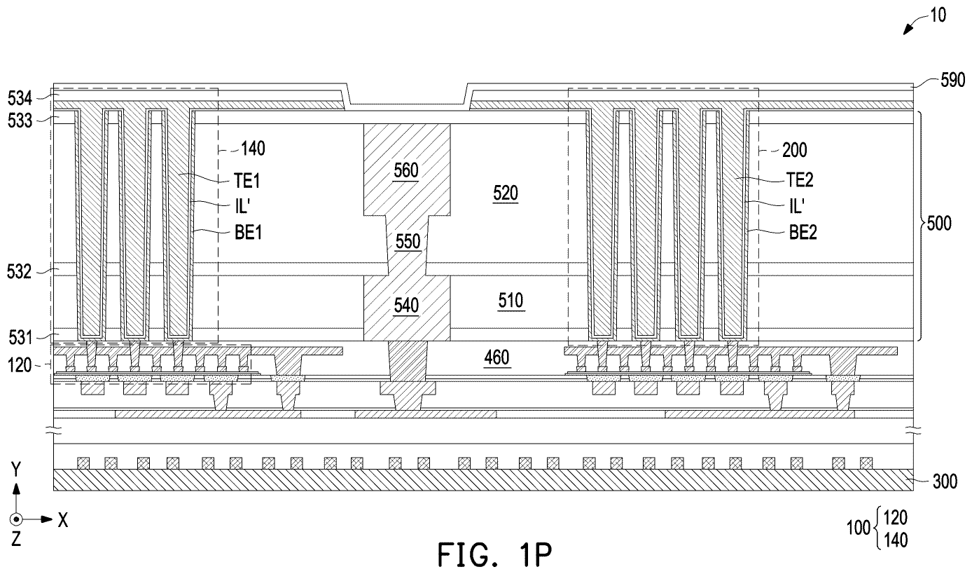

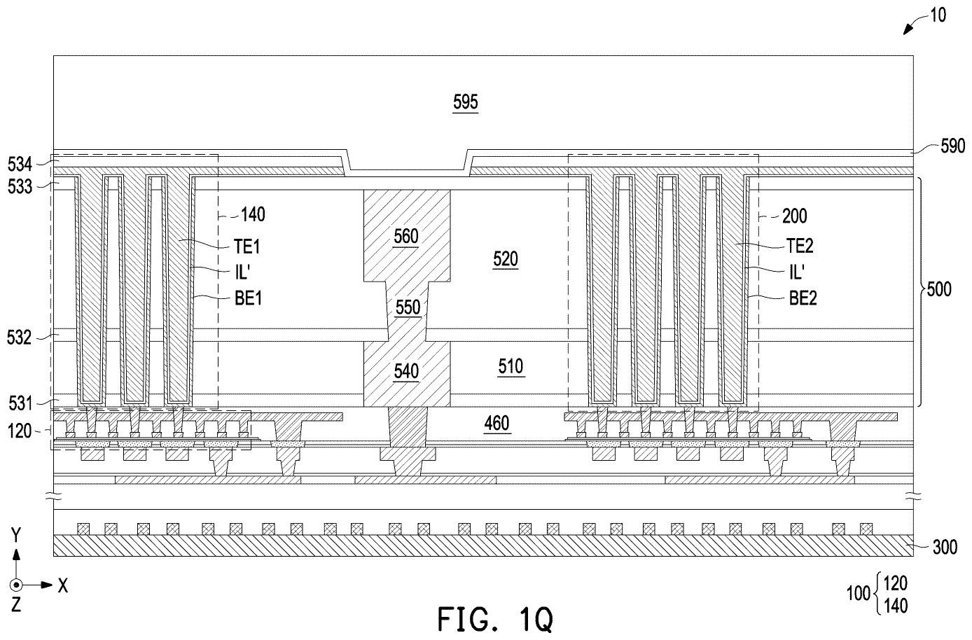

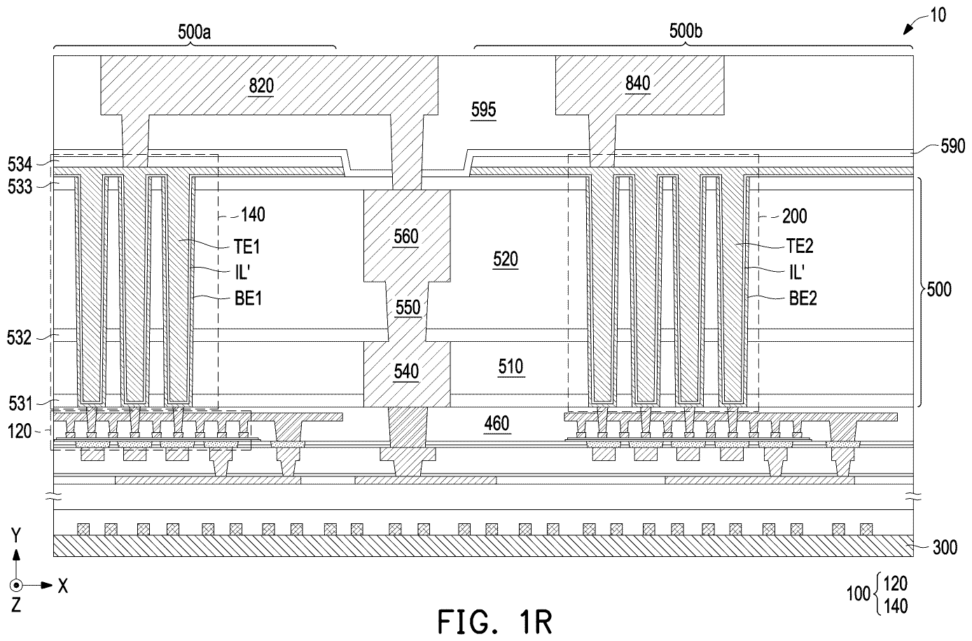

FIG. 1A through FIG. 1R are schematic cross-sectional views illustrating structures produced at various stages of a manufacturing process, in portion or entity, of forming a memory cell with a decoupling capacitor.

Referring to FIG. 1A, the method of forming a semiconductor structure including a memory cell with a decoupling capacitor, includes the step of providing a substrate 300. In some embodiments, the substrate 300 is a semiconductor substrate such as a silicon substrate, it may also be formed of other semiconductor materials, such as silicon germanium, germanium, silicon carbon, aluminum nitride, gallium arsenide, boron nitride, silicon nitride, beryllium oxide, indium arsenide, indium gallium arsenide, indium antimonide, or the like. In some embodiments, the substrate 300 is a bulk mono-crystalline silicon substrate, a layer of silicon on a silicon wafer, a layer of a silicon-on-insulator (SOI) wafer, or a layer of a germanium-on-insulator (GeOI) wafer. The semiconductor structure 10 includes a BEOL metallization stack 400 arranged over the substrate 300. The semiconductor structure 10 may further include additional BEOL, middle end of line (MEOL) and front end of line (FEOL) layers formed below the BEOL metallization stack 400. By way of example and not limitation, FEOL layers may include transistors and capacitor structures. The MEOL layer may include contacts (e.g., source/drain contacts, gate contacts, and other suitable contact vias) that connect the transistors and capacitor structures in the FEOL to structures in the BEOL metallization stack 400.

The BEOL metallization stack 400 includes a plurality of interlayer dielectric (ILD) layers. In some embodiment, ILD layers may be formed above the semiconductor substrate 300. The ILD layers may include one or more separate dielectric layers 410, 420 (e.g., a low-k dielectric material, an ultra low-k dielectric material, etc.) stacked onto one another over the semiconductor substrate 300. The BEOL metallization stack 400 may further include a plurality of metal layers 430, 440 and conductive vias 450 arranged in the dielectric layers 410, 420. Although two metal layers 430, 440 and one conductive via 450 are shown in FIG. 1A, in various embodiments, the semiconductor structure 10 may include any other numbers of interconnecting metal layers and conductive vias. The BEOL metal lines and conductive vias may be used to interconnect various inputs and outputs of the FEOL and used to house a memory cell and a decoupling capacitor as described herein.

Referring to FIG. 1B, the method includes forming a dielectric layer 460 over the dielectric layers 410, 420 within the BEOL metallization stack 400. In some embodiments, a transistor 120 of the memory cell (i.e., BEOL eDRAM) may be formed in the dielectric layer 460. The transistor 120 includes a pair of source/drain regions 121, 122 and a channel region 123 that is vertically disposed below the source/drain regions 121, 122. The transistor 120 may further include a gate dielectric layer 124 between the channel region 123 and a gate electrode 125.

The transistor 120 of the memory cell (i.e., BEOL eDRAM) may be interconnected into a network with conductive traces including bit lines 126, and word lines 127. Bit lines 126 may extend in a first direction (e.g., x-dimension), and word lines 127 may extend in a second, orthogonal direction (e.g., y-dimension). In some embodiments, the source terminal 121 of the transistor 120 may be in contact with a capacitor via 128 deposited above the source terminal 121, and the capacitor via 128 may be in contact with a subsequently formed bottom electrode BE1 of the memory cell storage capacitor 140 (as illustrated in FIG. 1R). In some embodiments, the source terminal 121 of the transistor 120 may be electrically coupled to a bottom electrode BE1 of the memory cell storage capacitor 140 (as illustrated in FIG. 1R), through the capacitor via 128. In some embodiment, the drain terminal 122 of the transistor 120 may be coupled to the local bit line 126. The configuration shown in FIG. 1B merely serves as an exemplary illustration. In some embodiments, as illustrated in FIG. 1B, the bit line 126 and the capacitor via 128 may be shown to be overlapping with each other from a cross-sectional view of the semiconductor structure 10. However, it should be noted that the bit line 126 may be formed spatially apart from the capacitor via 128 from a side view of the semiconductor structure 10, such that the source terminal 121 coupled to the capacitor via 128 may be electrically isolated from (that is, not in contact with) the drain terminal 122 coupled to the bit line 126. In some embodiment, the channel region 123 is separated from the gate electrode 125 and the word lines 127 by the gate dielectric layer 124. The bit lines 126, word lines 127, and the transistor 120 are within, and/or between, various ILD layers 410, 420, 460 within the BEOL metallization stack 400.

In some embodiments, where the memory cell is in the backend levels of a semiconductor wafer, each transistor 120 advantageously includes a TFT. In some embodiments, the TFT may be selected from a group consisting of staggered top gate transistor, staggered bottom gate transistor, coplanar top gate transistor and a coplanar bottom gate transistor, and equivalents thereof.

In some embodiments, the source/drain regions 121, 122 of the transistor 120 may include any suitable electrically conductive material, alloy, or a stack of multiple electrically conductive materials. In some embodiments, the source/drain regions 121, 122 of the transistor 120 may include one or more metals or metal alloys, e.g., molybdenum, ruthenium, osmium, iridium, rhenium, silver, gold, copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the source/drain regions 121, 122 of the transistor 120 may include one or more electrically conductive alloys, oxides, or carbides of one or more metals. In some embodiments, the source/drain regions 121, 122 of the transistor 120 may include metal composites, such as silicide (e.g., tungsten silicide, titanium silicide, etc.), and conductive metal oxide (e.g., ruthenium oxide, etc.). In some embodiments, the source/drain regions 121, 122 of the transistor 120 may include a doped semiconductor, such as silicon or another semiconductor doped with an N-type dopant or a P-type dopant. The metals may provide higher conductivity, while doped semiconductors may be easier to pattern during fabrication. In some embodiments, the source/drain regions 121,122 may be formed as a single or multi layer structure.

In some embodiments, the channel region 123 may be composed of semiconductor material systems including, for example, N-type or P-type materials systems. In some embodiments, the channel region 123 may include a high mobility oxide semiconductor (OS) film material, such as indium oxide, gallium oxide, zinc oxide, titanium oxide, aluminum oxide, tungsten oxide, cerium oxide, tin oxide, scandium oxide, silver oxide, copper oxide, chromium oxide, boron oxide, magnesium oxide, iron oxide, antimony oxide, and calcium oxide. In particular, the channel region 123 may be formed of a single layer or a multi-layer structure. Some of the foregoing materials may be deposited at relatively low temperatures, which allows depositing them within the thermal budgets imposed on back end fabrication to avoid damaging the FEOL components.

In various embodiments, the gate dielectric layer 124 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer 124 may include, but are not limited to, hafnium oxide, hafnium silicon oxide, hafnium zirconium oxide, hafnium titanium oxide, hafnium lanthanum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the gate dielectric layer 124 has a dielectric constant of greater than 9.0. In some embodiments, the gate dielectric layer 124 may be formed as a single layer or multi layer gate dielectric layer.

The gate electrode 125 may include metallic electrode, of similar composition to the source/drain regions 121, 122. In some embodiments, the gate electrode 125 may include single layer or a stack of two or more metallic layers.

Referring to FIG. 1C and FIG. 1D, the method further includes forming an interconnect structure 500 within the BEOL metallization stack 400 over the semiconductor substrate 300. The interconnect structure 500 is configured to electrically couple a capacitor (i.e., decoupling capacitor and storage capacitor of memory cell) and other electrical components in the semiconductor structure 10. The interconnect structure 500 includes ILD layers, wherein the ILD layers include a first ILD layer 510 and a second ILD layer 520. The interconnect structure 500 further includes a first etch stop layer (ESL) 531 formed over the transistor 120 of the memory cell. In some embodiments, the first ILD layer 510 is formed over the first ESL 531, and a first conductive contact 540 (i.e., metal line, metal pad, metal via) is formed within the first ILD layer 510 and the first ESL 531. In some embodiments, a second ESL 532 is formed over the first conductive contact 540 and the first ESL 531, and the second ILD layer 520 is formed over the second ESL 532. In some embodiments, a second conductive contact (i.e., metal line, metal pad, metal via) is formed in the second ILD layer 520 and a portion of the second ESL 532. The second conductive contact includes a via structure 550 coupled to a trench structure 560. The via structure 550 and the trench structure 560 may be simultaneously filled during a dual damascene process in some embodiment. The first conductive contact 540 and the second conductive contact 550, 560 extends though the first and the second ILD layers 510, 520 of the interconnect structure 500. In some embodiments, the first and the second conductive contacts 540, 550, 560 may be arranged in a alternating manner by stacking over one another. In some embodiments, the first and the second conductive contacts 540, 550, 560 are configured to electrically connect devices or components in the interconnect structure 500 with other devices of the semiconductor structure 10. In some embodiments, the interconnect structure 500 may include additional ESL and ILD layers. In some embodiments, the first and the second ESL 531, 532 may be formed of silicon nitride, silicon oxynitride, and/or other suitable materials. In some embodiments, the ILD layers 510, 520 of the interconnect structure 500 may be formed from a variety of dielectric materials, such as a low-k dielectric material, an ultra low-k dielectric material, an extreme low-k dielectric material, a metal oxide (e.g., germanium oxide), oxynitrides (e.g., gallium phosphide oxynitride), silicon dioxide (SiO₂), nitrogen-containing oxides (e.g. nitrogen-containing SiO₂), nitrogen doped oxide (e.g., N₂ implanting SiO₂), silicon oxynitride (e.g., SiₓO_{y}N_{z}), etc. The ILD layers 510, 520 may be formed by way of a deposition process, e.g., chemical vapor deposition (CVD), physical vapor deposition (PVD), atomic layer deposition (ALD), etc. The first and the second conductive contacts 540, 550, 560 may be formed of conductive materials such as aluminum, gold, silver, tungsten, copper, tantalum, tantalum nitride, titanium, titanium nitride, cobalt, tungsten nitride, molybdenum, ruthenium, etc. However, the disclosure is not limited thereto. In some alternative embodiments, the first and the second conductive contacts 540, 550, 560 may include a multi-layered gap fill structure, including a barrier layer (e.g., titanium nitride) and a gap-filling layer (e.g., copper).

Referring to FIG. 1E and FIG. 1F, in some embodiment, the method further includes performing a lithography process to form a plurality of trench segments 600 and 700 in the interconnect structure 500. The lithography process includes forming a hard mask layer HM and a photoresist layer PR1 over the interconnect structure 500, followed by a patterning step P to etch one or more recesses into a first region 500a and a second region 500b of the interconnect structure 500, thereby forming one or more first trench segments 600 and second trench segments 700 extending through the ILD layers 510, 520 in a first direction (y-direction). In some embodiments, prior to the formation of hard mask layer HM and the photoresist layer PR1, an ESL 533 may be formed over ILD layer 520 in the interconnect structure 500. The ESL 333 is of similar composition to the other ESLs 531, 532 within the semiconductor structure 10, such as silicon nitride, silicon oxynitride, and/or other suitable materials. In some embodiment, the first trench segments 600 and the second trench segments 700 extend through the ILD layer 510, 520 of the interconnect structure 500, and stop once a top surface of the ILD layer 460 underlying the interconnect structure 500 is reached, and exposing a top surface 128S of the underlying capacitor via 128. The second trench segments 700 are laterally adjacent to the first trench segments 600 in a second direction (x-direction) substantially perpendicular to the first direction (y-direction). The photoresist PR1 is stripped after the first and the second trench segments 600, 700 are formed. As seen in FIG. 1F, the plurality of first trench segments 600 are laterally spaced from the plurality of second trench segments 700 by the ILD layers 510, 520 of the interconnect structure 500. In some embodiments, the first trench segments 600 and the second trench segments 700 are concurrently defined in a single patterning process. In an embodiment, the first and the second trench segments 600, 700 are elongated in parallel in the first direction (y direction), such that the plurality of trench segments 600, 700 have individual greatest dimension (e.g., height) in the y-direction. Further, each of the first and the second trench segments 600, 700 are evenly spaced from each other in the second direction (x-direction), which is orthogonal to the first direction (y-direction). In alternative embodiments, the vertical height and spacing between the plurality of trench segments 600, 700 may be non-uniform and/or varied.

Further referring to FIG. 1F, in some embodiments, the first trench segments 600 in the first region 500a of the interconnect structure 500 may have a tapered shape when viewed in cross-section. A top portion of each of the first trench segments 600 has a lateral width W₁ measured in a direction parallel to a top surface of the semiconductor substrate 300, which is substantially greater than a lateral width W₂ at a bottom portion of each of the first trench segments 600. The top portion of the first trench segments 600 may have a greater lateral width W₁ than the lateral width W₂ at the bottom portion of the first trench segments 600 because an etchant that was used to form the trench segments 600 may be in contact with the top portion of the first trench segments 600 for a longer duration than a bottom portion of the first trench segments 600, therefore a greater amount of lateral etching may occur at the top portion of the first trench segments 600 than at the bottom portion of the first trench segments 600. Similarly, the second trench segments 700 in the second region 500b of the interconnect structure 500 may also have a tapered shape when viewed in cross-section. A top portion of each of the second trench segments 700 has a lateral width W₃ which is substantially greater than a lateral width W₄ at a bottom portion of each of the second trench segments 700. As further shown in FIG. 1F, the vertical height H₁ of the first trench segments 600, may be substantially the same as the vertical height H₂ of the second trench segments 700. In some embodiments, the bottom portions of the first trench segments 600 and the second trench segments 700 may be at the same elevation within the IDL layers 510, 520 of the interconnect structure 500. In some embodiment, the lateral width W₁ of the top portion of each of the first trench segments 600 is substantially the same as the lateral width W₃ of the top portion of each of the second trench segments 700. In some embodiment, the lateral width W₂ of the bottom portion of each of the first trench segments 600 is substantially the same as the lateral width W₄ of the bottom portion of each of the second trench segments 700. In some embodiments, a lateral distance D₁ between a plurality of the first trench segments 600 is substantially smaller than the vertical height H₁ of the first trench segments 600. In some embodiments, a lateral distance D₂ between a plurality of the second trench segments 700 is substantially smaller than the vertical height H₂ of the second trench segments 700. However, the disclosure is not limited thereto. In some embodiments, the vertical heights H₁, H₂ and the lateral distance D₁, D₂ may be independent of each other, and adjusted according to design or performance requirements. The lateral distance D₁ between the plurality of first trench segments 600 may be substantially the same or varied than the lateral distance D₂ between the plurality of second trench segments 700. In some embodiments, an aspect ratio of the first and the second trench segments 600, 700 may be in a range of 2 to 100, wherein the aspect ratio is defined as a ratio of a two-directional depth (e.g., vertical height H₁, H₂) to a width (e.g., lateral width W₁, W₂) of the trench segments 600, 700. The lateral width W₁, W₃ (i.e., critical dimension) of the first trench segments 600 may be in a range of 10 nm to 800 nm. The vertical height H₁ and the vertical height H₂ of the first and the second trench segments 600, 700 respectively, may be in a range of 50 nm to 15 μm. In some embodiments, the first trench segments 600 may have a sidewall angle θ₁ defined by an angle between the bottom surface 600B and sidewall 600S of the first trench segments 600. The second trench segments 700 may have a sidewall angle θ₂ defined by an angle between the bottom surface 700B and sidewall 700S of the second trench segments 700. In some embodiments, the sidewall angle θ₁ and the sidewall angle θ₂ may be substantially the same, included in a range of approximately 90 degrees to approximately 110 degrees. However, other values and range are within the scope of the present disclosure. It should be noted that the number of first trench segments 600 and the number of second trench segments 700 illustrated in FIG. 1F is for the sake of brevity, from the perspective of the manufacturing process, the first and the second trench segments may constitute more or less trench segments, the number and arrangement of the trench segments may be adjusted according to design requirement. It should also be noted that the dimensions (i.e., vertical height, width) of the first and the second trench segments 600, 700 may be adjusted according to design and performance requirements.

Referring to FIG. 1G, the method further includes depositing a bottom electrode material layer BE along sidewalls 600S, bottom surfaces 600B of the first trench segments 600, sidewalls 700S, bottom surfaces 700B of the second trench segments 700 and a top surface 533S of the ESL 533. In some embodiments, the bottom electrode material layer BE continuously extending between each of the trench segments of the first trench segments 600 and second trench segments 700. In some embodiments, the bottom electrode material layer BE is concurrently formed in the first trench segments 600 and the second trench segments 700 in a single deposition process. In an alternative embodiment, the bottom electrode material layer BE in the first trench segments 600 and the second trench segments 700 are formed sequentially in separate depositing processes. In the embodiment where the bottom electrode material layer BE in the first trench segments 600 and the second trench segments 700 are formed sequentially in separate depositing processes, the bottom electrode material layer BE in the first trench segments 600 and the bottom electrode material layer BE in the second trench segments 700 may be identical or different in material.

As illustrated in FIG. 1G, the bottom electrode material layer BE in the first trench segments 600 is in contact with the exposed top surface 128S of the capacitor via 128 in ILD layer 460 underlying the first trench segments 600, and is further connected to the source/drain region 121 of the underlying transistor 120, by way of one or more metal layers (e.g., metal contact, metal via).

In various embodiments, the bottom electrode material layer BE may include platinum, aluminum-copper, titanium nitride, gold, titanium, tantalum, tantalum nitride, tungsten, tungsten nitride, and/or copper, for example. In other embodiments, the bottom electrode material layer BE may include metal composites, such as silicide (e.g., tungsten silicide, titanium silicide, etc.), and/or metal nitride (e.g., tantalum nitride, titanium nitride, tungsten nitride, etc.). In some other embodiments, the bottom electrode material layer BE may be conductive metal oxide (e.g., ruthenium oxide). Although not limited by the present disclosure, the bottom electrode material layer BE may be formed as a single layer or multi layer conductive film, having a thickness ranging from about 1 to 200 nm. In some embodiments, a deposition tool may be used to deposit the bottom electrode material layer BE using a conformal deposition technique, such as CVD, ALD and PVD. However, for formation of trench segments having a desirable aspect ratio, ALD is preferred in order to precisely control the thickness of the conformal film.

Referring to FIG. 1H and FIG. 1I, in a subsequent step, a lithography process may be performed to pattern the bottom electrode material layer BE to form a first bottom electrode BE1 in the first trench segments 600, and a second bottom electrode BE2 in the second trench segments 700. The lithography process includes forming a photoresist layer PR2 over the interconnect structure 500, followed by a patterning process, such as an etch back process, to remove a portion of the bottom electrode material layer BE on the top surface 533S of the ESL 533. After performing the etch back process, a remaining of the bottom electrode material layer BE extends along the sidewalls 600S, 700S, and bottom surfaces 600B, 700B of the first and the second trench segments 600, 700, thereby forming the first bottom electrodes BE1 in the first trench segments 600, and the second bottom electrodes BE2 in the second trench segments 700. The removal of the bottom electrode material layer BE extending along the top surface 533S of the ESL 533, results in the bottom electrode material layer BE being non-continuous and spaced apart from each other between a trench segment 600, 700 and its adjacent trench segment 600, 700. In some embodiments, each of the first electrodes BE1 in each of the adjacent first trench segments 600 are separated from each other. In some embodiment, each of the second electrodes BE2 in each of the adjacent second trench segments 700 are separated from each other. In some embodiment, the first bottom electrode BE1 and the second bottom electrode BE2 may be formed concurrently by patterning the bottom electrode material layer BE in the first trench segments 600 and the second trench segments 700 in a single patterning process. In an alternative embodiment, the first bottom electrode BE1 and the second bottom electrode BE2 may be formed sequentially by patterning the bottom electrode material layer BE in separate patterning processes. In some alternative embodiments, the patterning of the bottom electrode material layer BE can be achieved by a Chemical Mechanical Polishing (CMP) process.

Referring to FIG. 1J, the method further includes forming an insulator layer IL over the first bottom electrodes BE1 in the first trench segments 600, the second bottom electrodes BE2 in the second trench segments 700, and the top surface 533S of the ESL 533. In some embodiments, the insulator layer IL continuously extends between each of the trench segments of the first trench segments 600 and second trench segments 700. In some embodiment, a top surface of a portion of the insulator layer IL extending along the ILD layer 520 in the first region 500a of the interconnect structure 500 may be substantially co-planar with a top surface of a portion of the insulator layer (IL) extending along the ILD layer 520 in the second region 500b of the interconnect structure 500. In some embodiment, the insulator layer IL is a high-k dielectric material such as zirconium oxide. Alternatively, the insulator layer IL may optionally include one or more layers of silicon oxide, silicon nitride, silicon oxynitride, aluminum oxide, hafnium silicates, tantalum oxide, hafnium oxide, hafnium zirconium oxide, titanium oxide, hafnium titanium oxide, hafnium silicon oxide, hafnium lanthanum oxide, yttrium oxide, barium strontium titanate, strontium titanate oxide, or combinations thereof. The insulator layer IL may have a thickness ranging between about 1 to about 100 nm, but may alternatively be thicker or thinner. In some embodiments, the insulator layer IL may have a dielectric constant of greater than 9.0. In some embodiments, the insulator layer IL may be formed as a single layer or multi layer structure. In some embodiments, a deposition tool may be used to deposit the insulator layer IL using a conformal deposition technique, such as CVD, ALD and PVD. However, for formation of trench segments having a desirable aspect ratio, ALD is preferred in order to precisely control the thickness of the conformal film.

Referring to FIG. 1K, the method further includes forming a top electrode material layer TE over the insulator layer IL. In some embodiment, the top electrode material layer TE fills up remaining spaces within the first trench segments 600 and the second trench segments 700 not occupied by the bottom electrodes BE1, BE2 and the insulator layer IL in the first trench segments 600 and the second trench segments 700, respectively. In some embodiments, the top electrode material layer TE is concurrently formed in the first trench segments 600 and the second trench segments 700 in a single deposition process. In an alternative embodiment, the top electrode material layer TE in the first trench segments 600 and the second trench segments 700 are formed sequentially in separate depositing processes. In some embodiment, the top electrode material layer TE may be formed as a single or multi layer film, having a thickness which is substantially the same as the thickness of the bottom electrode material layer BE. In some embodiment, the top electrode material layer TE may be a same material and deposited using a similar method as the bottom electrode material layer BE.

Referring to FIG. 1L and FIG. 1M, in some alternative embodiments, the first bottom electrode BE1 and the second bottom electrode BE2 may include a conformal electrode layer that conforms to the sidewalls 600S, 700S, and bottom surfaces 600B, 700B of the first and the second trench segments 600, 700. The insulator layer IL may include a conformal dielectric layer that conforms to the profile of the first and the second bottom electrodes BE1, BE2. The top electrode material layer TE may be formed as a conformal layer, conforming to the profile of the insulator layer IL. In these embodiments, a remaining area in the first and the second trench segments 600, 700 may be filled with an additional gap filler G, to avoid voids and seams to be formed in the deep trench segments 600, 700. In some embodiment, the gap filler G may be the same material as the top electrode material layer TE, including metal, and/or other suitable materials, such as metal composites, conductive metal oxide and metal nitride.

Referring to FIG. 1N and FIG. 1°, the method includes a lithography process to partially remove the top electrode material layer TE and the underlying insulator layer IL to form a patterned insulator layer IL′, a first top electrode TE1 in the first trench segment 600, and a second top electrode TE2 in the second trench segments 700, over the patterned insulator layer IL′. The lithography process includes forming a photoresist layer PR3 over the interconnect structure 500. In some embodiment, prior to the formation of the photoresist layer PR3, an ESL 534 may be formed over the top electrode material layer TE in the semiconductor structure 10. The lithography process may be performed to selectively pattern the ESL 534, the top electrode material layer TE and the underlying insulator layer IL, resulting in a recess 580 laterally between the first trench segments 600 in the first region 500a of the interconnect structure 500, and the second trench segments 700 in the second region 500b of the interconnect structure 500. In some embodiments, sidewalls of the ESL 534, the top electrode material layer TE and the insulator IL may form a sidewall 580S of the recess 580, wherein the sidewalls of the ESL 534, the top electrode material layer TE and the insulator IL may be substantially co-planar, and tapered towards the semiconductor substrate 300. The first bottom electrode BE1, the patterned insulator layer IL′ and the first top electrode TE1 collectively forms a memory cell storage capacitor 140 and the second bottom electrode BE2, patterned insulator layer IL′ and the second top electrode TE2 collectively forms a decoupling capacitor 200. In some embodiment, a top critical dimension TCD₁ may be substantially greater than a bottom critical dimension BCD₁ of the memory cell storage capacitor 140. In some embodiment, a top critical dimension TCD₂ may be substantially greater than a bottom critical dimension BCD₂ of the decoupling capacitor 200. In some alternative embodiments, the top critical dimension TCD₁ of the memory cell storage capacitor 140, may be substantially the same as the top critical dimension TCD₂ of the decoupling capacitor 200; and the bottom critical dimension BCD₁ of the memory cell storage capacitor 140, may be substantially the same as the bottom critical dimension BCD₂ of the decoupling capacitor 200.

In some embodiments, the memory cell storage capacitor 140 and the decoupling capacitor 200 may be formed as substantially u-shaped cross-sectional segments that are elongated in a vertical direction in the ILD layer 510, 520 of the interconnect structure 500, and are extending in the lateral direction substantially perpendicular to the vertical direction. The memory cell storage capacitor 140 and the decoupling capacitor 200 having a high aspect ratio trench type metal-insulator-metal (MIM) configuration, having a relatively large surface area for terminals (i.e., the top electrodes TE1, TE2 and the bottom electrodes BE1, BE2) separated by a relatively small amount of insulation (i.e., the insulator layer IL′). This advantageously creates a relatively large capacitance in the memory cell storage capacitor 140 and the decoupling capacitor 200. However, in alternative embodiments, the memory cell storage capacitor 140 and the decoupling capacitor 120, may have alternate structures (e.g., a planar capacitor structure, a bar-shaped capacitor structure, etc.)

Further referring to FIG. 1O, the memory cell storage capacitor 140 may be coupled to the underlying transistor 120 (described previously in FIG. 1B), resulting in a memory cell 100. The architecture of the memory cell 100 e.g., eDRAM device, is based on a 1T-1C cell that includes the transistor 120 and the storage capacitor 140. Within the 1T-1C cell, the transistor 120 (i.e., TFT) is coupled to the storage capacitor 140, and each storage capacitor 140 is disposed above a corresponding source terminal 121 of the transistor 140. In some embodiment, the storage capacitor 140 may be fabricated in the BEOL metallization stack 400 and electrically coupled to the transistor 120 through one or more metal interconnect layers formed in the BEOL.

As shown in FIG. 1°, the memory cell storage capacitor 140 and the decoupling capacitor 200 are laterally aligned with each other and can be located at any location within the BEOL metallization stack 400. In other words, the memory cell storage capacitor 140 and the decoupling capacitor 200 may be located within the same ILD layer 510, 520, and at a substantially same vertical location within the BEOL metallization stack 500. In some embodiments, the memory cell storage capacitor 140 and the decoupling capacitor 200 may be located within different ILD layers, and at different vertical locations in the BEOL metallization stack 400.

Referring to FIG. 1P, the method includes forming a spacer layer 590 extending along a top surface of the ESL 534 and covering the first top electrode TE1 of the memory cell storage capacitor 140, and the second top electrode TE2 of the decoupling capacitor 200. In some embodiments, the spacer layer 590 further extends into the recess 580 formed between the memory cell storage capacitor 140 and the decoupling capacitor 200. In some embodiments, the spacer layer 590 is deposited, such that a substantially uniform thickness of the spacer layer 590 is formed over the top surface of the ESL 534, and along the sidewalls 580S and a bottom surface 580B of the recess 580 over the interconnect structure 500. The spacer layer 590 may be formed of semiconductor materials, such as silicon carbide, silicon carbon nitride, silicon carbonate, aluminum oxide, silicon oxide, etc. The spacer layer 590 may be conformally formed by a variety of techniques, such as high density Ionized Metal Plasma (IMP) deposition, high density Inductively Coupled Plasma (ICP) deposition, sputtering, ALD, PVD, CVD, and the like. However, for formation of IC having a desirable conformity, throughput and cost-effectiveness, CVD is preferably used for forming the spacer layer 590 within the semiconductor structure 10.

Referring to FIG. 1Q, subsequently in the next step, a dielectric layer 595 may be blanket deposited over the spacer layer 590 and fill the recess 580. In some embodiment, the dielectric layer 595 fills an area of the recess 580 uncovered by the spacer layer 590, and covers the top surfaces of the first top electrode TE1 of the memory cell storage capacitor 140 and second top electrode TE2 of the decoupling capacitor 200. The dielectric layer 595 is of similar composition to the other dielectric layers 510, 520 within the semiconductor structure 10, including a low-k dielectric material, an ultra low-k dielectric material, etc., and formed by way of a deposition process similar to the other dielectric layers 510, 520 within the semiconductor structure 10.

Referring to FIG. 1R, in some embodiments, the method includes forming a first conductive feature 820 within the dielectric layer 595 over the memory cell 100 in the first region 500a of the interconnect structure 500. In some embodiments, the first conductive feature 820 extends within the dielectric layer 595 and engages the first top electrode TE1 of the memory cell storage capacitor 140. The first conductive feature 820 is physically and electrically coupled to the first top electrode TE1 of the memory cell storage capacitor 140. In some embodiments, a second conductive feature 840 may be formed within the dielectric layer 595 over the decoupling capacitor 200 in the second region 500b of the interconnect structure 500 of the semiconductor structure 10. In some embodiments, the second conductive feature 840 extends within the dielectric layer 595 and engages the second top electrode TE2 of the decoupling capacitor 200. The second conductive feature 840 is physically and electrically coupled to the second top electrode TE2 of the decoupling capacitor 200. In some embodiments, the second conductive feature 840 may be formed at a substantially same elevation as the first conductive feature 820. In an alternative embodiment, the first conductive feature 820 and the second conductive feature 840 may be vertically offset from each other.

In some embodiment, the memory cell storage capacitor 140 and the decoupling capacitor 200 may be coupled to various conductive contacts within the semiconductor structure 10. For examples, in some embodiments, the first top electrode TE1 of the memory cell storage capacitor 140 may be electrically coupled to the conductive contacts 540, 550, 560 through the first conductive feature 820 overlying the memory cell storage capacitor 140. In some embodiments, the bottom electrodes BE1, BE2 of the memory cell storage capacitor 140 and the decoupling capacitor 200 may be in contact with lower metal layers, such as the capacitor via 128 in the transistor 120. In some embodiment, the bottom electrode BE1 of the memory cell storage capacitor 140 may be coupled to the source region 121 of the transistor 120 of the memory cell 100 through the capacitor via 128. In some embodiment, the capacitor via 128 may be electrically connected to the first and the second conductive features 820, 840 within the semiconductor structure 10. The first and the second conductive features 820, 840 are of similar composition to the conductive contacts 540, 550, 560, including conductive materials, such as aluminum, gold, silver, tungsten, copper, tantalum, tantalum nitride, titanium, titanium nitride, cobalt, tungsten nitride, molybdenum, ruthenium, etc. However, the disclosure is not limited thereto. In some alternative embodiments, the first and the second conductive features 820,840 may include a multi-layered gap fill structure, including a barrier layer (e.g., titanium nitride) and a gap-filling layer (e.g., copper). In some embodiments, the first and the second conductive features 820,840 may be formed by a deposition process similar to the conductive contacts 540, 550, 560 within the semiconductor structure 10.

The memory cell 100 implemented in the BEOL may be interconnected to peripheral circuitry implemented in with CMOS logic fabricated in the FEOL and extending within the dielectric layers 510, 520, 595 of the semiconductor structure 10. The integration of the decoupling capacitor 200 in the BEOL including the memory cell, is configured to mitigate switching noise on a power supply line caused by switching of logic devices within the semiconductor structure 10. For example, the decoupling capacitor 200 may be used to reduce switching noise due to a voltage drop on a power supply line caused by simultaneous switching of input/output (I/O) and core circuits within the semiconductor structure 10. Without decoupling capacitor 200, the switching noise may increase signal delay, thereby reducing the operating frequency of the semiconductor structure 10, and inadvertently causing state transitions in logic circuits within the semiconductor structure 10.

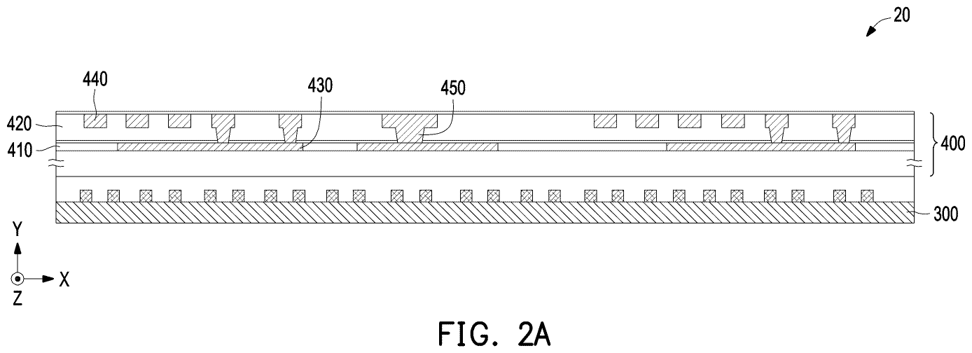

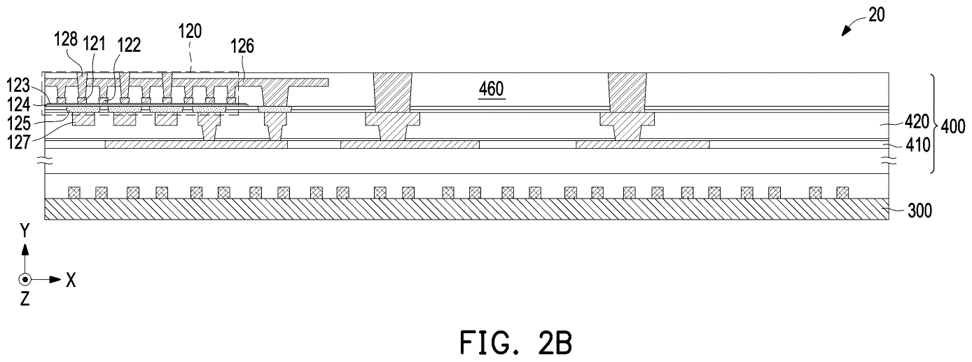

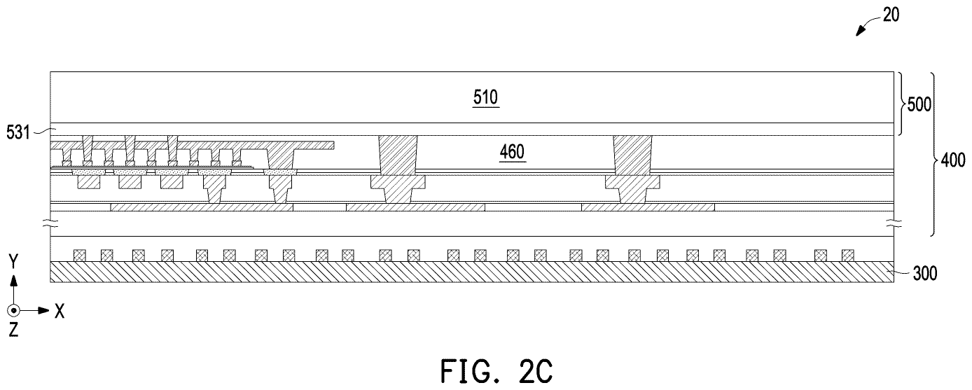

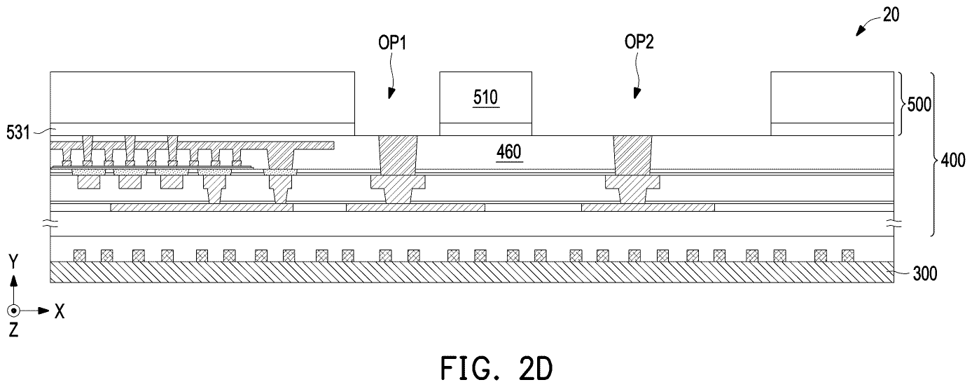

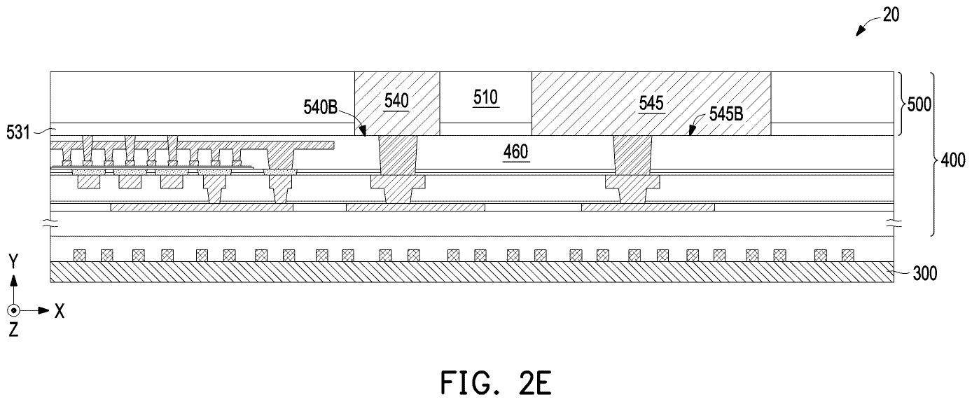

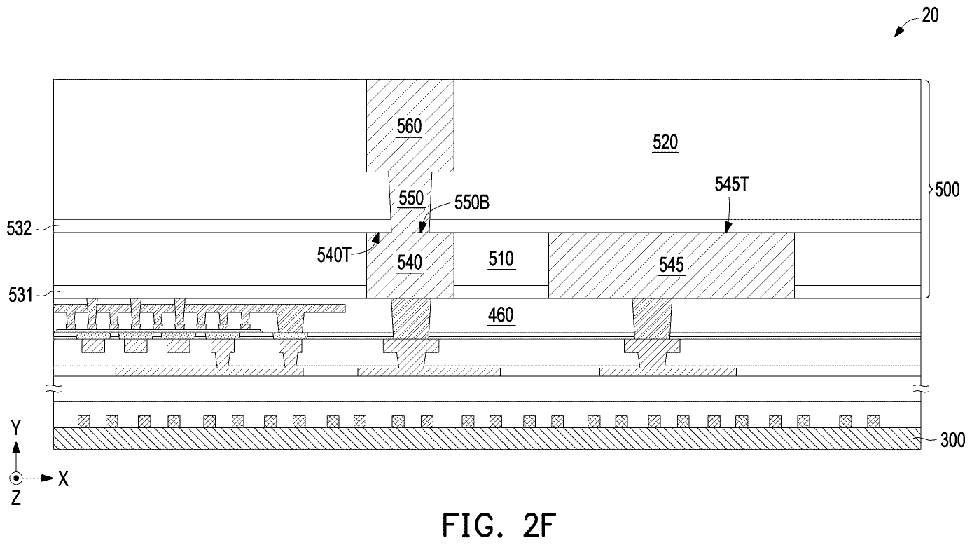

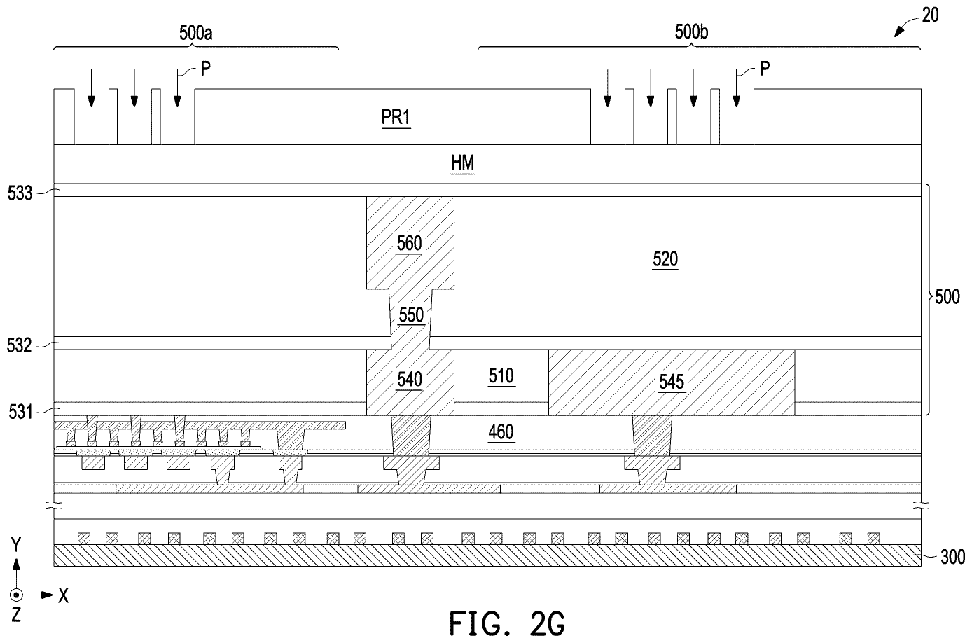

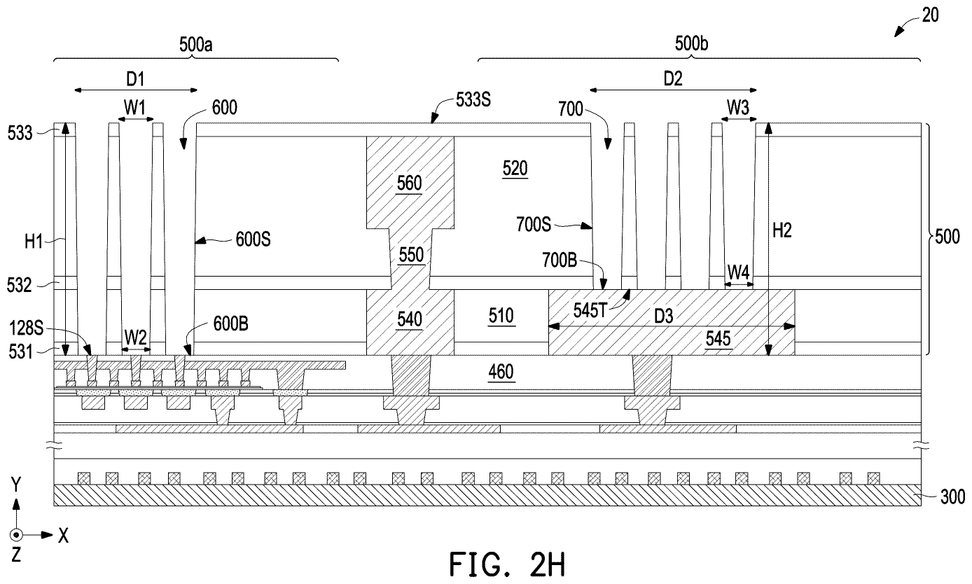

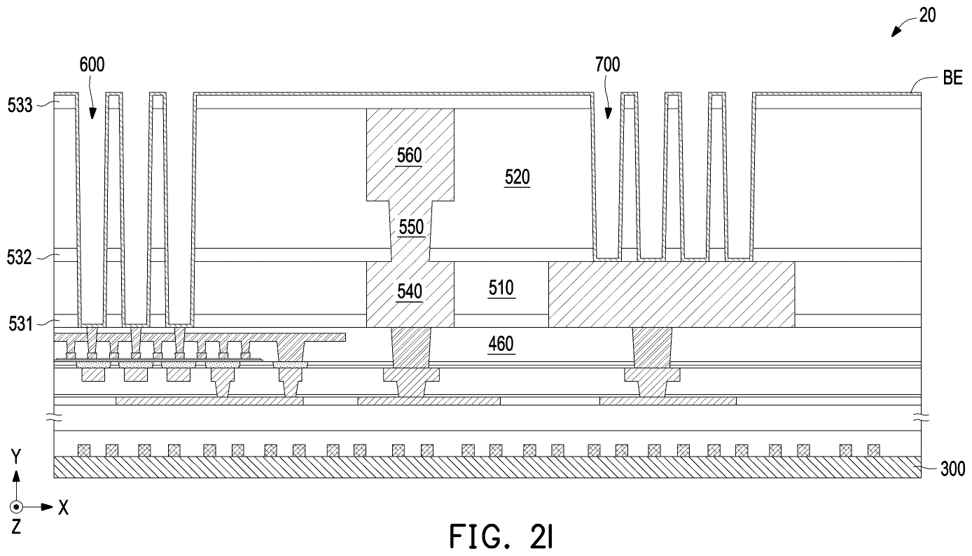

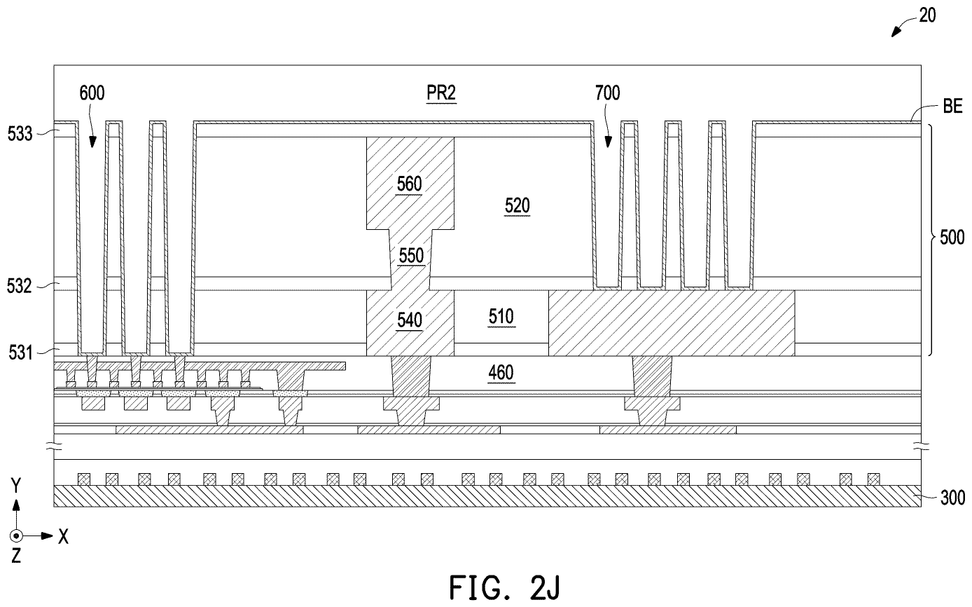

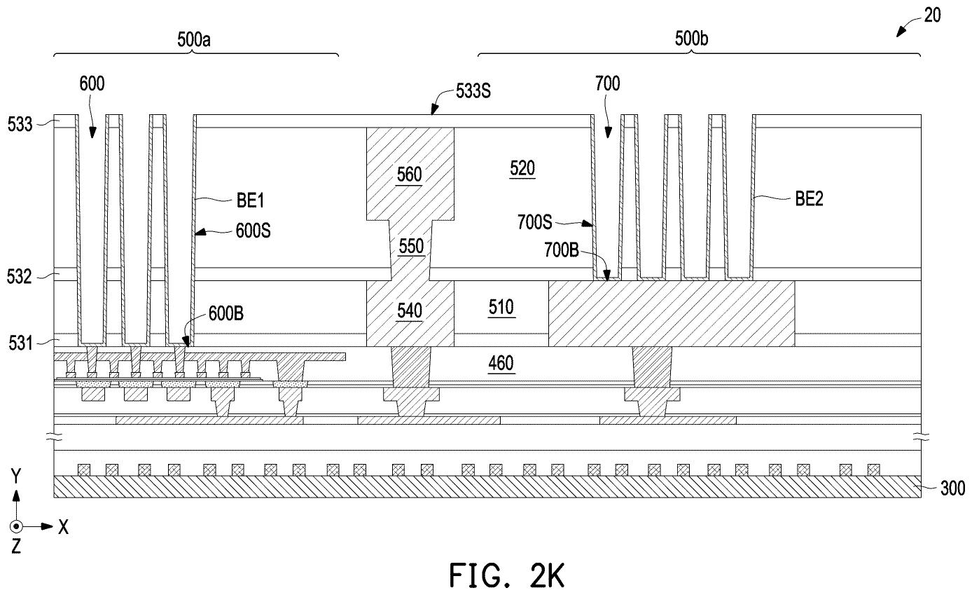

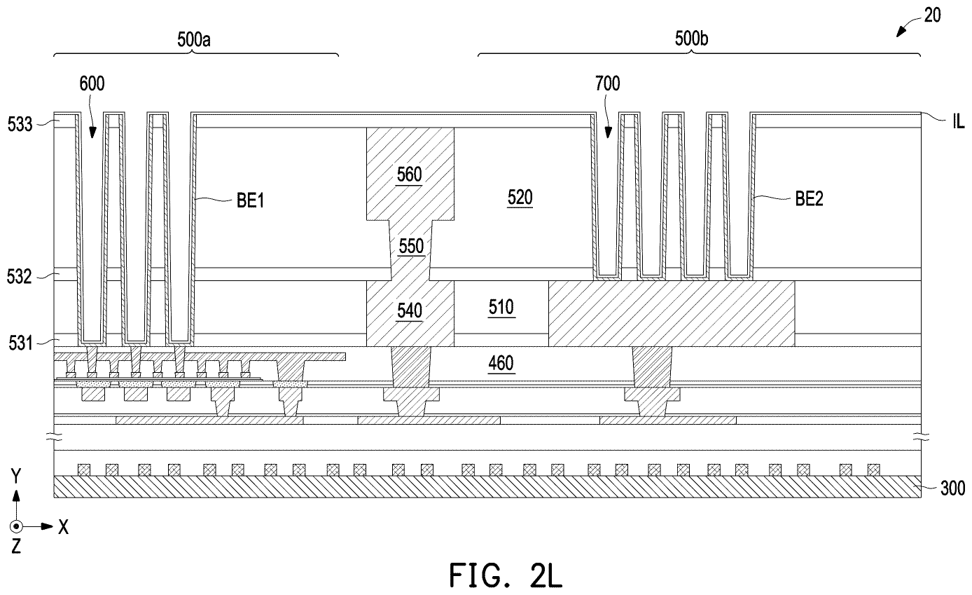

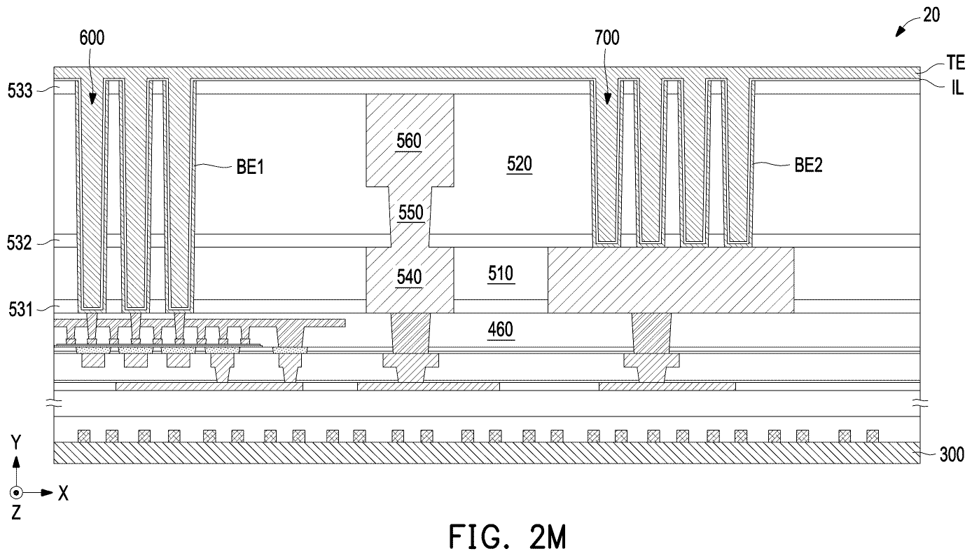

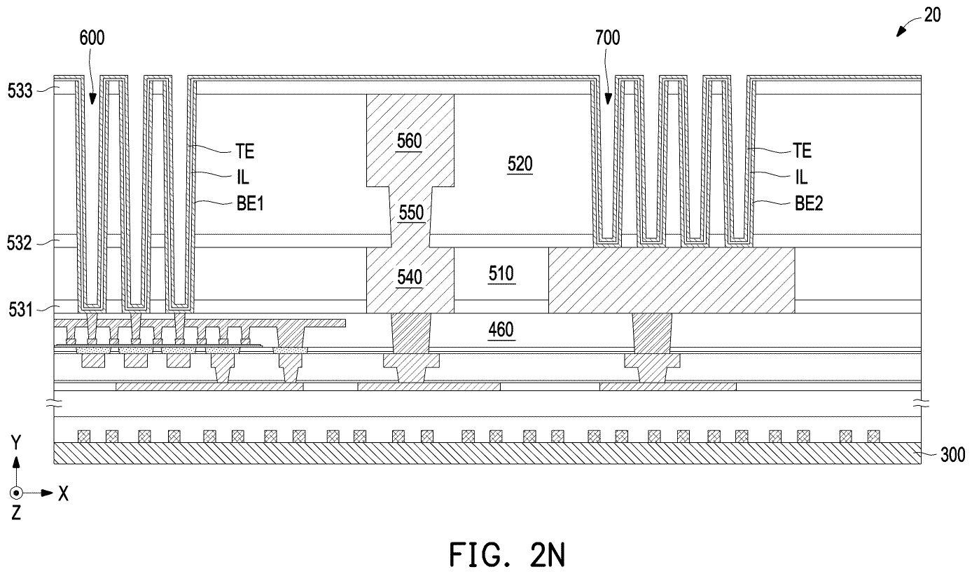

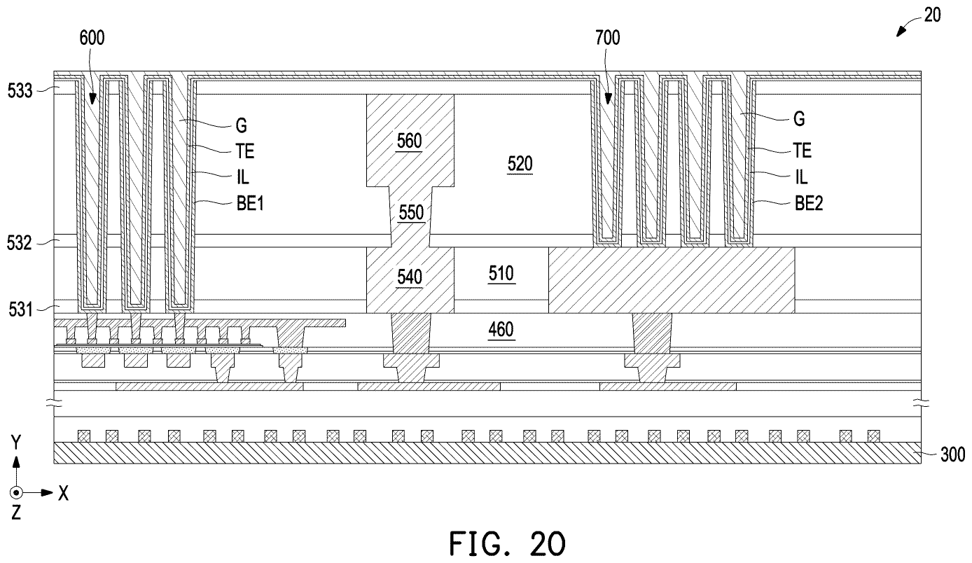

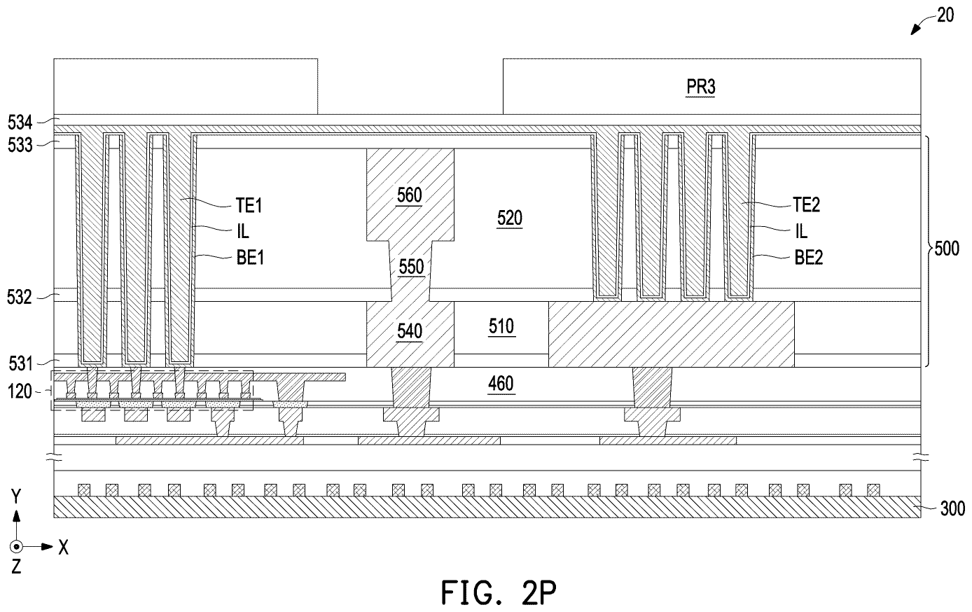

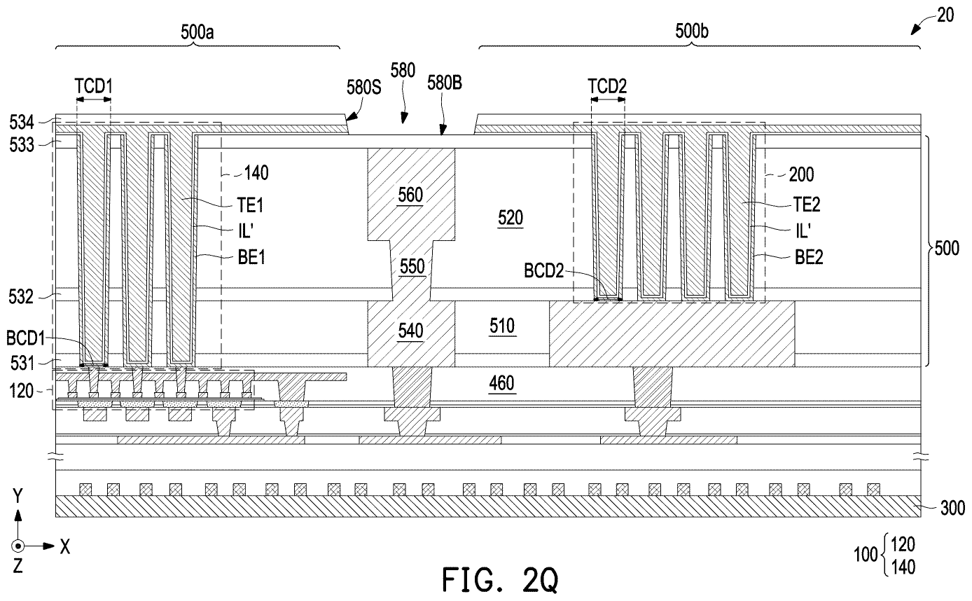

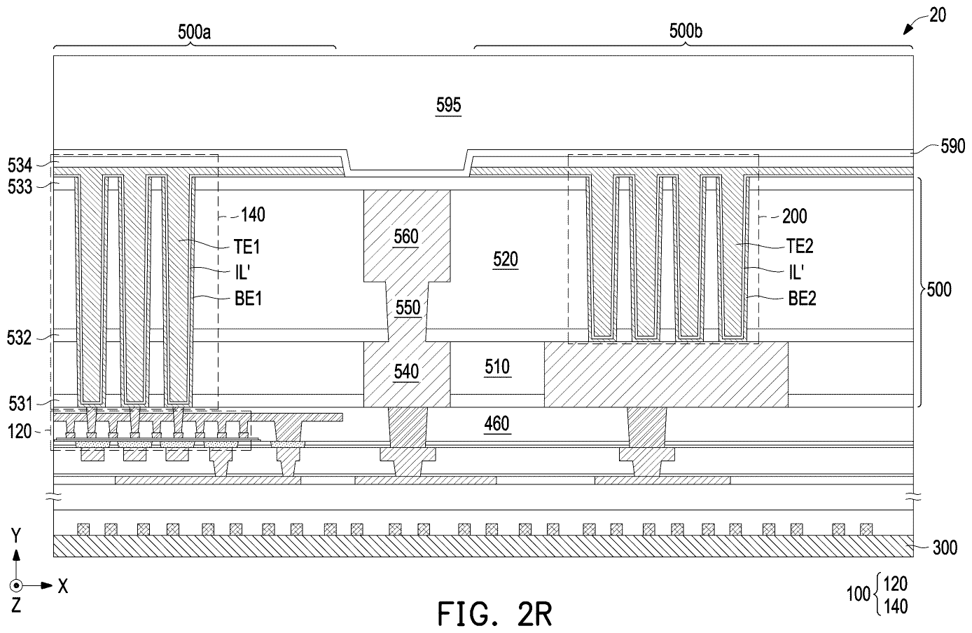

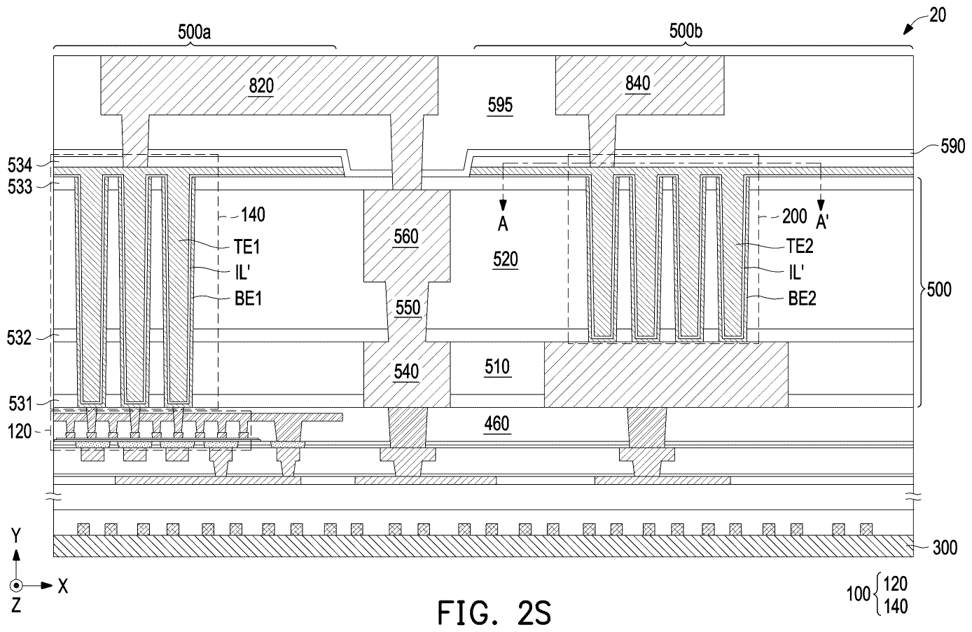

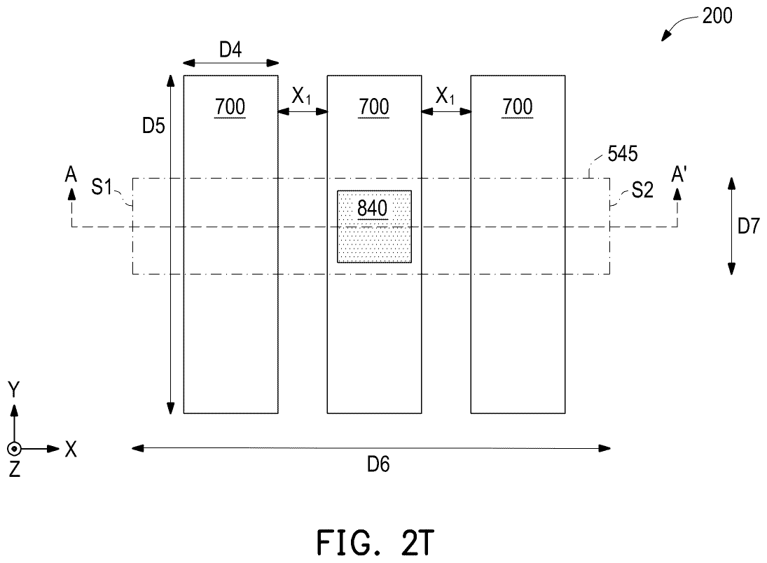

FIG. 2A through FIG. 2T are schematic cross-sectional views illustrating structures produced at various stages of a manufacturing process of forming a memory cell with a decoupling capacitor, in portion or entity, in accordance with some alternative embodiments of the present disclosure.

FIG. 2A and FIG. 2B, are schematic cross-sectional views illustrating an exemplary structure of a semiconductor structure 20 including a memory cell and a decoupling capacitor, in accordance with some alternative embodiments of the present disclosure. In some embodiments, the process steps and materials used for forming the exemplary structure are similar to the process steps and materials described with reference to FIG. 1A and FIG. 1B and in the previous paragraphs, so the detailed descriptions thereof shall be omitted herein. Similar or substantially the same structural parts or elements may be labelled with similar or the same reference numbers as FIG. 1A and FIG. 1B, for illustration purposes.

Referring to FIG. 2C through FIG. 2E, the method includes forming an interconnect structure 500 within the BEOL metallization stack 400 over the substrate 300. The interconnect structure 500 includes a ILD layer, wherein the ILD layer includes a first ILD layer 510 over the substrate 300, and a second ILD layer 520 over the first ILD layer 510. The interconnect structure 500 further includes a first ESL 531 formed between the ILD layer 510 and the substrate 300. A photoresist layer (not shown) is placed over the ILD layer 510 and the first ESL 531, and a lithography process is performed to create a first opening OP1 and a second opening OP2 through the ILD layer 510 and the first ESL 531. Subsequently, a first conductive contact 540 and a second conductive contact 545 may be formed in the first opening OP1 and the second opening OP2, respectively. In some embodiments, the first and the second conductive contacts 540, 545 may be concurrently formed in a single process step. In some embodiment, the second conductive contact 545 is formed laterally adjacent to the first conductive contact 540, and at a substantially same elevation as the first conductive contact 540, such that a bottom surface 540B of the first conductive contact 540 substantially levels with a bottom surface 545B of the second conductive contact 545 in the interconnect structure 500.

Referring to FIG. 2F, after the formation of the first and the second conductive contacts 540, 545 in the ILD layer 510, a second ESL 532 is formed over ILD layer 510 and the conductive contacts 540, 545. A second ILD layer 520 is deposited over the second ESL 532. Next a third conducive contact 550, 560 may be formed in the second ILD layer 520, by a dual damascene process, as similarly described in FIG. 1C and FIG. 1D. In some embodiment the third conductive contact 550, 560 may be formed over the first conductive contact 540, such that the first and the third conductive contacts 540, 550, 560 are stacked alternatingly and vertically aligned with each other along the interconnect structure 500. In some embodiment, the third conductive contacts 550, 560 may include a metal via 550 and a metal line 560. The first conductive contact 540 may be disposed at a first feature height over the top surface of the substrate 300, the metal via 550 of the third conductive contact is disposed at a first via height over the top surface of the substrate 300. The first via 550 is coupled to the first conductive contact 540, and the first via height is substantially greater than the first feature height. In some embodiment, the metal line 560 may be disposed at a second feature height over the top surface of the substrate 300. The metal line 560 is coupled to the first via 550, and the second feature height being substantially greater than the first via height. In some embodiment, the second conductive contact 545 may be spaced laterally apart from the first and the third conductive contacts 540, 550, 560, such that a top surface 545T of the second conductive contact 545 may be substantially co-planar with a bottom surface 550B of the first via 550, and a top surface 540T of the first conductive contact 540.

Referring to FIG. 2G and FIG. 2H, the method is followed by a lithography process to form a plurality of trench segments in the interconnect structure 500. The lithography process includes forming a hard mask layer HM and a photoresist layer PR1 over the interconnect structure 500, followed by a patterning step P to etch one or more recesses into a first region 500a and a second region 500b of the interconnect structure 500, thereby forming one or more first trench segments 600 and second trench segments 700 within the ILD layers 510, 520. In some embodiment, the first trench segments 600 extend through the ILD layer 510, 520 of the interconnect structure 500 in a first direction (y-direction), and stop once a top surface of the ILD layer 460 underlying the interconnect structure 500 is reached, and exposing a top surface 128S of the underlying capacitor via 128. In some embodiments, the second trench segments 700 may be formed laterally adjacent to the first trench segments 600 in a second direction (x-direction) substantially perpendicular to the first direction (y-direction). In some embodiments, the second trench segments 700 extend through the ILD 520 of the interconnect structure 500 towards the second conductive contact 545, stopping once the second conductive contact 545 is reached, and exposing the top surface 545T of the second conductive contact 545. The photoresist PR1 is stripped after the first and the second trench segments 600, 700 are formed. As seen in FIG. 2H, a plurality of the first trench segments 600 are laterally spaced from a plurality of the second trench segments 700 by the ILD layer 510, 520 of the interconnect structure 500. In some embodiments, the first trench segments 600 and the second trench segments 700 are concurrently defined in a single patterning process. In an alternative embodiment, the first trench segments 600 and the second trench segments 700 are formed sequentially in separate patterning processes.

Further referring to FIG. 2H, in some embodiments, the first and the second trench segments 600, 700 are elongated in parallel in the first direction (y direction), such that the plurality of trench segments 600, 700 have individual greatest dimension (e.g., height) in the y-direction. Further, each of the first trench segments 600, and each of the second trench segments 700 may be evenly spaced from each other in the second direction (x-direction) orthogonal to the first direction (y-direction). In alternative embodiments, the vertical height and spacing between the plurality of trench segments 600, 700 may be non-uniform and/or varied.

Further referring to FIG. 2H, in some embodiments, the first trench segments 600 in the first region 500a of the interconnect structure 500 may have a tapered shape when viewed in cross-section. A top portion of each of the first trench segments 600 has a lateral width W₁ measured in a direction parallel to a top surface of the substrate 300, which is substantially greater than a lateral width W₂ at a bottom portion of each of the first trench segments 600. Similarly, the second trench segments 700 in the second region 500b of the interconnect structure 500 may also have a tapered shape when viewed in cross-section. A top portion of each of the second trench segments 700 has a lateral width W₃ which is substantially greater than a lateral width W₄ at a bottom portion of each of the second trench segments 700. As further shown in FIG. 2H, the vertical height H₁ of the first trench segments 600, may be substantially greater than the vertical height H₂ of the second trench segments 700. In some embodiments, the bottom portions of the first trench segments 600 and the second trench segments 700 may be vertically offset and at a different elevation within the IDL layers 510, 520 of the interconnect structure 500. In some embodiment, the lateral width W₁ of the top portion of each of the first trench segments 600 may be substantially smaller than the lateral width W₃ of the top portion of each of the second trench segments 700. In some embodiment, the lateral width W₂ of the bottom portion of each of the first trench segments 600 may be substantially smaller than the lateral width W₄ of the bottom portion of each of the second trench segments 700. In some embodiments, a lateral distance D₁ between a plurality of the first trench segments 600 is substantially smaller than the vertical height H₁ of the first trench segments 600. In some embodiments, a lateral distance D₂ between a plurality of the second trench segments 700 is substantially smaller than the vertical height H₂ of the second trench segments 700. However, the disclosure is not limited thereto. In some embodiments, the vertical heights H₁, H₂ and the lateral distance D₁, D₂ may be independent of each other, and adjusted according to design or performance requirements. The lateral distance D₁ between the plurality of the first trench segments 600 may be varied with the lateral distance D₂ between the plurality of the second trench segments 700. In some embodiments, the plurality of second trench segments 700 may be located within the span of the second conductive contact 545. In other words, the lateral distance D₂ between the plurality of the second trench segments 700 may be substantially smaller than a lateral width D3 of the second conductive contact 545. In some embodiments, an aspect ratio of the first and the second trench segments 600, 700 may be in a range of 2 to 100. The lateral width W₁, W₃ (i.e., critical dimension) of the first trench segments 600 and second trench segments 700 may be in a range of 10 nm to 800 nm. The vertical height H₁ and the vertical height H₂ of the first and the second trench segments 600, 700 respectively, may be in a range of 50 nm to 15 μm. It should be noted that the number of first trench segments 600 and the number of second trench segments 700 illustrated in FIG. 2H is for the sake of brevity, from the perspective of the manufacturing process, the first and the second trench segments 600, 700 may constitute more or less trench segments, the number and arrangement of the trench segments may be adjusted according to design requirement. It should also be noted that the dimensions (i.e., vertical height, width) of the first and the second trench segments 600, 700 may be adjusted according to design and performance requirements.

Referring to FIG. 2I through FIG. 2S, the process steps and materials used for forming the exemplary structures of semiconductor structure 20 as illustrated in FIG. 2I through FIG. 2S, are described with reference to FIG. 1G through FIG. 1R and in the previous paragraphs, so the detailed descriptions thereof shall be omitted herein. Similar or substantially the same structural parts or elements may be labelled with similar or the same reference numbers as FIG. 1G through FIG. 1R, for illustration purposes.

As further shown in FIG. 2I, in some embodiments, the bottom electrode material layer BE in the second trench segments 700 may be in contact with the exposed top surface 545T of the second conductive contact 545. Further referring to FIG. 2K, a bottom surface of the first bottom electrode in the first trench segments 600 may be at a different elevation as a bottom surface of the second bottom electrode in the second trench segments 700. In an embodiment, the bottom surface of the first bottom electrode in the first trench segments 600 may be recessed relative to the second bottom electrode in the second trench segments 700. Referring to FIG. 2Q, in some embodiment, the top critical dimension TCD₁ may be substantially greater than the bottom critical dimension BCD₁ of the memory cell storage capacitor 140. In some embodiment, the top critical dimension TCD₂ may be substantially greater than the bottom critical dimension BCD₂ of the decoupling capacitor 200. In some alternative embodiments, the top critical dimension TCD₁ of the memory cell storage capacitor 140, may be substantially smaller than the top critical dimension TCD₂ of the decoupling capacitor 200; and the bottom critical dimension BCD₁ of the memory cell storage capacitor 140, may be substantially smaller than the bottom critical dimension BCD₂ of the decoupling capacitor 200. By increasing the critical dimension of the decoupling capacitor 200, a degree of contact between the bottom electrode BE2 of the decoupling capacitor 200 and the underlying conductive contact 545 will be increased, thereby reducing the effective series resistance (ESR) and increasing the capacitance value of the decoupling capacitor 200.

FIG. 2T is a schematic top layout view illustrating a portion of the decoupling capacitor 200, according to some embodiments of the present disclosure, wherein the top layout view is taken along a line A-A′ depicted in the cross-sectional view of FIG. 2S. For clarity of illustration, certain features, for example the top electrode TE2, the insulator layer IL′ and the bottom electrode BE2 are omitted and certain other features, for example the conductive contact 545 connected to and underlying the bottom electrode BE2 of the trench segments 700 is shown with dashed lines. As shown in FIG. 2T, the conductive contact 545 underlying the decoupling capacitor 200 partially overlaps with the plurality of trench segments 700 of the decoupling capacitor 200 and is at a center of the plurality of trench segments 700 in the y-direction. In some embodiments, the conductive feature 840 may be formed above the trench segments 700, and overlaps with the conductive contact 545 underlying the trench segments 700. In some embodiments, the trench segments 700 may be arranged in an approximately hollow quadrilateral layout in a top view of the decoupling capacitor 200. The perimeter of the trench segments 700 may have a x-direction width (dimension D4) and a y-direction width (dimension D5). The x-direction width D4 of each of the plurality of trench segments 700 is substantially the same from a first side S1 of the conductive contact 545 to a second side S2 of the conductive contact 545 opposing the first side S1, and wherein each of the plurality of trench segments 700 is laterally spaced by a substantially uniform distance of X₁. In some embodiments, the conductive contact 545 may also be arranged in an approximately quadrilateral layout, and the perimeter of the conductive contact 545 may have a x-direction width (dimension D6) and a y-direction width (dimension D7), wherein the x-direction width D6 of the conductive contact 545 is substantially greater than the x-direction width D4 of the trench segment 700, and the y-direction width D7 of the conductive contact 545 is substantially smaller than the y-direction width D5 of the trench segment 700. In this way, the bottom surfaces of the bottom electrodes BE2 in each of the trench segments 700 can be completely in contact with the underlying conductive contact 545 in the x-direction, thereby reducing the ESR and increasing the capacitance value of the decoupling capacitor 400. In some alternative embodiments, the y-direction width D7 of the conductive contact 545 may be substantially the same or greater than the y-direction width D5 of the trench segment 700, such that entire bottom surfaces of the trench segments 700 may be in contact with the underlying conductive contact 545, which further reduces the ESR and enhances the capacitance value of the decoupling capacitor 400. In alternative embodiments, the trench segment 700 and the conductive contact 545 may have some other non-polygonal shapes (e.g., elliptical, circular, oval, etc.) or polygonal shape (e.g., triangle, hexagon, etc.). Further in an alternative embodiment, trench segment 700 and the conductive contact 545 may have some other suitable sizes and shapes. The shapes and sizes of the trench segment 700 and the conductive contact 545 may be adjusted according to design and performance requirements.

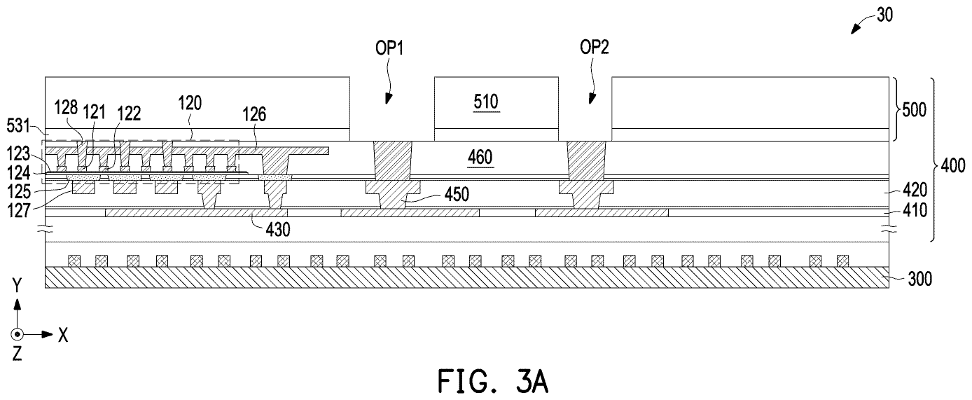

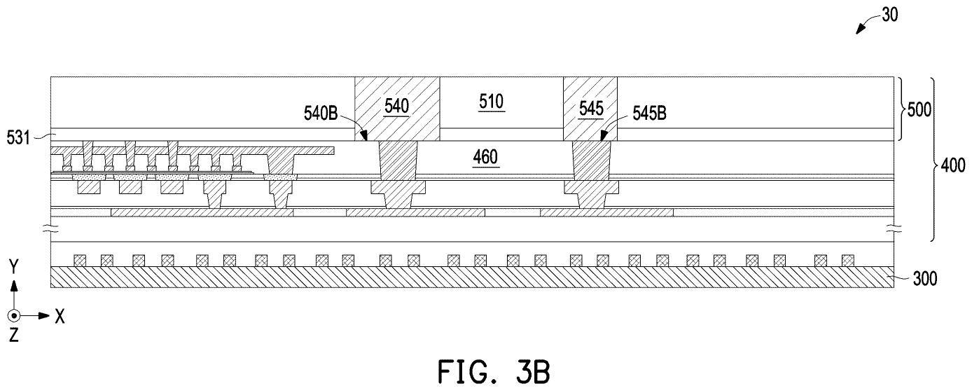

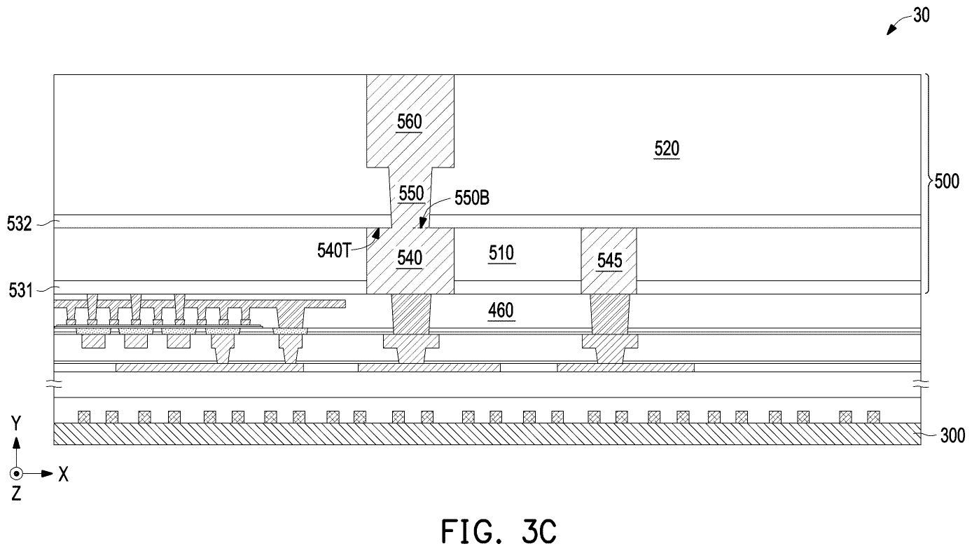

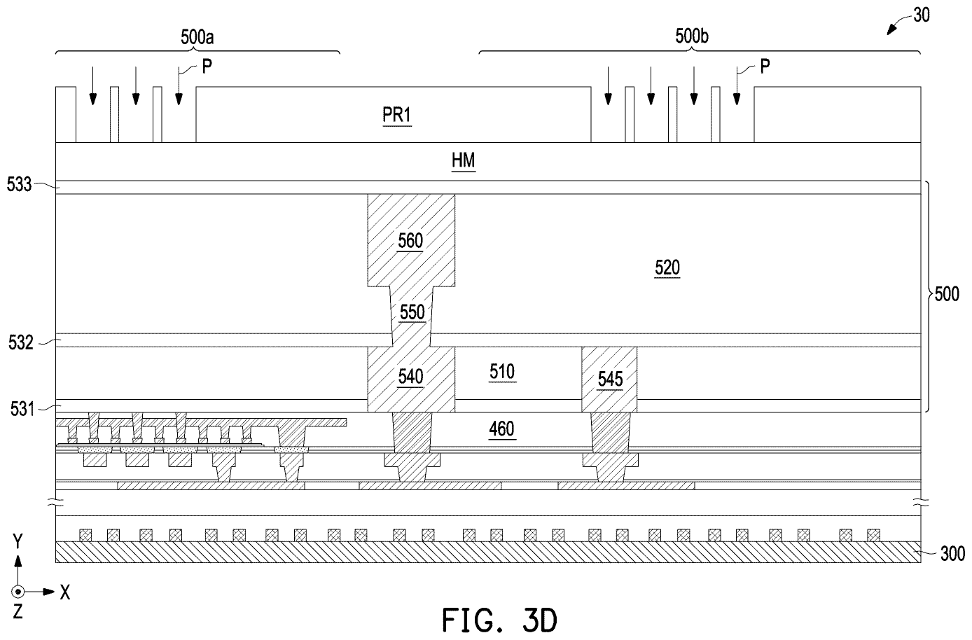

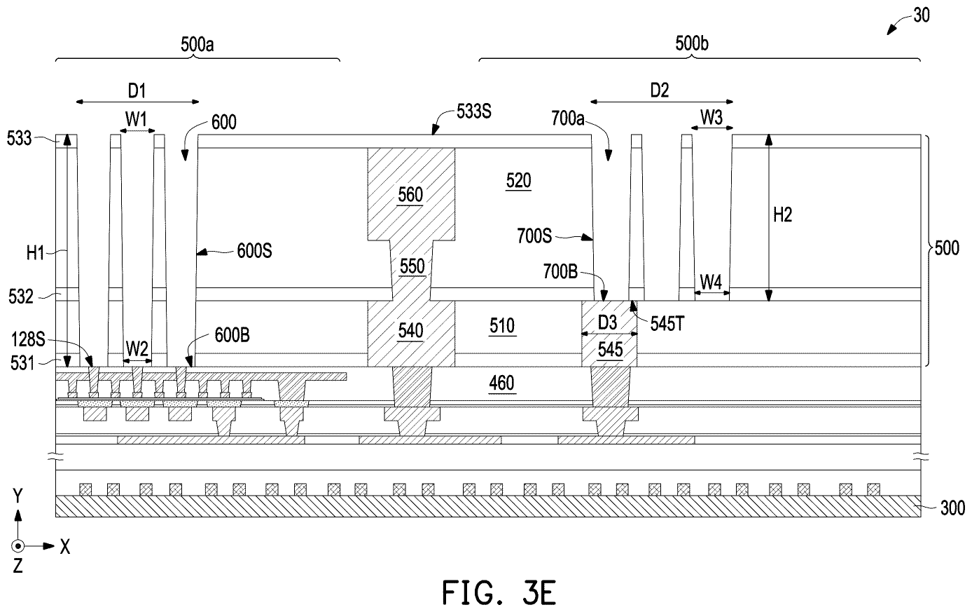

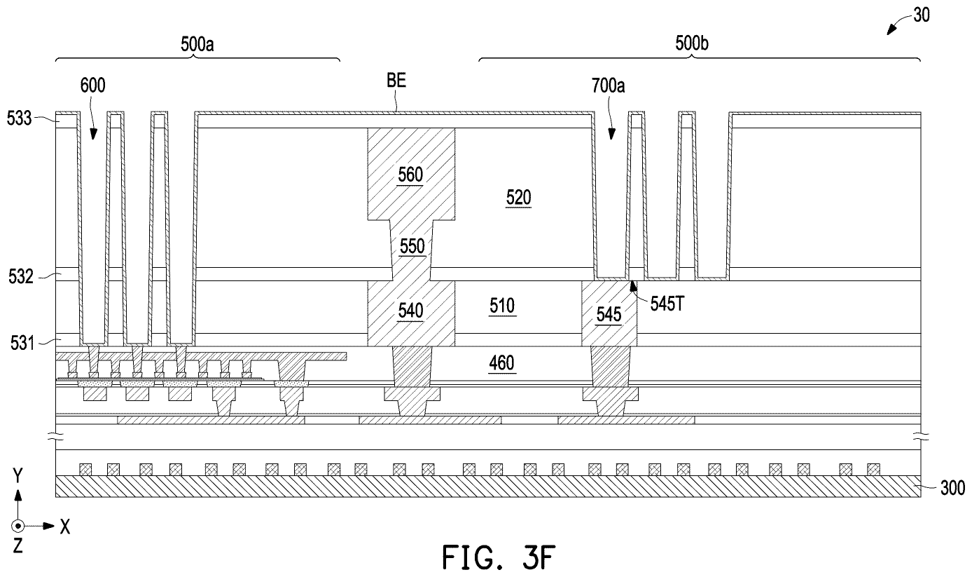

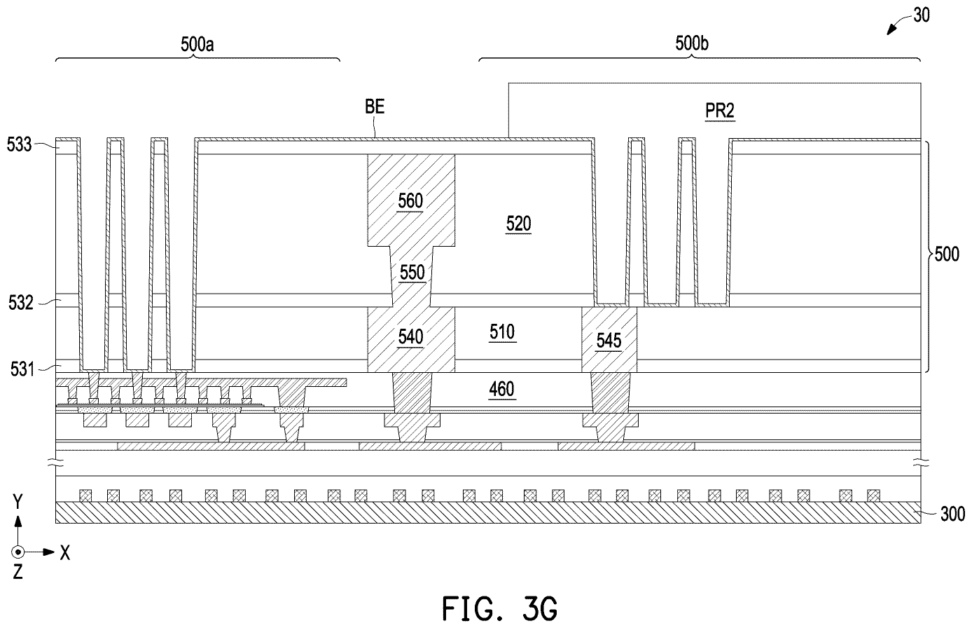

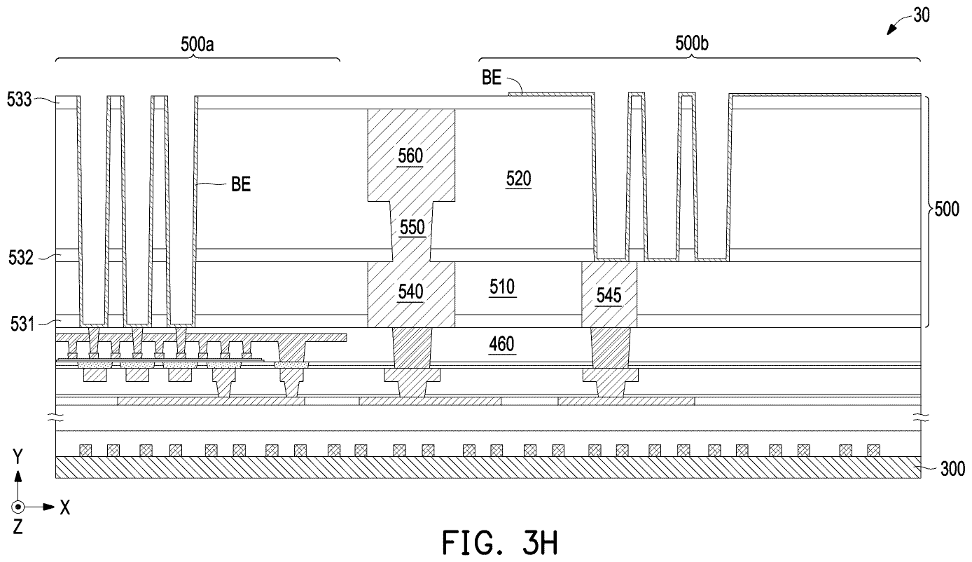

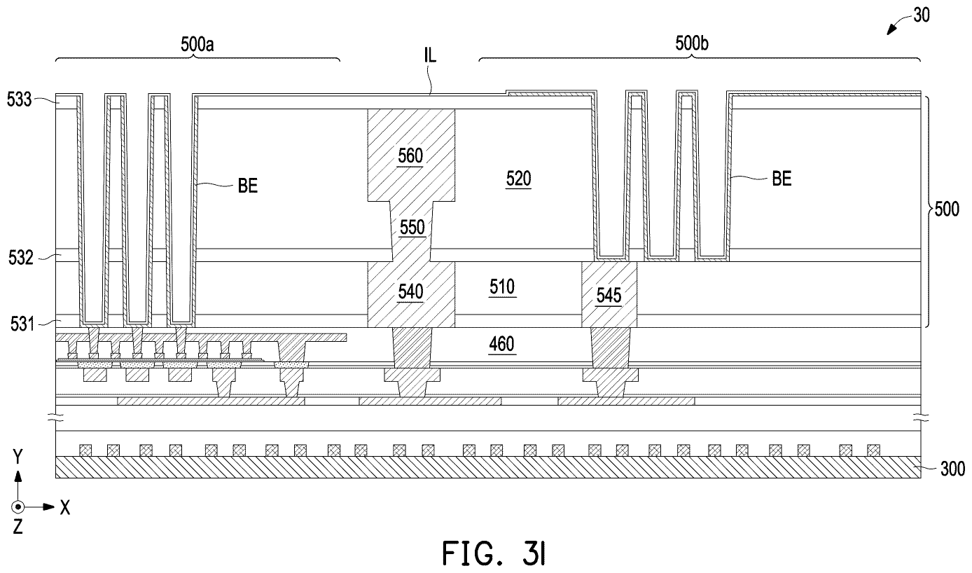

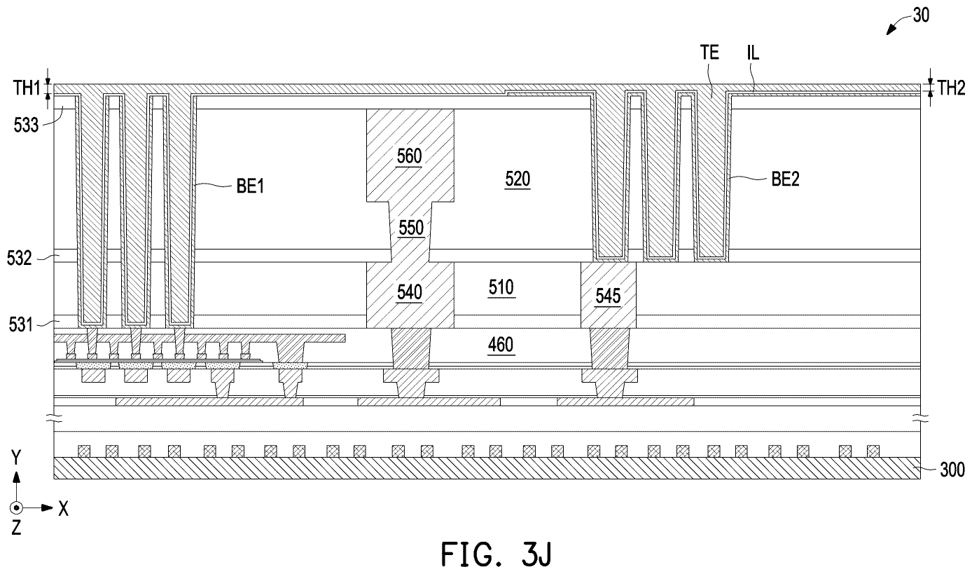

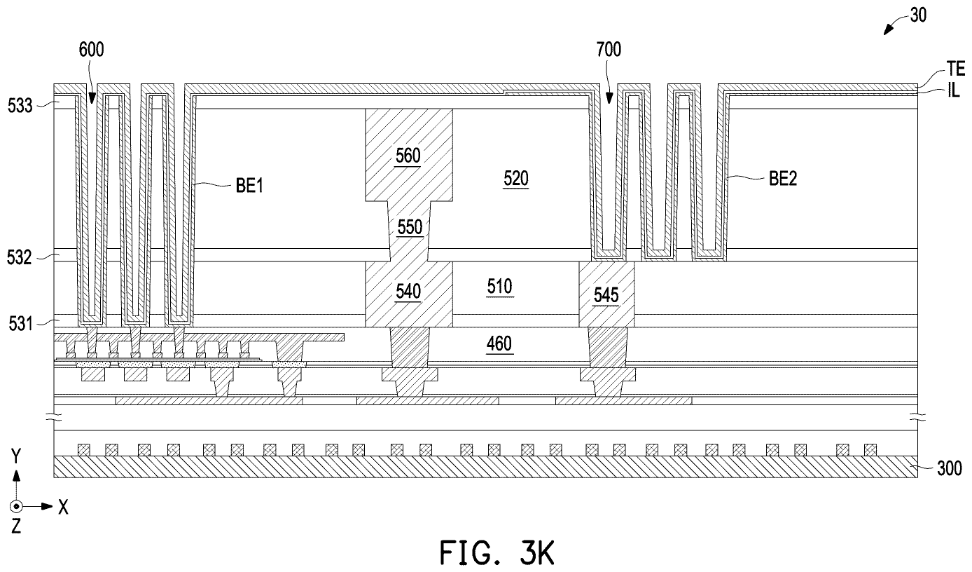

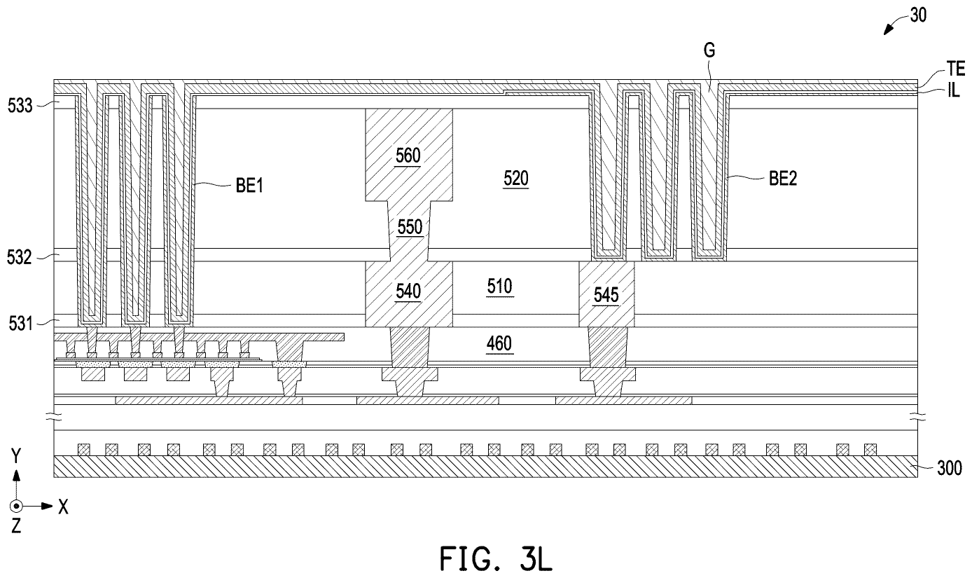

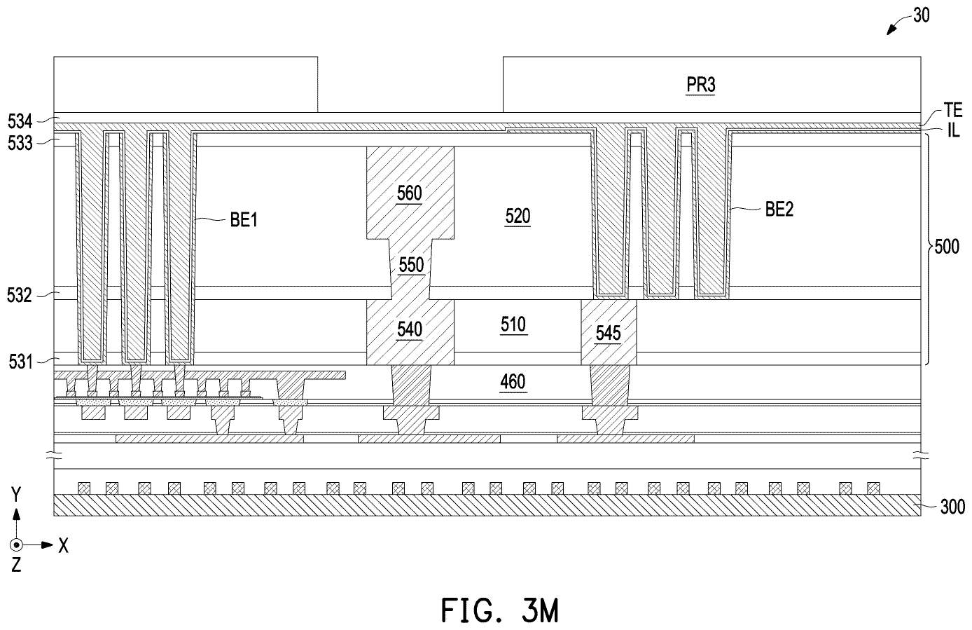

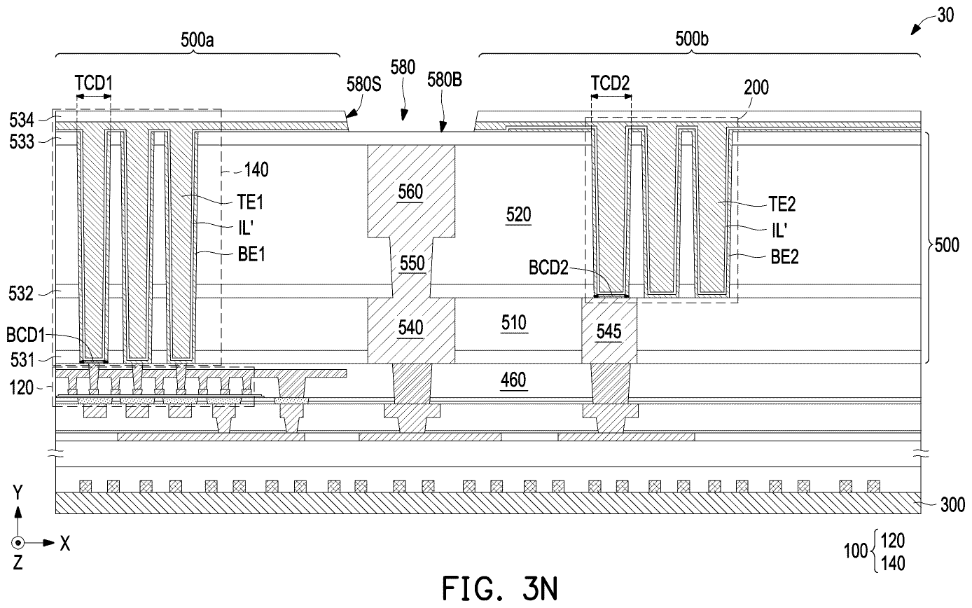

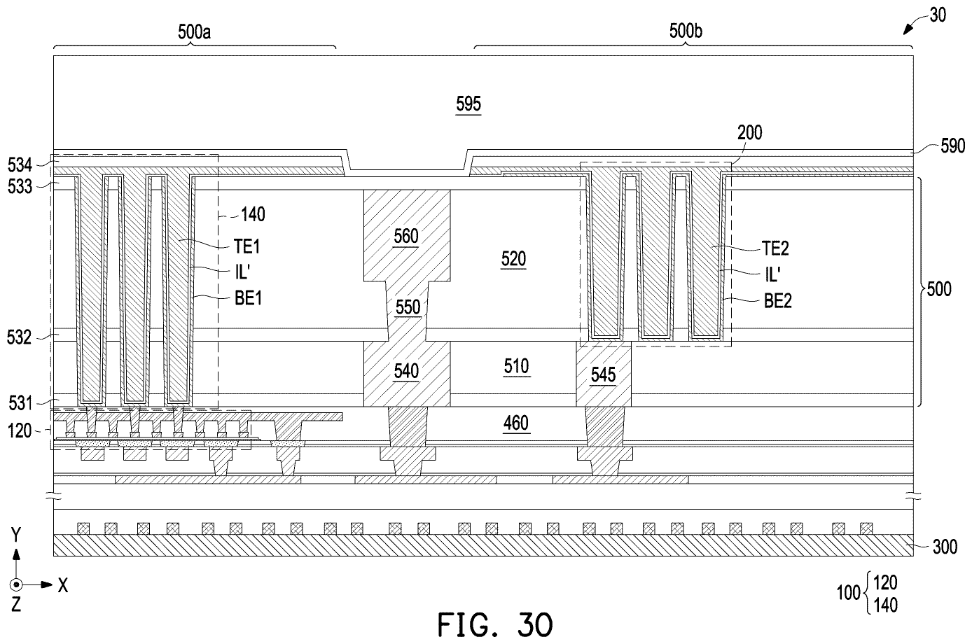

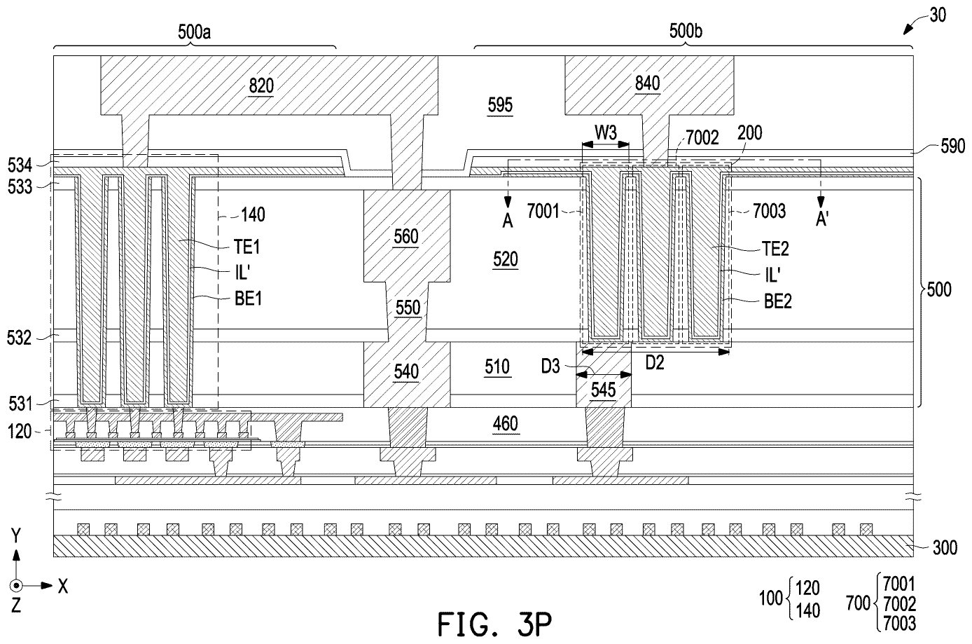

FIG. 3A through 3P are schematic cross-sectional views illustrating structures produced at various stages of a manufacturing process of forming a memory cell with a decoupling capacitor, in portion or entity, in accordance with some alternative embodiments of the present disclosure.

FIG. 3A through FIG. 3E are schematic cross-sectional views illustrating an exemplary structure of a semiconductor structure 30 including a memory cell and a decoupling capacitor, in accordance with some alternative embodiments of the present disclosure. In some embodiments, the process steps and materials used for forming the exemplary structure are similar to the process steps and materials described with reference to FIG. 2A through FIG. 2H and in the previous paragraphs, so the detailed descriptions thereof shall be omitted herein. Similar or substantially the same structural parts or elements may be labelled with similar or the same reference numbers as FIG. 2A through FIG. 2H, for illustration purposes.

Further referring to FIG. 3E, unlike the semiconductor structure 20, the conductive contact 545 of the semiconductor structure 30 is formed having a lateral width D3 substantially smaller than the lateral distance D2 between the plurality of second trench segments 700. In some embodiments, the plurality of second trench segments may include a first opening 700a at the periphery of the second trench segments 700, and the conductive contact 545 may be disposed at a center of the first opening 700a, in the y-direction. However, it should be noted that the conductive contact 545 may be disposed at any other suitable locations along the bottom surface 700B of the second trench segments 700.

Referring to FIG. 3F, the process includes forming a bottom electrode material layer BE over the first and the second trench segments 600, 700. In some embodiments, the process steps and materials used for forming the exemplary structure are similar to the process steps and materials described with reference to FIG. 1G and FIG. 2I and in the previous paragraphs, so the detailed descriptions thereof shall be omitted herein. Similar or substantially the same structural parts or elements may be labelled with similar or the same reference numbers as FIG. 1G and FIG. 2I, for illustration purposes.

Referring to FIG. 3G and FIG. 3H, a lithography process may be performed to pattern the bottom electrode material layer BE to form a first bottom electrode BE1 in the first trench segments 600, and a second bottom electrode BE2 in the second trench segments 700. The lithography process includes placing a photoresist layer PR2 over the second region 500b of the interconnect structure 500 followed by a patterning process, such as an etch back process, to remove a portion of the bottom electrode material layer BE on the top surface 533S of the ESL 533 within the first region 500a of the interconnect. In some alternative embodiments, the patterning of the bottom electrode material layer BE can be achieved by a CMP process. After the etch back process, a remaining of the bottom electrode material layer BE extends along the sidewalls 600S, bottom surfaces 600B of the first trench segments 600, thereby forming the first bottom electrodes BE1 in the first trench segments 600. The removal of the bottom electrode material layer BE extending along the top surface 533S of the ESL 533 results in the bottom electrode material layer BE being non continuous and spaced apart from each other between a trench segment 600 and its adjacent trench segments 600 within the first region 500a of the interconnect structure. The portion of the bottom electrode material layer BE over the second region 500b of the interconnect structure 500 remain intact and continuously extends along the top surface 533S of the ESL 533, and the sidewalls 700S and bottom surfaces 700B of the second trench segments 700, forming a second bottom electrode in the second trench segments 700. In some embodiments, the second electrode BE2 extending along a trench segment 700 and its adjacent trench segment 700 in the second region 500b of the interconnect structure 500 is continuous and, and connected together at tops of the respective trench segments 700.

Referring to FIG. 3I, the insulator layer IL may be formed conformally over the interconnect structure 500, extending along the top surface of the interconnect structure 500 in the first region 500a and along the top surface of the remaining portion of the bottom electrode material layer BE in the second region 500b. In this way, a top surface of the insulator layer IL extending along the first region 500a may be vertically offset from a top surface of the insulator layer IL extending along the second region 500b of the interconnect structure 500.

Referring to FIG. 3J, the method further includes forming a top electrode material layer TE over the insulator layer IL. In some embodiment, the top electrode material layer TE fills up remaining spaces within the first trench segments 600 and the second trench segments 700 not occupied by the bottom electrodes BE1, BE2 and the insulator layer IL in the first trench segments 600 and the second trench segments 700, respectively. In some embodiments, the top electrode material layer TE in the first region 500a may have a first thickness TH₁ over a top surface of the insulator layer IL, and the top electrode material layer TE in the second region 500b may have a second thickness TH₂ over the top surface of the insulator layer IL, wherein the first thickness TH₁ is substantially greater than the second thickness TH₂.

Referring to FIG. 3K through FIG. 3P, are schematic cross-sectional views illustrating an exemplary structure of a semiconductor structure 30, in accordance with some alternative embodiments of the present disclosure. In some embodiments, the process steps and materials used for forming the exemplary structure are similar to the process steps and materials described with reference to FIG. 2N through FIG. 2S and in the previous paragraphs, so the detailed descriptions thereof shall be omitted herein. Similar or substantially the same structural parts or elements may be labelled with similar or the same reference numbers as FIG. 2N through FIG. 2S, for illustration purposes.

Further referring to FIG. 3P, in some embodiments, the decoupling capacitor includes a plurality of trench segments 700 through the interconnect structure 500, extending towards the substrate 300. The plurality of trench segments 700 includes a first protrusion 7001 and a second protrusion 7002. In some embodiments, the conductive contact 545 underlying the decoupling capacitor 200 is electrically coupled to the first protrusion 7001 and is spaced from the second protrusion 7002, wherein the first protrusion 7001 is at the periphery of the decoupling capacitor 200 and the second protrusion 7002 is at a width-wise center of the decoupling capacitor 200. As shown in FIG. 3P, conductive contact 545 overlaps with the bottom surface of the bottom electrode BE2 of the first protrusion 7001 and is at a center of the first protrusion 7001. In this way, the bottom electrode BE2 of the decoupling capacitor 200 may be electrically coupled to the interconnect structure 500 with only one conductive path, which passes through the first protrusion 7001. In some embodiment, the interconnect structure 500 may include additional conductive contacts underlying the second protrusion 7002 at a same or different elevation as the conductive contact 545 underlying the first protrusion 7001, wherein the additional conductive contacts is electrically insulated from the bottom electrode BE2 of the decoupling capacitor and the second protrusion 7002. In some embodiment, the plurality of second trench segments 700 may include a third protrusion 7003 on an opposing side of the second protrusion 7002 as the first protrusion 7001. In some embodiment, the conductive contact 545 may have a lateral width D3 substantially greater than the lateral width W₃ of the first protrusion 7001, and substantially less a separation D2 between the first 7001 and the third protrusions 7003.

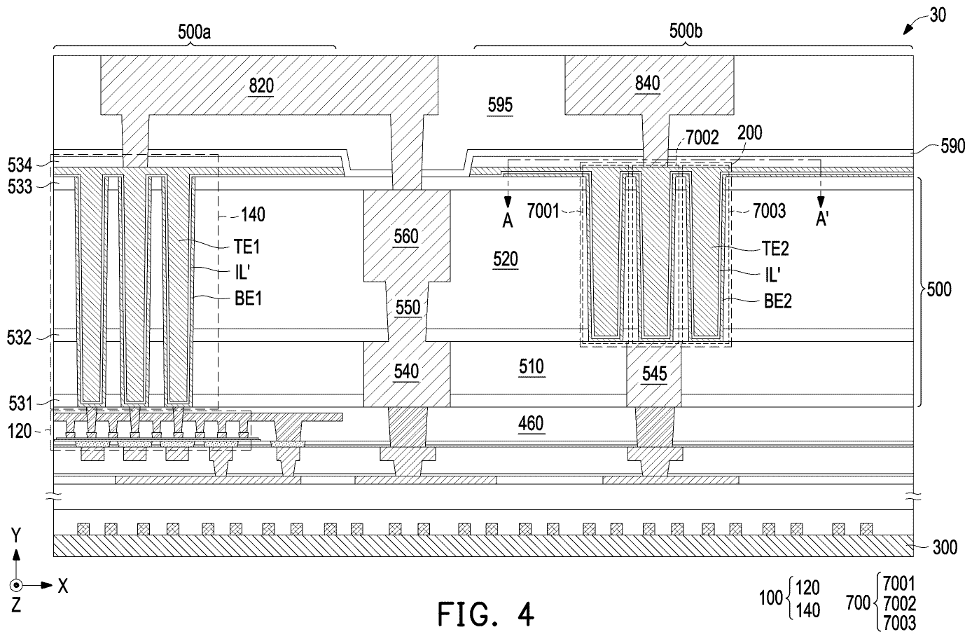

FIG. 4 through FIG. 8 are schematic cross-sectional views illustrating different configuration of an IC including a memory cell with a decoupling capacitor and its underlying conductive contact, in accordance with some embodiments of the present disclosure.

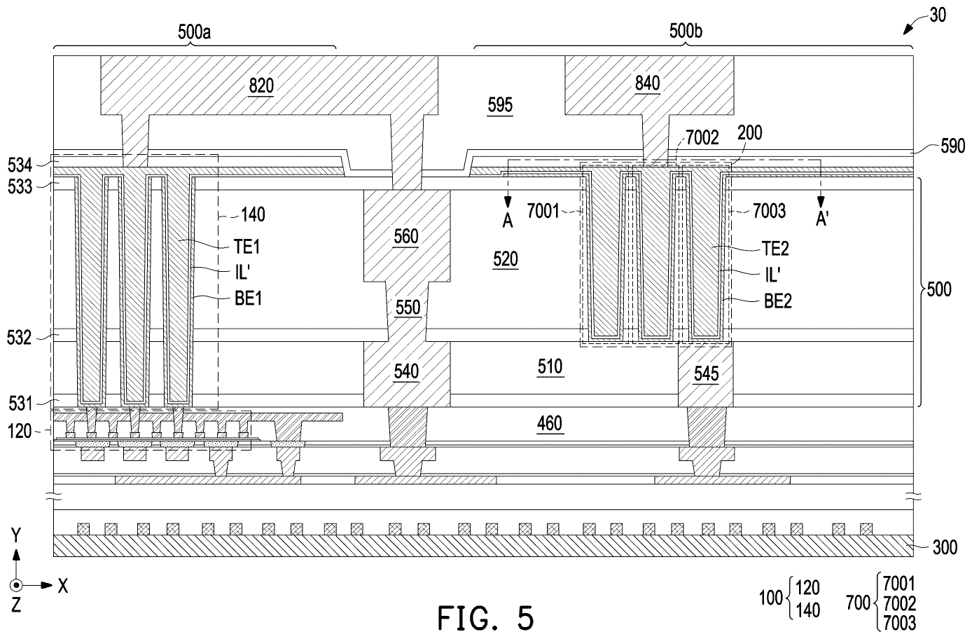

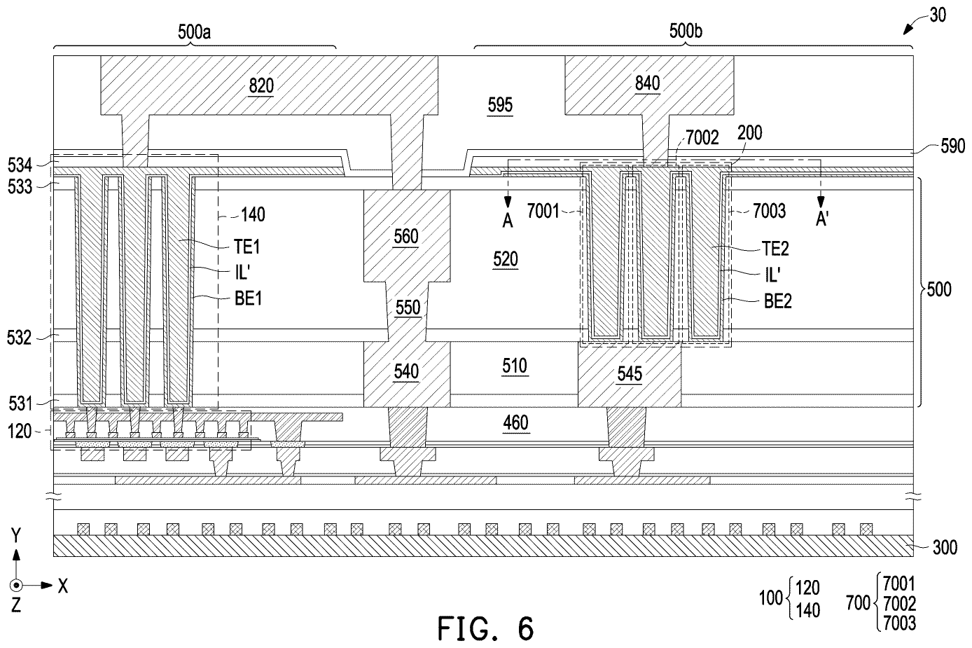

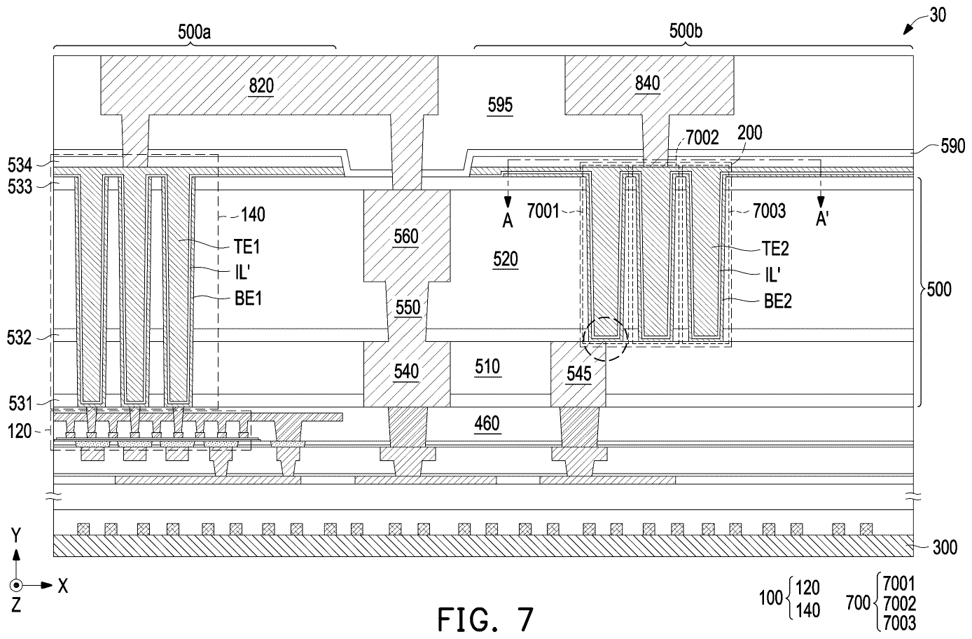

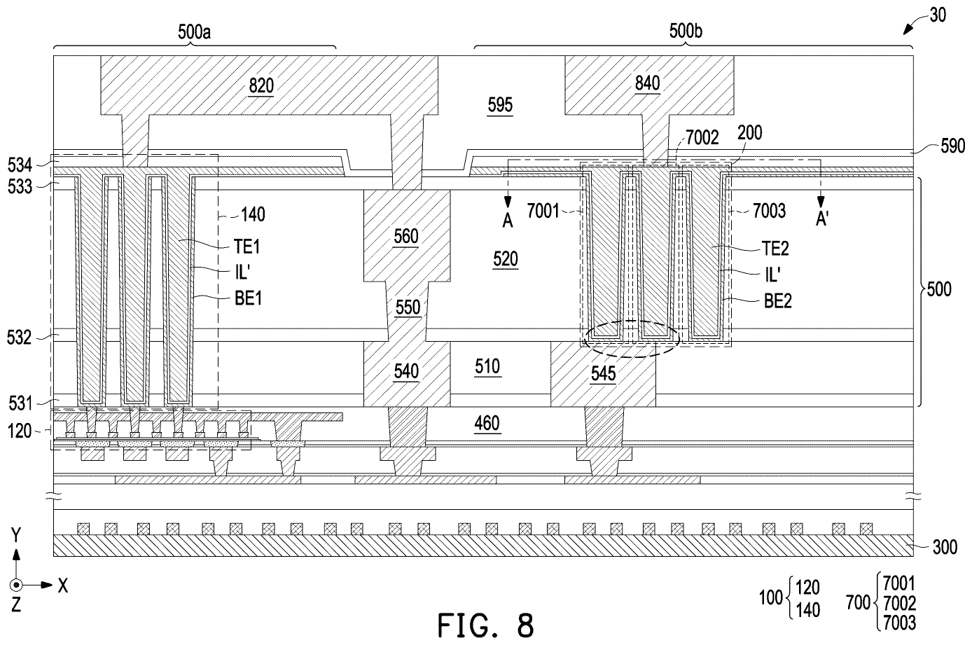

As shown in FIG. 4 through FIG. 8, in some alternative embodiments, the conductive contact 545 underlying the decoupling capacitor 200 may be at some other suitable locations on the second trench segments 700 of the decoupling capacitor. In some embodiments, the conductive contact 545 may be coupled to the second protrusion 7002 or the third protrusion 7003, as shown in FIG. 4 and FIG. 5. In an alternative embodiment, the conductive contact 545 may laterally span across two of the protrusions 7001, 7002, as shown in FIG. 6. In some other embodiments, the conductive contact 545 may be laterally offset from the first protrusion 7001 or the second protrusion 7002 in the x-direction, as shown in FIG. 7 and FIG. 8. In an alternative embodiment, the conductive contact 545 may be at some other suitable location along the plurality of trench segments 700, in the x-direction. In some instances, during the manufacturing process, a case of an overlay error (i.e., OVL misalignment or OVL displacement) may occur between the second photomask used for forming the trench segments 700 of the decoupling capacitor 200 (as illustrated in FIGS. 3D and 3E), and the conductive contact 545 formed by the first photomask (as illustrated in FIG. 3A and FIG. 3B). The circled dashed line shown in FIG. 7 illustrates how misalignment error results in displacement of the second photomask relative to conductive contact 545 formed by the first photomask. The overlay error causes the first protrusion 7001 of the decoupling capacitor 200 to partially overlap with the underlying conductive contact 545, thereby leading to the occurrence of electrical misconnection between the bottom electrode BE2 of the decoupling capacitor 200 and the underlying conductive contact 545. The occurrence of electrical misconnection due to OVL misalignment can be minimized in the case where there is an overlay shift, by increasing the lateral width D3 of the conductive contact 545. The increase in lateral width D3 of the conductive contact 545 may improve the process window, for example, for preventing an electrical misconnection between bottom electrode BE2 of the decoupling capacitor 200 and the underlying conductive contact 545, in the case where there is an overlay shift. As shown in FIG. 8, the first protrusion 7001 of the decoupling capacitor fully overlaps with the underlying conductive contact 545, while the second protrusion 7002 adjacent to the first protrusion 7001 partially overlaps with the underlying conductive contact 545. In order to ensure proper electrical connection between the bottom electrode BE2 of the decoupling capacitor 200 and the underlying conductive contact 545, and/or proper functioning of the semiconductor structure 30 as a whole, there is a need to provide sufficient overlap of the second photomask with the first photomask, thereby minimizing the risk of OVL misalignment.

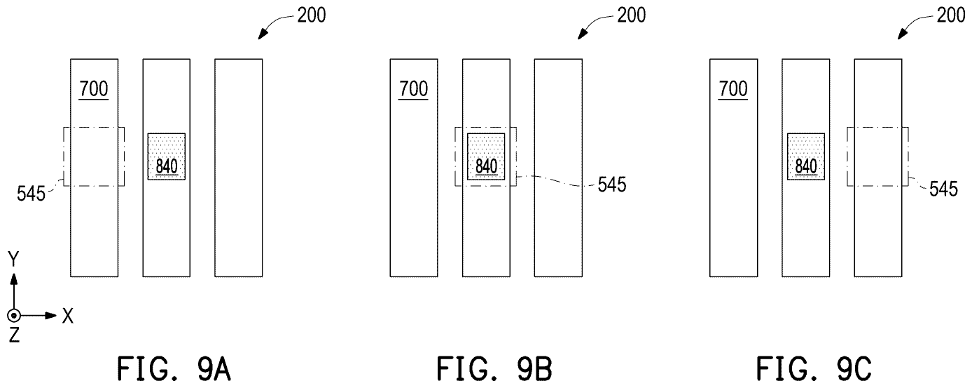

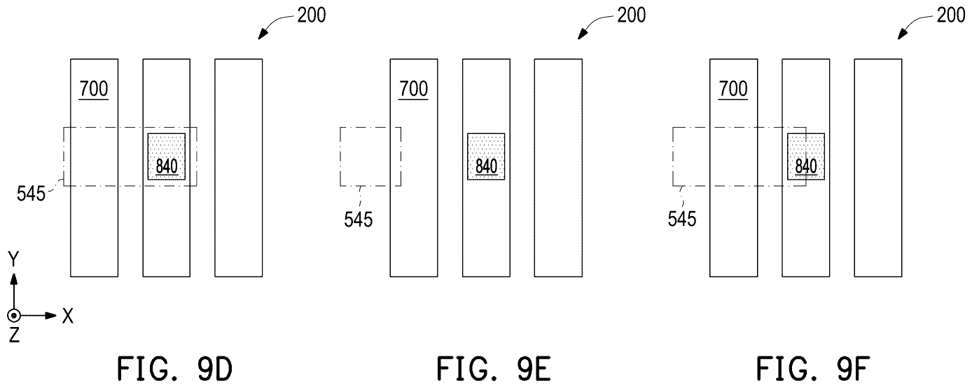

FIG. 9A through FIG. 9F depicts some embodiments of a top view of FIG. 3P through FIG. 8 of the semiconductor structure 30 as indicated in the cut-away lines A-A′ shown in FIG. 3P through FIG. 8. For clarity of illustration, certain features, for example the top electrode TE2, the insulator layer IL′ and the bottom electrode BE2 are omitted and certain other features, for example the conductive contact 545 connected to and underlying the bottom electrode BE2 of the trench segments 700 is shown with dashed lines. As illustrated in FIG. 9A through FIG. 9D and FIG. 9F, the conductive contact 545 fully overlaps with at least one of the trench segments 700 of the decoupling capacitor 200. The foregoing layouts increase an area of contact between the bottom electrode BE2 of the decoupling capacitor 200 with the underlying conductive contact 545, thereby providing a decoupling capacitor 200 having lower ESR, and thus larger capacitance value. In some alternative embodiment, as illustrated in FIG. 9E, the conductive contact 545 may be laterally offset from the trench segments 700, in the x-direction, such that the bottom electrode BE2 of the decoupling capacitor 200 and the underlying conductive contact 545 may be partially overlapping, thereby leading to the occurrence of electrical misconnection.

In some other embodiments, as illustrated in FIGS. 9B, 9D and 9F, the conductive feature 840 may be formed over the decoupling capacitor 200, and may overlap with the conductive contact 545 underlying the decoupling capacitor 200. In some alternative embodiments, the conductive feature 840 overlying the decoupling capacitor 200 may be laterally offset from the conductive contact 545 in the x-direction, such that that conductive feature 840 and the conductive contact 545 are non-overlapping, as illustrated in FIGS. 9A, 9C and 9E.

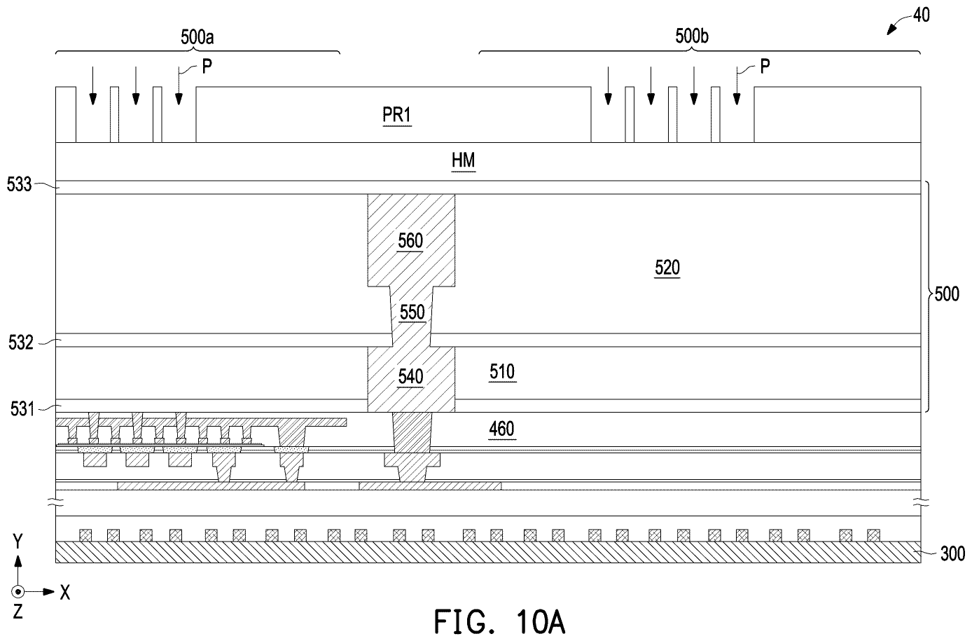

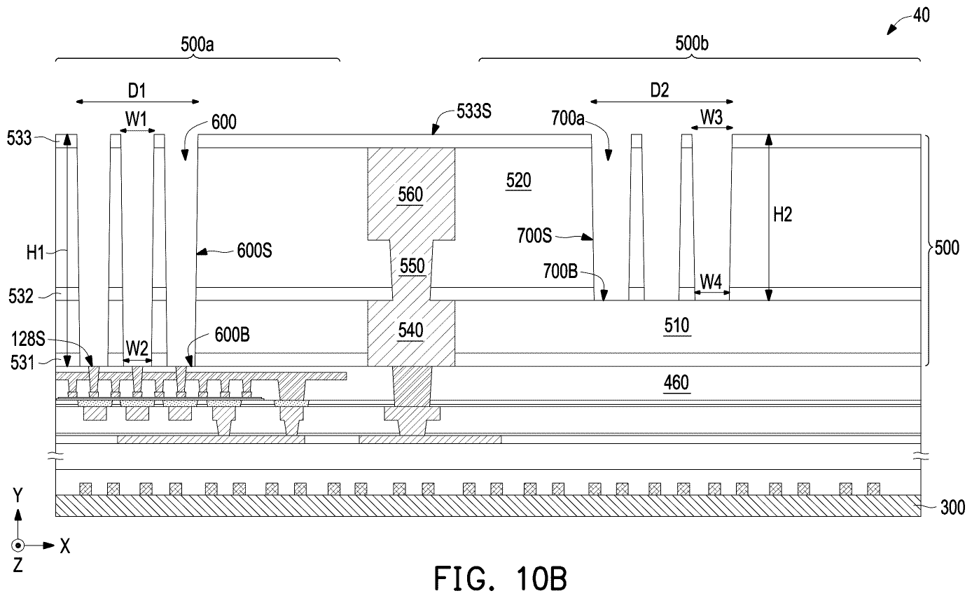

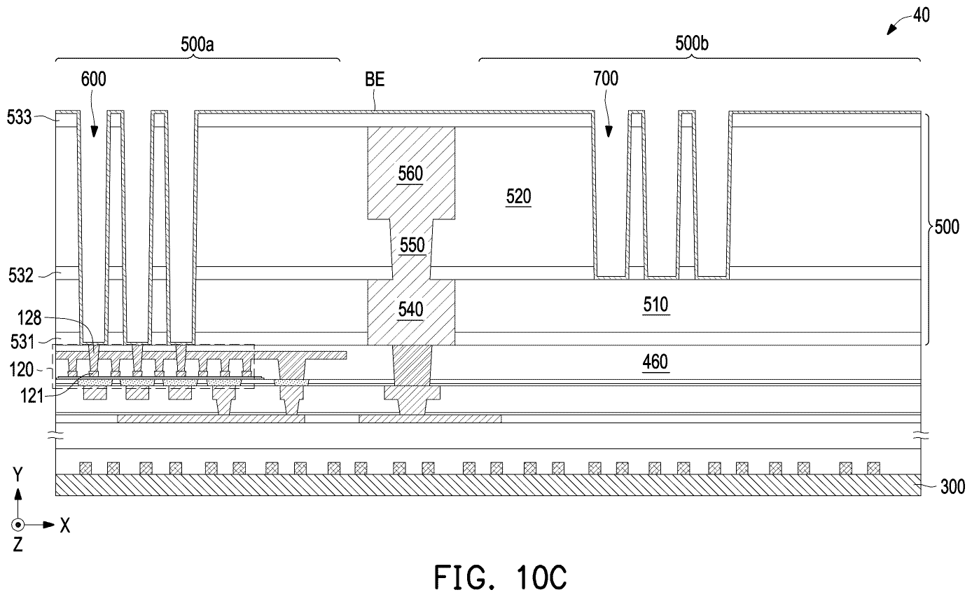

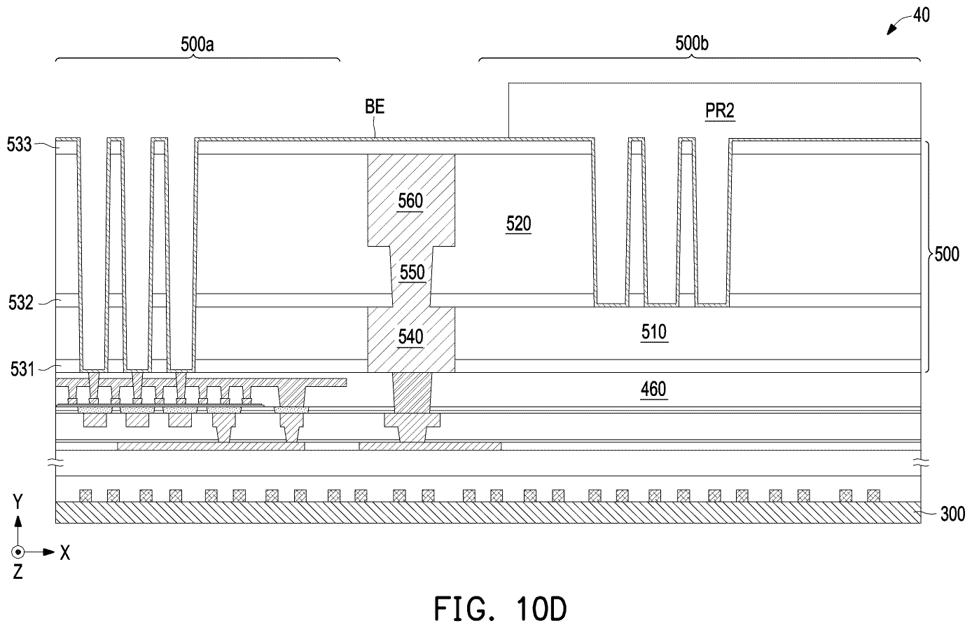

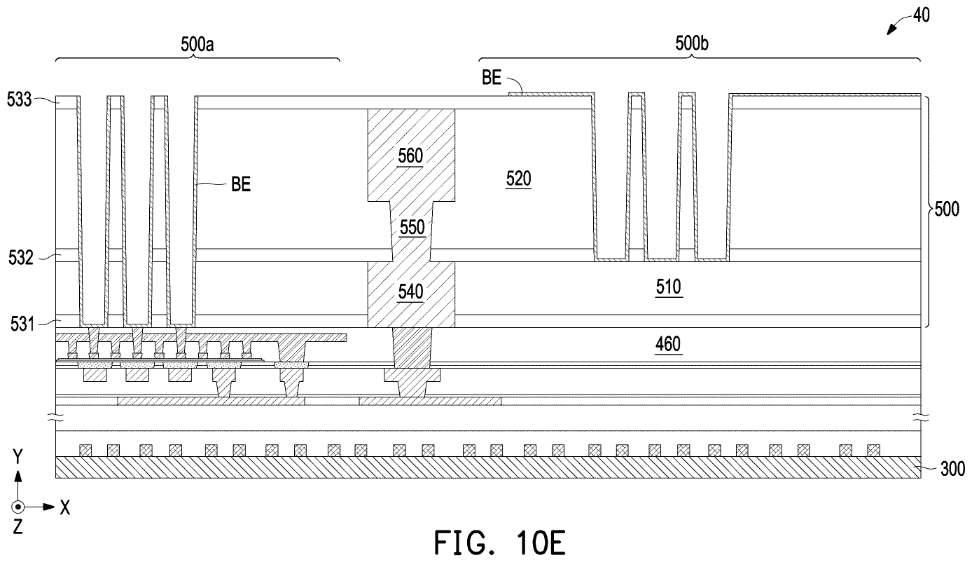

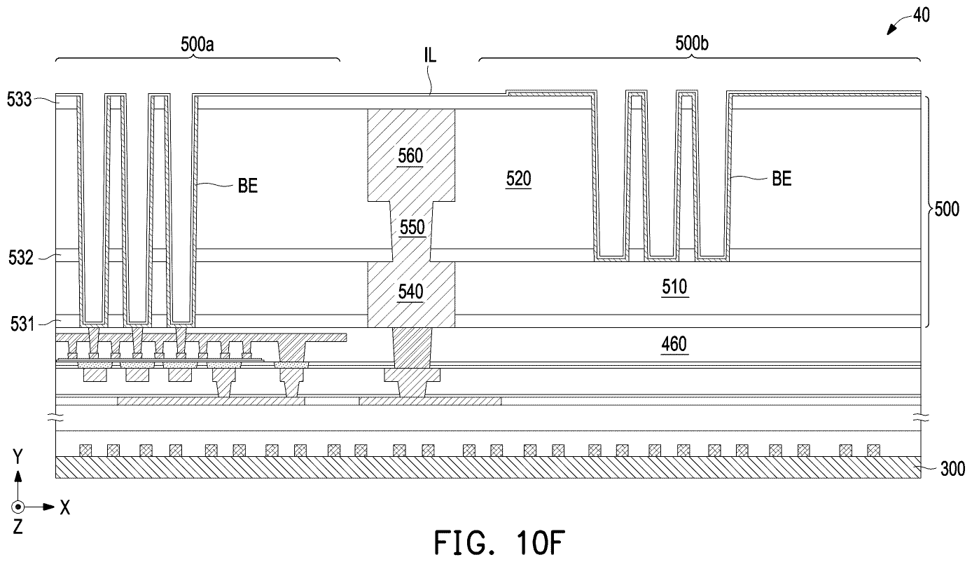

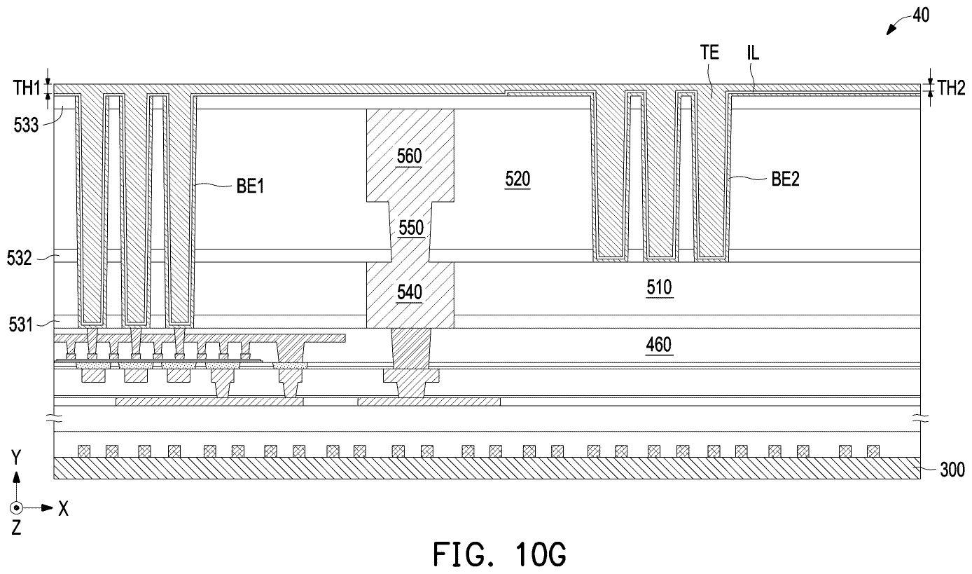

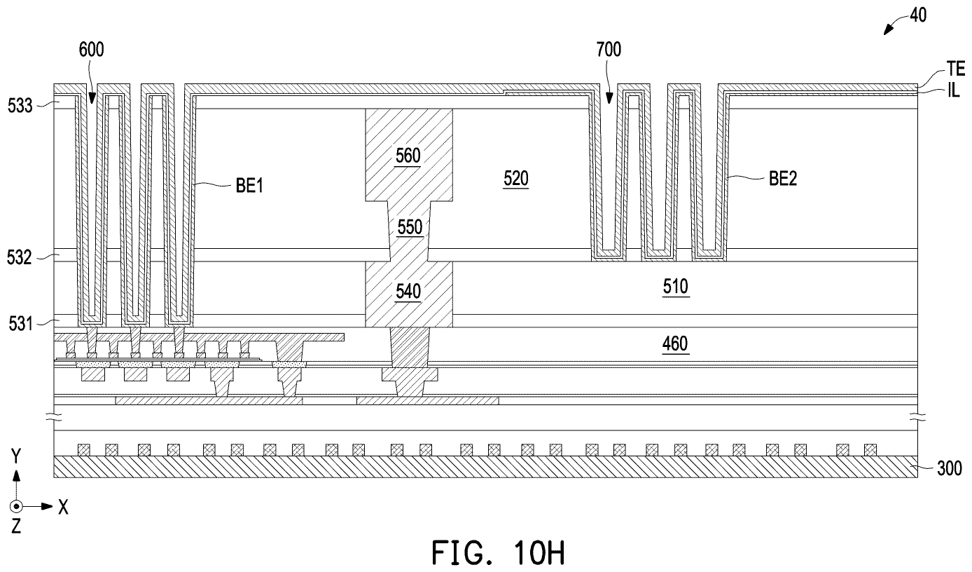

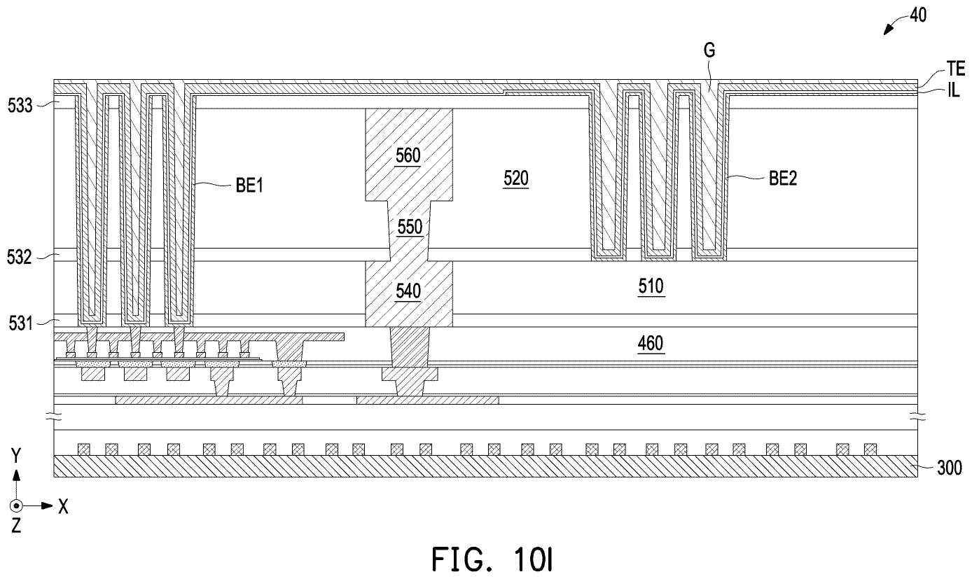

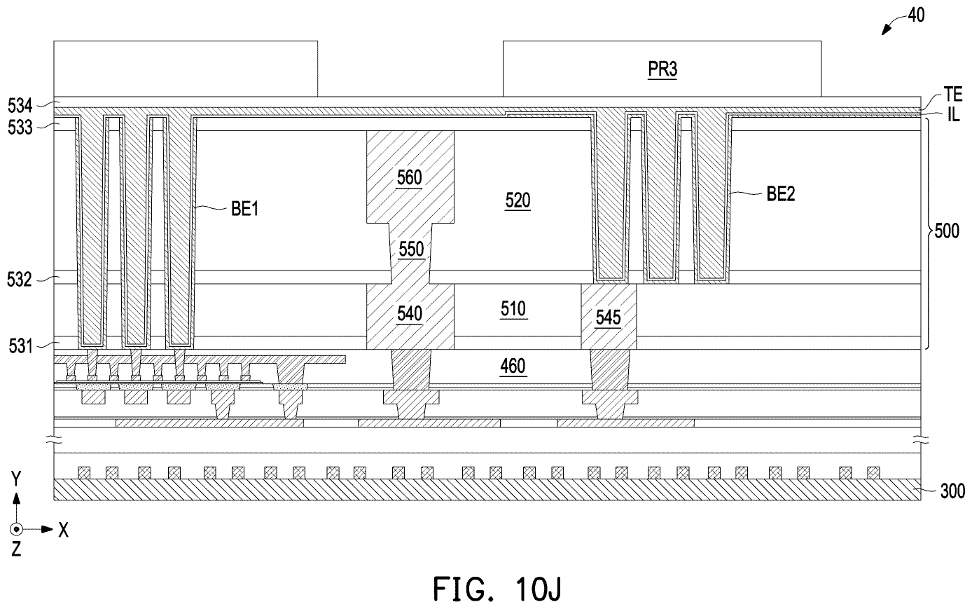

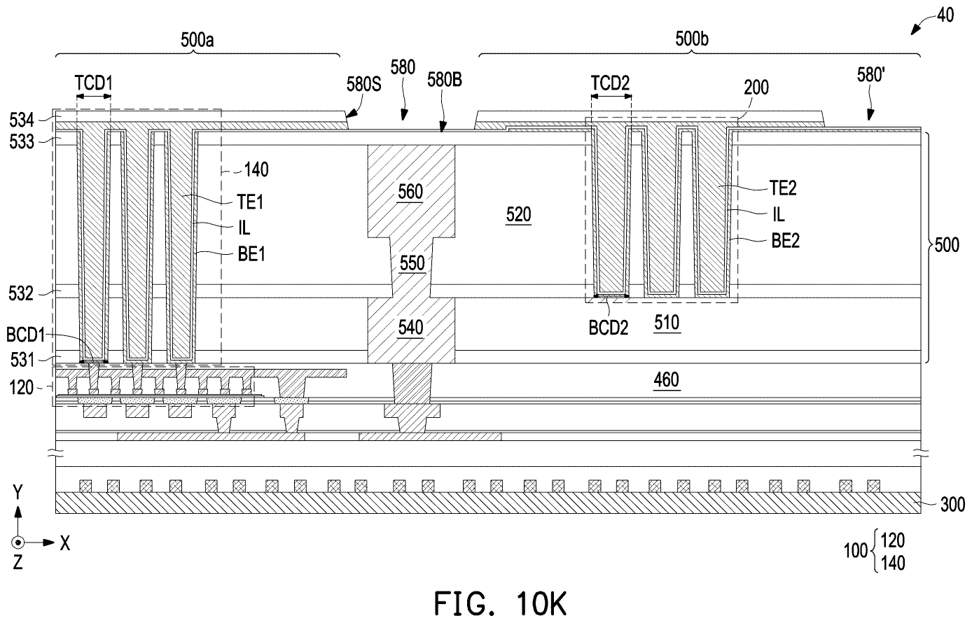

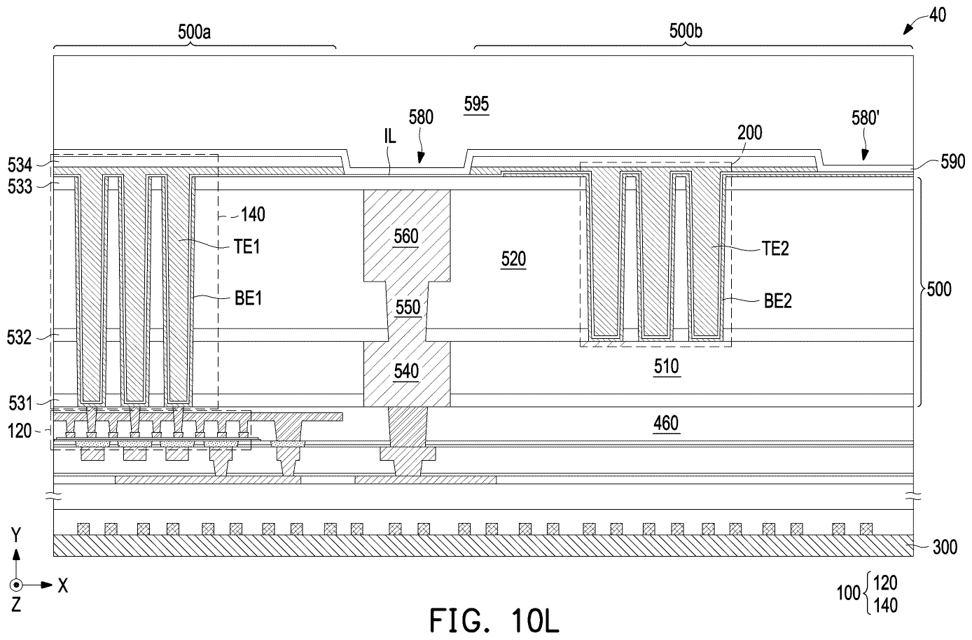

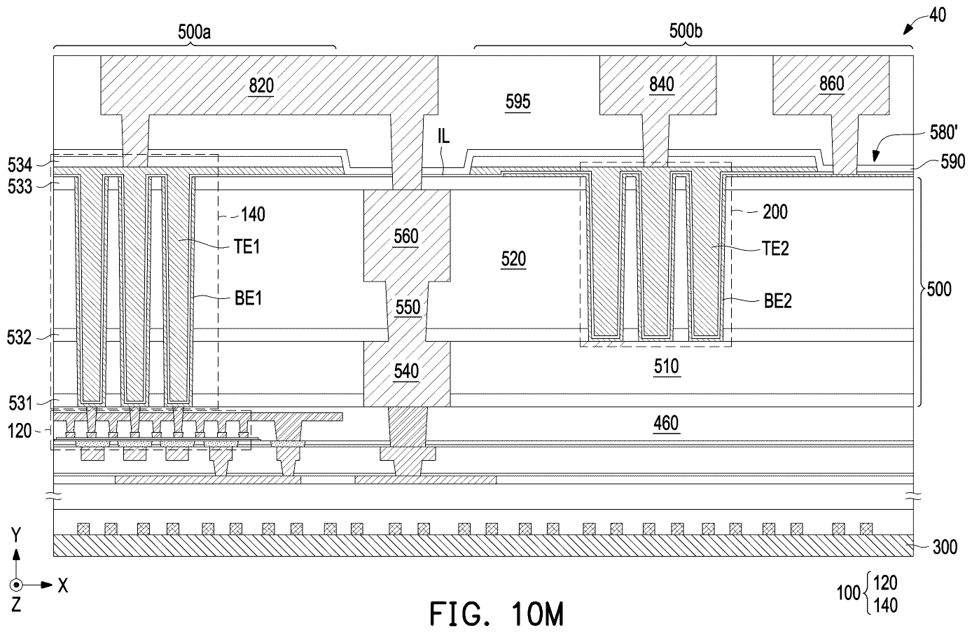

FIG. 10A through FIG. 10M are schematic cross-sectional views illustrating structures produced at various stages of a manufacturing process of forming a memory cell with a decoupling capacitor, in portion or entity, in accordance with some alternative embodiments of the present disclosure.

Referring to FIG. 10A, unlike the foregoing embodiments related to methods of forming the semiconductor structures 10, 20 and 30, the method of forming semiconductor structure 40 does not include the step of forming a conductive contact underlying the decoupling capacitor. In some embodiment, the method includes a lithography process to form a plurality of trench segments in the interconnect structure 500. The process steps and materials used for forming the exemplary structure are similar to the process steps and materials described with reference to FIGS. 2H, 2G, 3D and 3E, and in the previous paragraphs, so the detailed descriptions thereof shall be omitted herein. Similar or substantially the same structural parts or elements may be labelled with similar or the same reference numbers as FIGS. 2H, 2G 3D and 3E, for illustration purposes.

Referring to FIG. 10A and FIG. 10B, the lithography process includes forming a hard mask layer HM and a photoresist layer PR1 over the interconnect structure 500, followed by a patterning step P to etch one or more recesses into a first region 500a and a second region 500b of the interconnect structure 500, thereby forming one or more first trench segments 600 and second trench segments 700 within the ILD layers 510, 520. In some embodiment, the first trench segments 600 extend through the ILD layer 510, 520 of the interconnect structure 500 in a first direction (y-direction), and stop once a top surface of the ILD layer 460 underlying the interconnect structure 500 is reached, and exposing a top surface 128S of the underlying capacitor via 128. In some embodiments, the second trench segments 700 may be formed laterally adjacent to the first trench segments 600 in a second direction (x-direction) substantially perpendicular to the first direction (y-direction). In some embodiments, the second trench segments 700 extend through the ILD 520 of the interconnect structure 500 towards the semiconductor substrate 300, and stopping once the ESL 532 is reached. Due to the intrinsic property of the etching process, the second trench segments 700 having a wider lateral width W3 (i.e., critical dimension) will inevitably lead to openings having shallower depth relative to openings of the first trench segments 600.

Referring to FIG. 10C through FIG. 10I, the process steps and materials used for forming the exemplary structure are similar to the process steps and materials described with reference to FIG. 3F through FIG. 3L, and in the previous paragraphs, so the detailed descriptions thereof shall be omitted herein. Similar or substantially the same structural parts or elements may be labelled with similar or the same reference numbers as FIG. 3F through FIG. 3L, for illustration purposes.

Referring to FIG. 10J, the method of forming the semiconductor structure 40, includes a lithography process to partially remove the top electrode material layer TE to form a first top electrode TE1 in the first trench segment 600, and a second top electrode TE2 in the second trench segments 700, over the insulator layer IL. The lithography process includes placing a photoresist layer PR3 over the interconnect structure 500, to selectively pattern the top electrode material layer TE, resulting in a recess 580 laterally between the first trench segments 600 in the first region 500a of the interconnect structure 500, and the second trench segments 700 in the second region 500b of the interconnect structure 500. The patterning process further forms a second recess 580′ laterally aside the decoupling capacitor 200. The patterning process stops once the insulator layer IL overlying the ESL 533 is reached. In this way, the bottom surfaces of the recesses 580, 580′ may be lined by the insulator layer IL. In an alternative embodiment, the lithography process may be performed to selectively pattern the top electrode material layer TE and the underlying insulator layer IL in the second region 500b of the interconnect structure 500 overlying the decoupling capacitor 200, such that the patterning process stops once the bottom electrode BE2 of the decoupling capacitor 200 is reached.

Referring to FIG. 10L and FIG. 10M, the process steps and materials used for forming the exemplary structure are similar to the process steps and materials described with reference to FIG. 3O and FIG. 3P, and in the previous paragraphs, so the detailed descriptions thereof shall be omitted herein. Similar or substantially the same structural parts or elements may be labelled with similar or the same reference numbers as FIG. 3O and FIG. 3P, for illustration purposes.

Further referring to FIG. 10M, in some embodiments, the method further includes forming a third conductive feature 860 within the dielectric layer 595 over the second recess 580′. The third conductive feature 860 extends within the dielectric layer 595 and engages the bottom electrode BE2 of the decoupling capacitor 200, to enable electrical connection between the bottom electrode BE2 of the decoupling capacitor 200 and the conductive feature 860 overlying the decoupling capacitor 200.

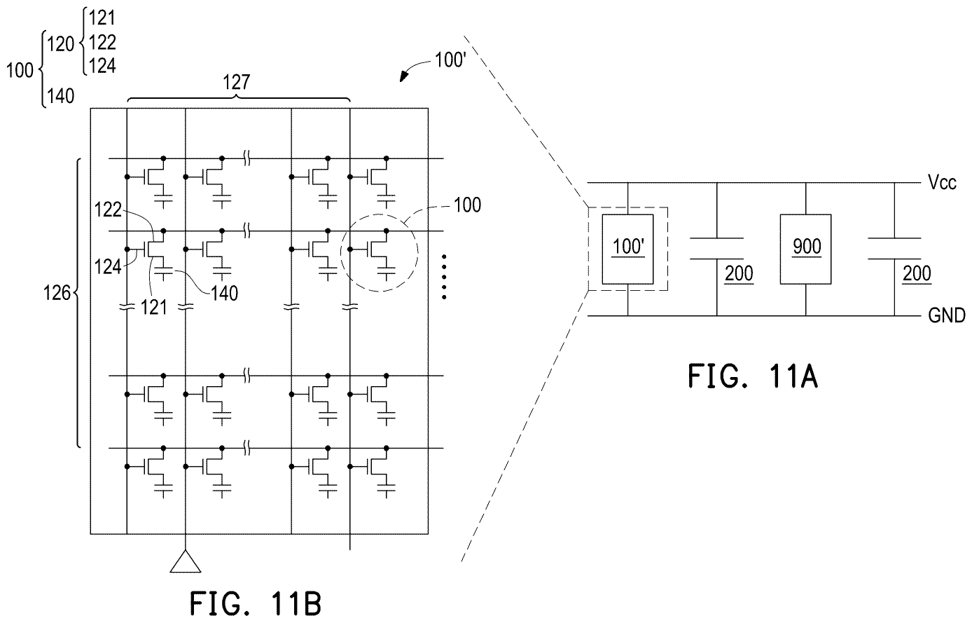

FIG. 11A through FIG. 11B are schematic illustration demonstrating an interconnecting network including a memory cell, a decoupling capacitor and front-end-of-line (FEOL) devices, in accordance with some embodiments.

FIG. 11A is a schematic illustration of an example configuration of a memory cell array 100′ implementing a plurality of 1T-1C memory cells 100, and a decoupling capacitor 200, according to some embodiments of the present disclosure. The memory cell array 100′ and the decoupling capacitor 200 are in series connection between a first voltage potential V1 and a second voltage potential V2, which is less than the first voltage potential V1. In some embodiments, the first voltage potential V1 may be a supply voltage (Vcc) and the second voltage potential V2 may be a ground voltage (i.e., a voltage potential of zero, GND). In some embodiments, the memory cells array 100′ and the decoupling capacitor 200 may be arranged in the BEOL region, and interconnected to complementary metal oxide semiconductor (CMOS) logic 900 fabricated in front-end-of-line (FEOL). Each of the memory cell 100 in the memory cells array 100′ may be interconnected to peripheral circuitry implemented in with CMOS logic, for example a central processing unit (CPU) and/or a graphics processing unit (GPU) fabricated in the FEOL. Peripheral memory circuitry further includes control circuitry. One or more memory cells 100 may be electrically coupled to control circuitry, wherein the control circuitry may include, for example, various voltage biasing circuits, such as capacitor bias (Vcc) circuitry.

FIG. 11B illustrates an enlarged schematic view of the memory cell array 100′ of FIG. 11A, wherein the memory cell array 100′ having a plurality of memory cells, each of the memory cell 100 includes a transistor 120 and a storage capacitor 140. The transistor 120 may be implemented as a TFT. The memory cell 100 may be provided in the BEOL metallization layer 400. The transistor 120 includes a first S/D electrode 121, a second S/D electrode 122, and a gate electrode 124. It should be noted that the source and the drain terminals are interchangeable in transistors (hence, the notation “S/D” terminals is sometimes used, indicating the interchangeability of the source and drain terminals). The S/D electrode 121, 122 is coupled to a bit line 126, the gate electrode 124 is coupled to the word line 127. The memory cell 100 may further include a storage capacitor 140, which may be used for storing charge. In some embodiments, the storage capacitor 140 may be implemented as a three-dimensional (3D) MIM capacitor.

As shown further in FIG. 11B, the plurality of memory cells may be arranged in rows and columns. In some embodiments, the drain terminals 122 of the transistor 120 of each of the memory cell 100 of a given row may be coupled to a common bit line 126. In some embodiments, the gate electrode 124 of the transistor 120 may be coupled to the word line 127, which can be selectively couple the bit line 126 to the storage capacitor 140. During write operations, different amounts of charge, which correspond to different data states, respectively, can be placed on the storage capacitor 140 through the bit line 126 and the transistor 140. Further, during read operations, the amount of charge present on the storage capacitor 140 at a given time can be read by asserting the word line 127 and monitoring the current or voltage on the bit line 126, thereby allowing the data state stored in the memory cell (i.e., DRAM) to be read. It should be noted that the designation of “rows” and “columns” is only in terms of how different memory cells 100 of the memory cells array 100′ may be addressed and not how the memory cells 100 are actually laid out in a given design. The number of rows and columns shown in FIG. 11B is purely illustrative, and, in other embodiments, any number of rows and columns, each containing any number of one or more memory cells 100 may be used.

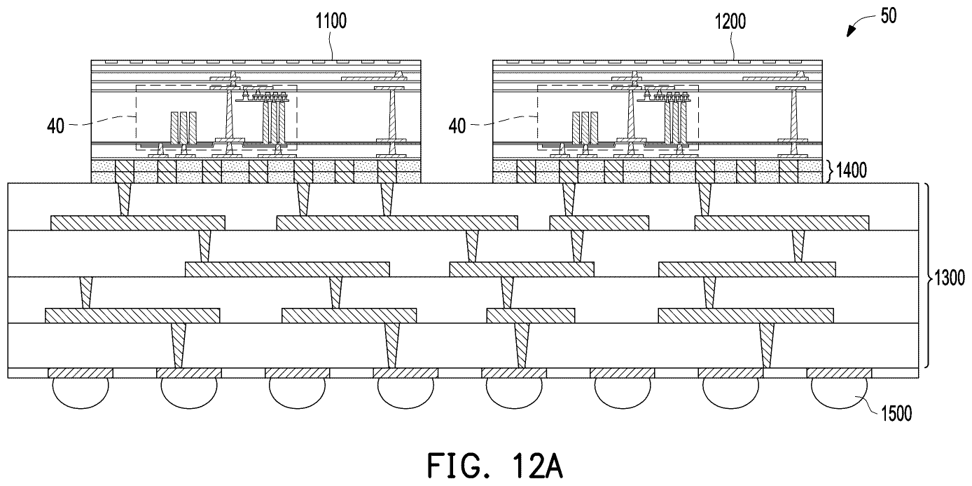

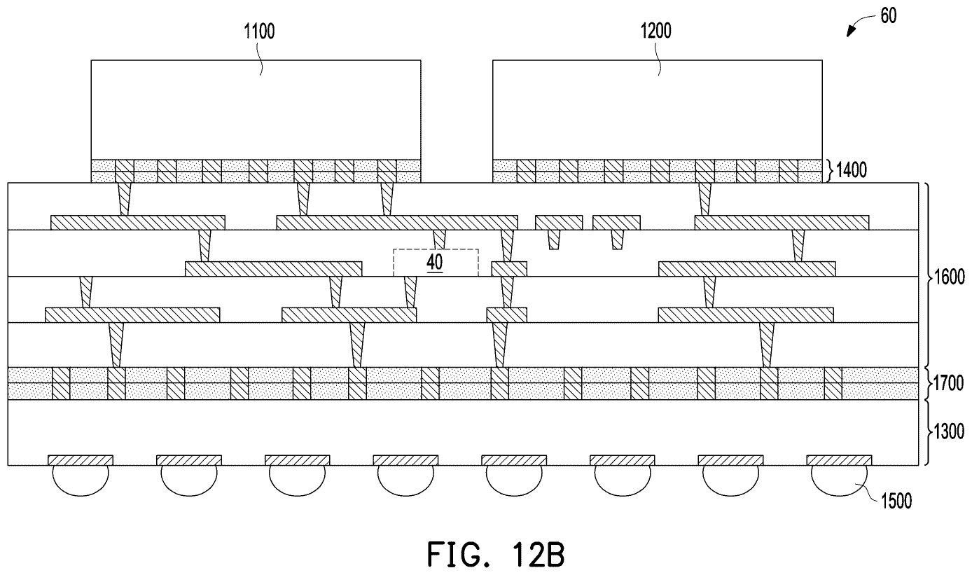

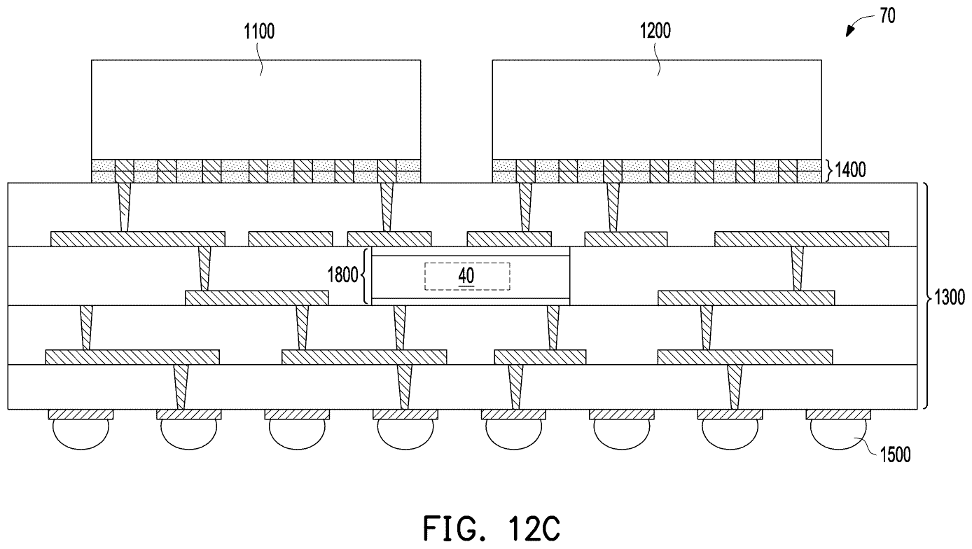

FIG. 12A through FIG. 12C are schematic cross-sectional views illustrating the integration of a memory cell with a decoupling capacitor in a semiconductor device, in accordance with some embodiments of the present disclosure.

In some embodiments, as shown in FIG. 12A, the semiconductor structure 40 including a memory cell 100 with a decoupling capacitor 200 may be implemented in a semiconductor device 50. The semiconductor structure 40 may be provided within at least one or more semiconductor dies 1100, 1200 disposed over a package substrate 1300. It should be noted that any of the semiconductor structures 10 through 40, shown in the foregoing embodiments may be integrated into the semiconductor device 50. The configuration shown in FIG. 12A merely serves as an exemplary illustration. Further, multiple semiconductor structures 40 may be formed in various orientation within the semiconductor dies 1100, 1200. In some embodiments, the semiconductor structure 40 may be electrically connected to the package substrate 1300 through conductive terminals 1400 interposed between the semiconductor dies 1100, 1200 and the package substrate 1300. In some embodiments, the semiconductor dies 1100, 1200 may include a memory die, such as a high-bandwidth memory (HBM) die, a logic die, etc. The semiconductor dies 1100, 1200 may be the same type of dies or perform the same functions or may be different types of dies or perform different functions. In some embodiment, the semiconductor device 50 may further include conductive connectors 1500, capable of electrically connecting the package substrate 1300 and the overlying semiconductor dies 1100, 1200 to a corresponding component (not shown).

In some embodiment, as illustrated in FIG. 12B, the semiconductor structure 40 including a memory cell with a decoupling capacitor may be implemented within the interposer substrate 1600 of a semiconductor device 60. In some embodiments, the semiconductor structure 40 will be integrated within a network of conductive traces (i.e., conductive vias, pads, metal line, metal wiring, etc.) within the interposer substrate 1600. For clarity of illustration, the semiconductor structure 40 may be represented by a dashed box. The dashed box may depict any of the semiconductor structure 10 through 40, shown in the foregoing embodiments. The configuration shown in FIG. 12B merely serves as an exemplary illustration. Further, multiple semiconductor structure 40 may be formed in various orientation across the interposer substrate 1600. In some embodiments, the semiconductor structure 40 may be electrically connected to at least one or more of the semiconductor dies 1100, 1200 disposed over the interposer substrate 1600, and the package substrate 1300 underlying the interposer substrate 1600, wherein the semiconductor dies 1100, 1200 and the package substrate 1300 are disposed at opposing sides of the interposer substrate 1600, through conductive terminals 1400, 1700. In some embodiment, the semiconductor device 60 may further include conductive connectors 1500, capable of electrically connecting the semiconductor device 60 to a corresponding component (not shown).

In some embodiments, as illustrated in FIG. 12C, the semiconductor structure 40 including a memory cell with a decoupling capacitor may be implemented within a bridge die 1800 within the package substrate 1300 of a semiconductor device 70. For clarity of illustration, the semiconductor structure 40 may be represented by a dashed box. The dashed box may depict any of the semiconductor structure 10 through 40, shown in the foregoing embodiments. The configuration shown in FIG. 12C merely serves as an exemplary illustration. Further, multiple semiconductor structure 40 may be formed in various orientation within the bridge die 1800 of the semiconductor device 70. In some embodiments, the semiconductor structure 40 may be integrated within the routing patterns of the bridge die 1800, and may be electrically connected to the conductive traces (i.e., conductive vias, pads, metal line, metal wiring, etc.) within the package substrate 1300. The semiconductor structure 40 may be electrically connected to the semiconductor dies 1100, 1200 disposed over the package substrate 1300 through the conductive traces within the package substrate 1300. In some embodiment, the semiconductor device 70 may further include conductive connectors 1500, capable of electrically connecting the semiconductor device 70 to a corresponding component (not shown).

The present disclosure is related to a method of integrating a memory cell (i.e., eDRAM) with a high-density 3D decoupling capacitor having low ESR, in the BEOL region. The integration is free from the FEOL region. and may be performed without the inclusion of additional process steps. Furthermore, it is highly compatible with advanced logic, and may be performed on a same chip with logic processing unit, such that the memory cell and the decoupling capacitor may be in immediate proximity to the CMOS device, thereby significantly reducing the data transfer energy and latency. and further improving the decoupling and noise suppression efficiency of an IC structure.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

In accordance with some embodiments of the disclosure, a method including forming an interconnect structure over a semiconductor substrate. The interconnect structure including interlayer dielectric (IDL) layers. The method further includes patterning a first region of the interconnect structure to form first trench segments extending through the ILD layers in a first direction and patterning a second region of the interconnect structure to form second trench segments laterally adjacent to the first trench segments in a second direction substantially perpendicular to the first direction. The method further includes forming first bottom electrodes in the first trench segments and second bottom electrodes in the second trench segments. The method further includes forming an insulator layer covering the first bottom electrodes and the second bottom electrode. The method further includes concurrently forming a first top electrode and a second top electrode over the patterned insulator layer. The first bottom electrodes, a first portion of the insulator layer and the first top electrode, form a memory cell storage capacitor in the first region of the interconnect structure, and the second bottom electrodes, a second portion of the insulator layer and the second top electrode, form a decoupling capacitor in the second region of the interconnect structure. The first trench segments and the second trench segments are concurrently defined by a single patterning process. The step of concurrently forming the first bottom electrodes in the first trench segments and the second bottom electrodes in the second trench segments includes forming a bottom electrode material layer; and prior to forming the insulator layer, patterning the bottom electrode material layer to form the first bottom electrodes in each of the first trench segments, wherein each of the first bottom electrodes are separated from each other, and to form the second bottom electrodes in each of the second trench segments, wherein each of the second bottom electrodes are separated from each other. The step of concurrently forming the first bottom electrodes in the first trench segments and the second bottom electrodes in the second trench segments includes forming a bottom electrode material layer; and prior to forming the insulator layer, patterning the bottom electrode material layer to form the first electrodes in each of the first trench segments, wherein each of the first bottom electrodes are separated from each other, and to form the second bottom electrodes in each of the second trench segments, wherein each of the second bottom electrodes are connected to each other. The step of concurrently forming a first top electrode and a second top electrode over the insulator layer includes forming a top electrode material layer over the insulator layer, wherein the top electrode material layer continuously extend along the insulator layer from the first trench segments to the second trench segments. The method further includes partially removing the top electrode material layer and the underlying insulator layer resulting in a recess laterally between the memory cell storage capacitor and the decoupling capacitor, to form a patterned insulator layer, the first top electrode and the second top electrode over the patterned insulator layer. The method further includes comprising forming a dielectric layer above the semiconductor substrate prior to forming the interconnect structure over the semiconductor substrate, and forming a transistor within the dielectric layer, wherein the transistor is vertically adjacent to the memory cell storage capacitor, and the memory cell storage capacitor is coupled to a terminal on the transistor. The method further includes forming a first conductive feature over the IDL layers, wherein the first conductive feature is electrically coupled to the first top electrode of the memory cell storage capacitor. The method further includes forming a second conductive feature laterally adjacent to the first conductive feature, and at a substantially same elevation as the first conductive feature, wherein the second conductive feature is electrically coupled to the second bottom electrode of the decoupling capacitor.

In accordance with some embodiments of the disclosure, a method including forming a interlayer dielectric (ILD) layer over a semiconductor substrate. The ILD layer including a first ILD layer, and a second ILD layer formed between the first ILD layer and the semiconductor substrate. The method includes forming a first conductive feature in the second ILD layer. The method includes performing a first patterning to form a first cavity extending pass the first and the second ILD layers. The method includes performing a second patterning to form a second cavity extending pass the first ILD layer and stopping at a top surface of the first conductive feature. The method includes forming a first electrode in the first cavity and the second cavity. The method includes forming an insulator layer on the first electrode. The method includes forming a second electrode on the insulator layer, wherein the first electrode, the insulator layer and the second electrode in the first cavity forms a memory cell storage capacitor, and the first electrode, the insulator layer and the second electrode in the second cavity forms a decoupling capacitor. A bottom surface of the memory cell storage capacitor is recessed relative to a bottom surface of the decoupling capacitor, and a top surface of the memory cell storage capacitor substantially levels with a top surface of the decoupling capacitor. The first cavity and the second cavity comprises a plurality of substantially u-shaped cross-sectional segments that are elongated in a vertical direction in the ILD layer, and are extending in the lateral direction substantially perpendicular to the vertical direction. A dimension of the second cavity has a first width measured in a direction parallel to a top surface of the semiconductor substrate, and the first width is less than a lateral width of the first conductive feature. The first electrode formed in each of the adjacent substantially u-shaped cross-sectional segments of the second cavity are connected together at tops of the substantially u-shaped cross-sectional segments. The first electrode formed in each of the adjacent substantially u-shaped cross-sectional segments of the second cavity are separated in a lateral direction along a top surface of the ILD layer. The top surface of the first conductive feature partially overlaps with a bottom surface of the decoupling capacitor. A portion of a bottom surface of the decoupling capacitor is spaced apart from the first conductive feature.

In accordance with some embodiments of the disclosure, an integrated circuit device including an interconnect structure formed over a semiconductor substrate is formed. A memory cell disposed at a first region of the interconnect structure. The memory cell comprising a transistor and a storage capacitor. A decoupling capacitor disposed at a second region of the interconnect structure, and arranged in a direction that is substantially perpendicular to a top surface of the semiconductor substrate. The interconnect structure further includes a first metal line, a first via coupled to the first metal line and at a height substantially greater than the first metal line over the top surface of the semiconductor substrate. A second metal line coupled to the first via and at a height substantially greater than the first via. A bottom surface of the storage capacitor of the memory cell is substantially co-planar with a bottom surface of the first metal line. The transistor of the memory cell is formed below the first metal line. A bottom surface of the decoupling capacitor is between the first metal line and the second metal line. The transistor of the memory cell includes a semiconductor channel vertically adjacent to the storage capacitor and in a plane substantially parallel to the top surface of the semiconductor substrate. A first end of the semiconductor channel is electrically coupled to a bit line disposed below the first metal line, and running substantially parallel to the top surface of the substrate. A second end of the semiconductor channel is electrically coupled to the storage capacitor.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method, comprising:
forming an interconnect structure over a semiconductor substrate, wherein the interconnect structure comprising interlayer dielectric (ILD) layers;
patterning a first region of the interconnect structure to form first trench segments extending through the ILD layers in a first direction;
patterning a second region of the interconnect structure to form second trench segments laterally adjacent to the first trench segments in a second direction substantially perpendicular to the first direction;
concurrently forming first bottom electrodes in the first trench segments and second bottom electrodes in the second trench segments;
forming an insulator layer IL covering the first bottom electrodes and the second bottom electrodes;
concurrently forming a first top electrode and a second top electrode over the insulator layer, wherein the first bottom electrodes, a first portion of the insulator layer and the first top electrode, form a memory cell storage capacitor in the first region of the interconnect structure, and the second bottom electrodes, a second portion of the insulator layer and the second top electrode, form a decoupling capacitor in the second region of the interconnect structure.

2. The method of claim 1, wherein the first trench segments and the second trench segments are concurrently defined by a single patterning process.

3. The method of claim 1, wherein concurrently forming the first bottom electrodes in the first trench segments and the second bottom electrodes in the second trench segments comprises:
forming a bottom electrode material layer; and
prior to forming the insulator layer, patterning the bottom electrode material layer to form the first bottom electrodes in each of the first trench segments, wherein each of the first bottom electrodes are separated from each other, and to form the second bottom electrodes in each of the second trench segments, wherein each of the second bottom electrodes are separated from each other.

4. The method of claim 1, wherein concurrently forming the first bottom electrodes in the first trench segments and the second bottom electrodes in the second trench segments comprises:
forming a bottom electrode material layer; and
prior to forming the insulator layer, patterning the bottom electrode material layer to form the first electrodes in each of the first trench segments, wherein each of the first bottom electrodes are separated from each other, and to form the second bottom electrodes in each of the second trench segments, wherein each of the second bottom electrodes are connected to each other.

5. The method of claim 1, wherein concurrently forming the first top electrode and the second top electrode over the insulator layer comprises:
forming a top electrode material layer over the insulator layer, wherein the top electrode material layer continuously extends along the insulator layer from the first trench segments to the second trench segments.

6. The method of claim 5, further comprising partially removing the top electrode material layer and the underlying insulator layer resulting in a recess laterally between the memory cell storage capacitor and the decoupling capacitor, to form a patterned insulator layer, the first top electrode and the second top electrode over the patterned insulator layer.

7. The method of claim 1, further comprising forming a dielectric layer above the semiconductor substrate prior to forming the interconnect structure over the semiconductor substrate, and forming a transistor within the dielectric layer,
wherein the transistor is vertically adjacent to the memory cell storage capacitor, and the memory cell storage capacitor is coupled to a terminal on the transistor.

8. The method of claim 1, further comprising forming a first conductive feature over the ILD layers, wherein the first conductive feature is electrically coupled to the first top electrode of the memory cell storage capacitor.

9. The method of claim 8, further comprising forming a second conductive feature laterally adjacent to the first conductive feature, and at a substantially same elevation as the first conductive feature, wherein the second conductive feature is electrically coupled to the second top electrode of the decoupling capacitor.

10. A method, comprising:
forming a interlayer dielectric (ILD) layer over a semiconductor substrate, the ILD layer comprising a first ILD layer and a second ILD layer, wherein the first ILD layer is interposed between the second ILD layer and the semiconductor substrate;
forming a first conductive feature in the first ILD layer;
performing a first patterning to form a first cavity extending pass the first and the second ILD layers;
performing a second patterning to form a second cavity extending pass the second ILD layer and stopping at a top surface of the first conductive feature;
forming a first electrode in the first cavity and the second cavity;
forming an insulator layer on the first electrode;
forming a second electrode on the insulator layer, wherein the first electrode, the insulator layer and the second electrode in the first cavity forms a memory cell storage capacitor, and the first electrode, the insulator layer and the second electrode in the second cavity forms a decoupling capacitor.

11. The method of claim 10, wherein a bottom surface of the memory cell storage capacitor is recessed relative to a bottom surface of the decoupling capacitor, and a top surface of the memory cell storage capacitor substantially levels with a top surface of the decoupling capacitor.

12. The method of claim 10, wherein the first cavity and the second cavity comprises a plurality of substantially u-shaped cross-sectional segments that are elongated in a vertical direction in the ILD layer, and are extending in the lateral direction substantially perpendicular to the vertical direction.

13. The method of claim 10, wherein a dimension of the second cavity has a first width measured in a direction parallel to a top surface of the semiconductor substrate, and the first width is less than a lateral width of the first conductive feature.

14. The method of claim 12, wherein in the first electrode formed in each of the adjacent substantially u-shaped cross-sectional segments of the second cavity are connected together at tops of the substantially u-shaped cross-sectional segments.

15. The method of claim 12, wherein the first electrode formed in each of the adjacent substantially u-shaped cross-sectional segments of the second cavity are separated in a lateral direction along a top surface of the ILD layer.

16. The method of claim 10, wherein the top surface of the first conductive feature partially overlaps with a bottom surface of the decoupling capacitor.

17. The method of claim 10, wherein a portion of a bottom surface of the decoupling capacitor is spaced apart from the first conductive feature.

18. An integrated circuit device, comprising:
an interconnect structure formed over a semiconductor substrate;
a memory cell disposed at a first region of the interconnect structure, wherein the memory cell comprising a transistor and a storage capacitor;
a decoupling capacitor disposed at a second region of the interconnect structure, and arranged in a direction that is substantially perpendicular to a top surface of the semiconductor substrate.

19. The structure of claim 18, wherein the interconnect structure further comprising:
a first metal line;
a first via coupled to the first metal line and at a height greater than the first metal line over the top surface of the semiconductor substrate; and
a second metal line coupled to the first via and at a height greater than the first via,
wherein a bottom surface of the storage capacitor of the memory cell is substantially co-planar with a bottom surface of the first metal line, the transistor of the memory cell is formed below the first metal line, and a bottom surface of the decoupling capacitor is between the first metal line and the second metal line.

20. The structure of claim 19, wherein the transistor of the memory cell comprises a semiconductor channel vertically adjacent to the storage capacitor and in a plane substantially parallel to the top surface of the semiconductor substrate, a first end of the semiconductor channel is electrically coupled to a bit line disposed below the first metal line, and running substantially parallel to the top surface of the substrate, and a second end of the semiconductor channel is electrically coupled to the storage capacitor.
